(19) United States
(12) Patent Application Publication
(10) Pub. No.: US 2023/0238477 A1
(43) Pub. Date: Jul. 27, 2023

(54) TRANSFER PROCESS TO REALIZE SEMICONDUCTOR DEVICES

(71) Applicant: The Regents of the University of California, Oakland, CA (US)

(72) Inventors: Srinivas Gandrothula, Ibaraki (JP); Takeshi Kamikawa, Kyoto (JP)

(73) Assignee: The Regents of the University of California, Oakland, CA (US)

(21) Appl. No.: 18/008,064

(22) PCT Filed: Jun. 21, 2021
(86) PCT No.: PCT/US21/38194

§ 371 Date: Dec. 2, 2022

Related U.S. Application Data
(60) Provisional application No. 63/041,659, filed on Jun. 19, 2020.

(51) Int. Cl. H01L 33/00; H01L 33/46; H01L 21/683; H01S 5/42; H01S 5/02; H01S 5/0237; H01S 5/343; H01S 5/183; H01S 5/22

(52) U.S. Cl. CPC H01L 33/0093; H01L 33/0075; H01L 33/46; H01L 21/6838; H01S 5/423; H01S 5/0201; H01S 5/0237; H01S 5/34333; H01S 5/18361; H01S 5/22; H01L 25/167

(57) ABSTRACT

A method of fabricating and transferring high quality and manufacturable light-emitting devices, such as micro-sized light-emitting diodes (μLEDs), edge-emitting lasers and vertical-cavity surface-emitting lasers (VCSELs), using epitaxial later over-growth (ELO) and isolation methods. III-nitride semiconductor layers are grown on a host substrate using a growth restrict mask, and the III-nitride semiconductor layers on wings of the ELO are then made into the light-emitting devices. The devices are isolated from the host substrate to a thickness equivalent to the growth restrict mask and then transferred or lifted from of the host substrate. Back-end processing of the devices is then performed, such as attaching distributed Bragg reflector (DBR) mirrors, forming cladding layers, and/or adding heatsinks.

### CROSS REFERENCE TO RELATED APPLICATIONS

This application claims the benefit under 35 U.S.C. Section 119(e) of the following co-pending and commonly-assigned application:

U.S. Provisional Application Ser. No. 63/041,659, filed on Jun. 19, 2020, by Srinivas Gandrothula and Takeshi Kamikawa, entitled “TRANSFER PROCESS TO REALIZE SEMICONDUCTOR DEVICES,” attorneys' docket number G&C 30794.0777USP1 (UC 2020-723-1);

which application is incorporated by reference herein.

This application is related to the following co-pending and commonly-assigned applications:

U.S. Utility patent application Ser. No. 16/608,071, filed on Oct. 24, 2019, by Takeshi Kamikawa, Srinivas Gandrothula, Hongjian Li and Daniel A. Cohen, entitled “METHOD OF REMOVING A SUBSTRATE,” attorney's docket number 30794.0653USWO (UC 2017-621-1), which application claims the benefit under 35 U.S.C. Section 365(c) of co-pending and commonly-assigned PCT International Patent Application No. PCT/US18/31393, filed on May 7, 2018, by Takeshi Kamikawa, Srinivas Gandrothula, Hongjian Li and Daniel A. Cohen, entitled “METHOD OF REMOVING A SUBSTRATE,” attorney's docket number 30794.0653WOU1 (UC 2017-621-2), which application claims the benefit under 35 U.S.C. Section 119(e) of co-pending and commonly-assigned U.S. Provisional Patent Application No. 62/502,205, filed on May 5, 2017, by Takeshi Kamikawa, Srinivas Gandrothula, Hongjian Li and Daniel A. Cohen, entitled “METHOD OF REMOVING A SUBSTRATE,” attorney's docket number 30794.0653USP1 (UC 2017-621-1);

U.S. Utility patent application Ser. No. 16/642,298, filed on Feb. 20, 2020, by Takeshi Kamikawa, Srinivas Gandrothula and Hongjian Li, entitled “METHOD OF REMOVING A SUBSTRATE WITH A CLEAVING TECHNIQUE,” attorney's docket number 30794.0659USWO (UC 2018-086-2), which application claims the benefit under 35 U.S.C. Section 365(c) of co-pending and commonly-assigned PCT International Patent Application No. PCT/US18/51375, filed on Sep. 17, 2018, by Takeshi Kamikawa, Srinivas Gandrothula and Hongjian Li, entitled “METHOD OF REMOVING A SUBSTRATE WITH A CLEAVING TECHNIQUE,” attorney's docket number 30794.0659WOU1 (UC 2018-086-2), which application claims the benefit under 35 U.S.C. Section 119(e) of co-pending and commonly-assigned U.S. Provisional Patent Application No. 62/559,378, filed on Sep. 15, 2017, by Takeshi Kamikawa, Srinivas Gandrothula and Hongjian Li, entitled “METHOD OF REMOVING A SUBSTRATE WITH A CLEAVING TECHNIQUE.” attorney's docket number 30794.0659USP1 (UC 2018-086-1):

U.S. Utility patent application Ser. No. 16/978,493, filed on Sep. 4, 2020, by Takeshi Kamikawa. Srinivas Gandrothula and Hongjian Li, entitled “METHOD OF FABRICATING NONPOLAR AND SEMIPOLAR DEVICES USING EPITAXIAL LATERAL OVERGROWTH,” attorney's docket number 30794.0680USWO (UC 2018-427-2), which application claims the benefit under 35 U.S.C. Section 365(c) of co-pending and commonly-assigned PCT International Patent Application No. PCT/US19/25187, filed on Apr. 1, 2019, by Takeshi Kamikawa, Srinivas Gandrothula and Hongjian Li, entitled “METHOD OF FABRICATING NONPOLAR AND SEMIPOLAR DEVICES USING EPITAXIAL LATERAL OVERGROWTH,” attorney's docket number 30794.0680WOU1 (UC 2018-427-2), which application claims the benefit under 35 U.S.C. Section 119(e) of co-pending and commonly-assigned U.S. Provisional Patent Application Ser. No. 62/650,487, filed on Mar. 30, 2018, by Takeshi Kamikawa, Srinivas Gandrothula, and Hongjian Li, entitled “METHOD OF FABRICATING NONPOLAR AND SEMIPOLAR DEVICES BY USING LATERAL OVERGROWTH,” attorney docket number G&C 30794.0680USP1 (UC 2018-427-1);

U.S. Utility patent application Ser. No. 17/048,383, filed on Oct. 16, 2020, by Takeshi Kamikawa and Srinivas Gandrothula, entitled “METHOD FOR DIVIDING A BAR OF ONE OR MORE DEVICES,” attorney's docket number 30794.0681USWO (UC 2018-605-2), which application claims the benefit under 35 U.S.C. Section 365(c) of co-pending and commonly-assigned PCT International Patent Application No. PCT/US19/32936, filed on May 17, 2019, by Takeshi Kamikawa and Srinivas Gandrothula, entitled “METHOD FOR DIVIDING A BAR OF ONE OR MORE DEVICES.” attorney's docket number 30794.0681WOU1 (UC 2018-605-2), which application claims the benefit under 35 U.S.C. Section 119(e) of co-pending and commonly-assigned U.S. Provisional Application Ser. No. 62/672,913, filed on May 17, 2018, by Takeshi Kamikawa and Srinivas Gandrothula, entitled “METHOD FOR DIVIDING A BAR OF ONE OR MORE DEVICES,” attorneys' docket number G&C 30794.0681USP1 (UC 2018-605-1);

U.S. Utility patent application Ser. No. 17/049,156, filed on Oct. 20, 2020, by Srinivas Gandrothula and Takeshi Kamikawa, entitled “METHOD OF REMOVING SEMICONDUCTING LAYERS FROM A SEMICONDUCTING SUBSTRATE.” attorney's docket number 30794.0682USWO (UC 2018-614-2), which application claims the benefit under 35 U.S.C. Section 365(c) of co-pending and commonly-assigned PCT International Patent Application No. PCT/US19/34686, filed on May 30, 2019, by Srinivas Gandrothula and Takeshi Kamikawa, entitled “METHOD OF REMOVING SEMICONDUCTING LAYERS FROM A SEMICONDUCTING SUBSTRATE,” attorney's docket number 30794.0682WOU1 (UC 2018-614-2), which application claims the benefit under 35 U.S.C. Section 119(e) of co-pending and commonly-assigned U.S. Provisional Application Ser. No. 62/677,833, filed on May 30, 2018, by Srinivas Gandrothula and Takeshi Kamikawa, entitled “METHOD OF REMOVING SEMICONDUCTING LAYERS FROM A SEMICONDUCTING SUBSTRATE.” attorneys' docket number G&C 30794.0682USP1 (UC 2018-614-1);

U.S. Utility patent application Ser. No. 17/285,827, filed on Apr. 15, 2021, by Takeshi Kamikawa and Srinivas Gandrothula, entitled “METHOD OF OBTAINING A SMOOTH SURFACE WITH EPITAXIAL LATERAL OVERGROWTH,” attorney's docket number 30794.0693USWO (UC 2019-166-2), which application claims the benefit under 35 U.S.C. Section 365(c) of co-pending and commonly-assigned PCT International Patent Application No. PCT/US19/59086, filed on Oct. 31, 2019, by Takeshi Kamikawa and Srinivas Gandrothula, entitled “METHOD OF OBTAINING A SMOOTH SURFACE WITH EPITAXIAL LATERAL OVERGROWTH,” attorney's docket number 30794.0693WOU1 (UC 2019-166-2), which application claims the benefit under 35 U.S.C. Section 119(e) of co-pending and commonly-assigned U.S. Provisional Application Ser. No. 62/753,225, filed on Oct. 31, 2018, by Takeshi Kamikawa and Srinivas Gandrothula, entitled “METHOD OF OBTAINING A SMOOTH SURFACE WITH EPITAXIAL LATERAL OVERGROWTH,” attorneys' docket number G&C 30794.0693USP1 (UC 2019-166-1):

PCT International Patent Application No. PCT/US20/13934, filed on Jan. 16, 2020, by Takeshi Kamikawa. Srinivas Gandrothula and Masahiro Araki, entitled “METHOD FOR REMOVAL OF DEVICES USING A TRENCH,” attorney's docket number 30794.0713WOU1 (UC 2019-398-2), which application claims the benefit under 35 U.S.C. Section 119(e) of co-pending and commonly-assigned U.S. Provisional Application Ser. No. 62/793,253, filed on Jan. 16, 2019, by Takeshi Kamikawa, Srinivas Gandrothula and Masahiro Araki, entitled “METHOD FOR REMOVAL OF DEVICES USING A TRENCH.” attorneys' docket number G&C 30794.0713USP1 (UC 2019-398-1);

PCT International Patent Application No. PCT/US20/20647, filed on Mar. 2, 2020, by Takeshi Kamikawa and Srinivas Gandrothula, entitled “METHOD FOR FLATTENING A SURFACE ON AN EPITAXIAL LATERAL GROWTH LAYER,” attorney's docket number 30794.0720WOU1 (UC 2019-409-2), which application claims the benefit under 35 U.S.C. Section 119(e) of co-pending and commonly-assigned U.S. Provisional Application Ser. No. 62/812,453, filed on Mar. 1, 2019, by Takeshi Kamikawa and Srinivas Gandrothula, entitled “METHOD FOR FLATTENING A SURFACE ON AN EPITAXIAL LATERAL GROWTH LAYER,” attorneys' docket number G&C 30794.0720USP1 (UC 2019-409-1);

PCT International Patent Application No. PCT/US20/22430, filed on Sep. 17, 2020, by Takeshi Kamikawa, Srinivas Gandrothula and Masahiro Araki, entitled “METHOD FOR REMOVING A BAR OF ONE OR MORE DEVICES USING SUPPORTING PLATES,” attorney's docket number 30794.0724WOU1 (UC 2019-416-2), which application claims the benefit under 35 U.S.C. Section 119(e) of co-pending and commonly-assigned U.S. Provisional Application Ser. No. 62/817,216, filed on Mar. 12, 2019, by Takeshi Kamikawa, Srinivas Gandrothula and Masahiro Araki, entitled “METHOD FOR REMOVING A BAR OF ONE OR MORE DEVICES USING SUPPORTING PLATES,” attorneys' docket number G&C 30794.0724USP1 (UC 2019-416-1);

PCT International Patent Application No. PCT/US21/27914, filed on Apr. 19, 2021, by Takeshi Kamikawa, Masahiro Araki and Srinivas Gandrothula, entitled “METHOD FOR REMOVING A DEVICE USING AN EPITAXIAL LATERAL OVERGROWTH TECHNIQUE,” attorney's docket number 30794.0762WOU1 (UC 2020-706-2), which application claims the benefit under 35 U.S.C. Section 119(e) of co-pending and commonly-assigned U.S. Provisional Application Ser. No. 63/011,698, filed on Apr. 17, 2020, by Takeshi Kamikawa, Masahiro Araki and Srinivas Gandrothula, entitled “METHOD FOR REMOVING A DEVICE USING AN EPITAXIAL LATERAL OVERGROWTH TECHNIQUE,” attorneys' docket number G&C 30794.0762USP1 (UC 2020-706-1);

all of which applications are incorporated by reference herein.

### BACKGROUND OF THE INVENTION

### 1. Field of the Invention

This invention simplifies methods of fabricating semiconducting devices, mainly light emitting devices, by placing or separating semiconducting layer(s) from a host substrate.

### 2. Description of the Related Art

Small-sized light-emitting diodes (LEDs) (also known as micro-LEDs or μLEDs), are inorganic LEDs in micron dimensions and are self-emissive, which means μLEDs can attain the highest contrast ratio and simplify display panel design. Recently, there has been some research interests in employing μLEDs in sizes from 100 to 200 μm as the backlight source in Liquid Crystal Displays (LCDs) to boost the contrast ratio, to reduce the complexity of LCD architecture, and to improve other display parameters, such as viewing angle and aperture ratio. Since μLEDs are sized in the microscopic scale, each μLED represents a pixel in monochromic displays, or three red, green, and blue μLEDs form a pixel in full-color displays. In addition. μLEDs are comprised of mature inorganic semiconductor materials, such as InGaN or AlGaInP, that provide advantages superior to existing display technologies, such as LCDs and organic LEDs, including high peak brightness, remarkable energy efficiency, chemical robustness, and long operating lifespan.

The present focus of the III-nitride material system consists of the chemical formula GaₓAl_{y}In_{z}N where 0≤x≤1, 0≤y≤1, 0≤z≤1, and x+y+z=1. The majority of research attention focuses on InGaN-based μLEDs, although there is some research on UV-A AlGaN μLEDs for display applications.

One of the most vital advantages of the InGaN material system is the emission wavelength tunability by varying the composition percentage of indium and gallium in the active region, also known as quantum wells (QWs), since the bandgaps of GaN and InN are 3.4 eV and 0.7 eV, respectively, and the alloy of InGaN can theoretically cover the entire visible spectrum.

Additionally, current InGaN materials, especially for display applications, are grown on sapphire (Al₂O₃) or silicon (Si) substrates using metalorganic chemical vapor deposition (MOCVD). Depending on the reactor dimensions, the wafer diameter can be scaled from 2-inch to 6-inch for sapphire substrates or up to 18-inch for silicon substrates, and this scalability is ideal for mass production with low material cost.

Epitaxial lateral overgrowth (ELO), which in principle can be adopted to any of the above-mentioned substrates, and thus scalability is not a problem in applying the technique, is known for better crystal quality as compared to growing device layers directly on heterogeneous templates.

Conventional LEDs (with at least one side larger than 300 μm) usually have a large top emitting area device design to reduce carrier concentration in the active region to avoid the influences of efficiency droop. Due to this large emitting area, non-radiative centers, such as crystal defects, may not play a major role in device operation. However, when light emitting areas are on the order of 100 μm×100 μm to 10 μm×10 μm, or even smaller, existing defects in the light emitting layer may significantly degrade performance.

Besides the scalable flexibility when using heterogeneous substrates, such as sapphire or silicon, in a conventional approach, a laser liftoff method or other damage-induced method may be employed to remove fabricated devices from the heterogeneous substrates to other substrates or display panels, although there are no methods that report utilizing a homogeneous substrate. Also, when used with a heterogeneous or foreign substrate to obtain quality device layers, one must include buffer layers or seed layers and, to avoid laser lift off damage, the total device would be thicker.

Although μLEDs have great potential in display and other emerging applications, there are some challenges need to be addressed before there is realization of commercial products for mass production. Three essential issues of InGaN μLEDs are: size-dependent efficiency, color gamut (long-wavelength emission), and mass-transfer techniques.

Production of quality μLEDs is problematic due to their size limiting efficiency, which is attributed to the increase in non-radiative recombination when the size of the device dimensions are comparable to crystalline defects of the semiconducting layers, or the increase in the presence of defects in the given device dimension. The mass transfer of μLEDs are also unique problems for display manufacturers of μLED displays, where each red, green, and blue device represents a pixel, and large numbers of pixels are needed for display applications.

Despite the numerous existing methods for mass transfer, the ideal mass-transfer methods should have rapid transfer rate with high yield and selectivity of dead or defective pixels. This is particularly difficult for display builders.

The pick-and-place method developed using elastomer stamps is the standard approach for transferring μLEDs in solid-state lighting packaging. The typical pick-and-place method is suitable for the transfer of μLED displays, but selectivity or avoiding dead pixels or locally repairing dead pixels after transferring them onto a display panel is a necessity when millions of devices involved.

Additionally, besides advancing the μLED transfer technology for display applications, there are other emerging usages, including biomedical and optogenetic, for heterogeneous integration of inorganic semiconductors on flexible and transparent substrates.

Edge-emitting lasers, commonly known as Fabry-Perot lasers, have been the focus of many high-energy-based applications, such as automotive lighting, specialty lighting, outdoor and indoor lighting, and light-fidelity (Li-Fi) applications. However, most of the developments were focused on fabricating them in a conventional manner, which includes a host substrate in the final product.

There is also a lot of interest in fabricating vertical-cavity surface-emitting lasers (VCSELs) that satisfies the goals of manufacturability, good quality, non-critical tolerances, best characteristics and better yield. The distributed Bragg reflector (DBR) is a key building block in the formation of semiconductor microcavities and VCSELs. The success in epitaxial GaAs DBR mirrors paved the way for the ubiquitous deployment of III-V VCSELs in communication and mobile applications.

However, a similar development of GaN-based blue VCSELs has been hindered by challenges in preparing DBRs that are mass producible. It is accepted that a key component and bottleneck in the GaN VCSEL technologies is the preparation of DBR mirrors, in particular, a DBR mirror on the substrate side. Furthermore, semiconductor epitaxial DBRs or conductive DBRs could be made electrically and thermally conductive, thus producing significant benefits to the VCSEL performance.

There have been approaches to making continuous VCSEL structures by employing semiconductor epitaxial DBRs on the host substrate, but this is tedious due to the requirement of a larger number of quarter wavelength layer pairs. For example, for an epitaxial DBR of lattice matched AlInN/GaN or AlGaN/GaN DBRs, at least 30 or more quarter wavelength layer pairs are necessary to achieve better reflectivity. Also, due to the difference in lattice parameters between the constituent layers, leading to high tensile or compressive strains during the growth of DBR before reaching the required number of pairs for high reflectance, the growth of AlGaN/GaN DBRs already encounters significant cracking, morphological degradation, or generation of dislocations.

As a result, it would be ideal to stack or laminate the gain medium of a VCSEL with vertically conducting DBRs or epitaxial DBRs separately. However, the use of methods such as chemical mechanical polishing (CMP), or laser lift-off (LLO), which was developed to separate GaN LEDs from sapphire substrates with back-side irradiation by an excimer laser, or photoelectrical or electrical etching, are the only available methods for substrate removal, so that the VCSEL gain medium removed from the host substrate can be stacked to desired DBRs.

However, these methods have their own limitations when implementing them at industrial scale. For example, the LLO method does not work with GaN or Si substrates due to their opacity to the excimer laser, which is a serious limitation for VCSEL devices grown on bulk GaN substrates.

Generally, substrate removal requires a follow-up polishing step to smoothen the surface and fine-tune the cavity thickness after layer separation. Achieving precise control of cavity thickness through polishing, with good uniformity across the entire wafer, can be a challenging task.

The use of a photoelectrical etching approach has the advantage of precisely controlling the thickness of the microcavity through a bandgap-selective etching process, but yield, controllability and time to remove substrates might be hindering the approach from mass production adoption.

The work done by Kuramoto et al., APEX, 11, 112101(2018), on developing epitaxial DBRs, and Hamaguchi et al, APEX, 12, 044004 (2019), on developing a curved mirror approach on the substrate side, are some examples from industry that avoid some of the limitations of the manufacturability methods.

In the case of visible region light emitters, III-nitride materials, such as GaN, are required to fabricate good quality VCSELs. Alternatively, there have been approaches utilizing III-nitride templates on foreign substrates, such as Si, sapphire, SiC, etc. However, especially with devices that involve stimulated emission and smaller dimensional light emitting areas, a homogeneous epitaxy would be suggested, rather than a non-homogeneous epitaxy or hetero-epitaxy, in order to tolerate micron-level defects.

There is also a need for a method of fabricating a good quality light emitting aperture for VCSEL devices, which emits light normal to the substrate.

In U.S. Pat. No. 9,407,067 B2, and US Patent Application Publication No. 2019/0173263 A1, and in the publication Phys. Status Solidi A 2016, 213, 1170-1176, Hamaguchi et al. mentioned fabricating a light emitting element aperture on an ELO region; however, mass production and an unwanted crystal quality between the resonating length of the cavity might affect the final characteristics of the device.

Also, Hamaguchi et al. uses a curved mirror approach that still needs substrate thinning to reduce absorption loss in the cavity, which can be a difficult process to control at industrial scales. In addition, removing or thinning the substrate by chemical or mechanical polishing would be tedious and affect yields.

In Takeshi et al., OPEX, Vol. 27, Issue 17. pp. 24717-24723 (2019), as well as PCT International Patent Application No. PCT/US18/31393, filed on May 7, 2018, by Takeshi Kamikawa, Srinivas Gandrothula, Hongjian Li and Daniel A. Cohen, entitled “METHOD OF REMOVING A SUBSTRATE,” which is cross-referenced above, and Gandrothula et al., APEX, Vol. 13. Number 4, (2020), a robust method was demonstrated for removing a substrate after fabricating a light emitting element on the substrate. This method utilized the ELO wing as a light emitting aperture, and the smooth layer surface of the device layers on the ELO wing's growth restrict mask as a bonding assistance surface for a thermally or/and conducting DBR of an external carrier, such as AlN/GaN DBR on Si, SiC, GaN, etc.

Nonetheless, there remains a need in the art for improved transfer processes to realize semiconductor devices. The present invention satisfies those needs.

### SUMMARY OF THE INVENTION

To overcome the limitations in the prior art described above, and to overcome other limitations that will become apparent upon reading and understanding this specification, the present invention discloses a method for fabricating semiconducting layer(s) on a host substrate and then separating the semiconducting layers from the host substrate, where the host substrate can be a homogeneous or foreign substrate or a template containing materials of the fabricated and separated semiconducting layers. The fabrication and separation is performed at wings of III-nitride ELO layers, thereby resulting in devices on these layers that has good crystal quality in terms of dislocation densities and stacking faults.

This invention provides a solution for mass transfer of small-sized LEDs, such as μLEDs, for local repair of μLEDs on a display panel, and for improved yield in edge-emitting laser devices, and is also helpful in realizing innovative designs, such as dual-cladding laser devices, and stacking a resonant cavity of a VCSEL device with at least one fully conducting DBR mirror.

This invention starts by placing or arranging the semiconducting device layers on the host substrate with or without a minimal link with the host substrate using ELO and etching. Once the semiconducting device layers are isolated from the host substrate with or without the minimal link with the host substrate, several unique devices can be realized, including μLEDs, edge-emitting lasers, and VCSELs.

This invention can be realized either using a homogeneous host substrate, similar to device layers' material, or a foreign substrate, such as Si, SiC, sapphire, Ga₂O₃, III-nitride templates, or an ELO-containing III-nitride template substrate, for better crystal qualities and improved efficiencies. Alternatively, this approach can be adopted to any semiconducting material system.

Specifically, this invention performs the following steps: III-nitride ELO layers are grown using the ELO method on the host substrate using a growth restrict mask. The III-nitride ELO layers are meant to be regions with reduced dislocation densities, as compared to regions that are not III-nitride ELO layers. The light emitting region of the micro-LED, or the gain medium (ridge) of the edge-emitting laser, or the light emitting aperture of the VCSEL, is confined to the wings of the III-nitride ELO layers, at least in part, such that good crystal quality layers can be guaranteed. In the case for edge-emitting lasers, for example, dual-clad edge-emitting lasers, or at least one DBR mirror of VCSELs, or micro-cavity LEDs (where at least one DBR mirror is placed to minimize cross talking), there is still a need for further back-end processes. In the case of VCSELs, preferably the light emitting apertures are fully made within the wings of the III-nitride ELO layers. In the case of μLEDs, the front-end process until the p-pad and n-pad can be finished on the wings of the III-nitride ELO layers, and then devices are separated and isolated, but not lifted from the host substrate.

The isolated devices remain on the host substrate with a very minimal link or no link at all, so lifting them off the host substrate for post-processing or preparing for packaging does not require hard liftoff methods, such as LLO or polishing. The devices can be removed from the substrate either by an elastomer stamp, or by a vacuum chuck, or by bonding, or by attaching them to a separate carrier substrate.

This invention can avoid damage at a backside of the III-nitride device layers, even when removed from heterogeneous or foreign substrates. This damage-free removal method can be very beneficial when transferring μLEDs from their heterogeneous or homogeneous substrates to other substrates, for example, mechanically flexible or optically transparent substrates.

In the case of edge-emitting lasers, even though the laser devices remain on the host substrate (e.g., wafer), they are isolated from the host substrate in the form of devices with a minimal link or without having a link at all, which reduces the stiffness of the host substrate. Generally, bonding or attaching devices containing a stiff host substrate to another carrier, for good heatsinking or for further processing, such as facet cleaving and facet coating, results in bowing of the substrate and leads to several process failures. However, in this invention, as devices are isolated from the host substrate, the invention can selectively pick some devices and attach them to a heatsink carrier to allocate more heatsinking area, rather than crowding the devices all together. Also, a wafer-scale bonding process improves yield, due to the flexibility of the isolated devices on the host substrate.

In the case of special designs, like dual-clad lasers, an epitaxial cladding layer or externally prepared cladding layer, for example, using a sputter or chemical vapor deposition, can be attached to the backside of the removed devices, either by surface activation bonding or through a bonding assist layer. In particular, the backside of the III-nitride ELO layers has an interface with a roughness on the order of <2 nm, as these layers' surface is a replication of the surface of the growth restrict mask used in the ELO method. This roughness may allow simple surface activation for bonding another carrier wafer containing an external clad or conducting DBR mirror, such as dielectric multi layers or epitaxial multi layers. This invention ideally may help to avoid intermediate layers when bonding DBRs, cladding layers, or external cladding, to the backside of the device, as the III-nitride ELO layers are smooth enough for such surface activation bonding processes, wherein the surface activation bonding may include a method to expose a plasma to the carrier or substrate surface.

The interface at the growth restrict mask and the III-nitride ELO layers is smooth enough to fabricate or attach a DBR mirror, without severe chemical treatments. The III-nitride ELO layers and III-nitride device layers, which together comprise island-like III-nitride semiconductor layers, are removed from the substrate and DBR mirrors are attached at the backside of the wings of the ELO III-nitride layers, which is the interface served between the growth restrict mask and ELO III-nitride layers. As fabricated. μLEDs on the wings of the III-nitride ELO layers can be transferred onto a different carrier for further processing by means of a simple PDMS stamp, or a vacuum chuck, or glue attached a carrier plate, etc. Edge-emitting lasers fabricated on the wings of the III-nitride ELO layers can be transferred onto a better thermal management scheme, or the gain medium of the edge-emitting lasers can be stacked with dual-clad layers as fabricated.

The ELO method used to form the island-like III-nitride semiconductor layers may include growth by metal organic chemical vapor deposition (MOCVD), hydride vapor phase epitaxy (HVPE), etc., to accurately control thickness, and thus the cavity length of VCSEL devices. The III-nitride ELO layers and III-nitride device layers are dimensioned such that one or more of the island-like III-nitride semiconductor layers form a bar (known as a semiconductor bar or a bar of the device). By doing this, nearly identical devices can be fabricated adjacent to each other in a self-assembled array, and thus, by integration, scale-up can be made easier. Alternatively, the III-nitride ELO layers can made to coalesce initially, such that they can be later divided into bars of devices or individual chips.

Every device of such a bar can be addressed separately or together with other devices, by designing a proper fabrication process. For example, one could make a common cathode or anode for such a bar for monolithic integration, or one can address individual devices for full color display applications. Consequently, a high yield can be obtained.

This invention works irrespective of material system, wherein blue and green pixels are generally made from the III-nitride material system, while red pixels are generally made from the AlInGaP material system. This invention aims at not only providing a quality light emitting layer, but also a simplified transfer or pixel repair system for current display applications.

The simplified fabrication process described in this invention also provides a way to repair local pixels for μLED displays, to realize edge-emitting Fabry-Perot lasers, to realize edge-emitting laser devices with improved thermal characteristics and smaller footprints to improve yield, or to realize complex dual-cladding thin edge-emitting lasers by removing the host substrate, or to stack vertical conducting DBR mirrors for VCSELs.

Moreover, the present invention can use hetero-substrates to grow the island-like III-nitride semiconductor layers that form a bar. For example, a GaN template grown on a hetero-substrate, such as sapphire, Si, GaAs, SiC, etc., can be used in the present invention.

Furthermore, the ELO method can drastically reduce dislocation density and stacking faults density, which are critical issues when using hetero-substrates.

This invention combines ELO with a substrate removal technique that provides a way to realize better thermally managed devices, smaller footprint devices at least two times smaller than conventional size, as these devices can be realized on wings of the III-nitride ELO layers, and also more unique devices, which require removal of the substrate to employ cladding on the surfaces normal to the light emission, i.e., on the top and bottom of the edge-emitting devices.

Therefore, this invention can solve many kinds of problems incurred with the use of hetero-substrates, at the same time. For example, in a laser device, the interface between the growth restrict mask and the III-nitride ELO layers can be used as a facet for a resonator.

Key aspects of this invention include:
No damage is generated as laser liftoff is not used. When using laser liftoff, device layer thickness has some critical tolerances in order to avoid damage from the laser, but the process of this invention is not limited by damage.
A damage-free separation process may be applied to any kind of substrate, including homogeneous and heterogeneous substrates.
Enhances the process to transfer devices, as selected devices can be extracted from the host substrate.
A vacuum process or stamping process enables selectivity of the devices.
This invention fabricates the light emitting area of the device on wings of the III-nitride ELO layers, thereby providing better crystal quality in the light emission area, which improves performance.
This invention can utilize foreign substrates such as Si, SiC, sapphire, template substrates, ELO assisted semiconducting substrates, etc., to scale up manufacturability for industrial needs.
This invention can be utilized to increase yield by making smaller footprint devices confined to the wings of the III-nitride ELO layers.
Fabry-Perot lasers or edge-emitting lasers can be made better by facilitating thermal management schemes with the edge-emitting laser devices removed from the host substrate.
Wafer-to-wafer bonding problems, such as bowing, can be avoided as this invention bonds discrete or separated devices from the host substrate to an external carrier, which is typically a better thermal conducting carrier. Also, instead of attaching discrete devices together to an external carrier, which restricts the available thermal spread on the carrier, more thermal space can be allocated to each device on the carrier by selective transfer.
Complex designs such as clad stacking on both sides of a light emitting surface or on a surface normal to light emission.
Edge-emitting lasers can be fabricated on wings of the III-nitride ELO layers, where the ridge can be placed in a region with the least defect density to improve electrical characteristics and lifetime.
A dual-clad edge-emitting laser can be fabricated, wherein an epitaxial cladding layer can be grown along the laser device structure during the ELO method and later, after transferring an isolated wing (laser device), additional layers of the device can be etched to the cladding layer. For example, AlN can be used as an epitaxial cladding layer.
A light-emitting aperture of the device can be made on the wings of the III-nitride ELO layers, which provides better crystal quality in terms of defects and stacking faults than a light-emitting aperture made directly on a native substrate.
The resonant cavity length of a VCSEL can be controlled epitaxially rather than using complicated techniques of thinning or chemical methods on native substrates.
At least one of the DBR mirrors of the VCSEL cavity may be placed on the wings of the III-nitride ELO layers, and a DBR mirror may be placed on a backside of the III-nitride ELO layers, after separating the III-nitride ELO layers from the substrate. The surface of the backside of the III-nitride ELO layers is very smooth, and thus is suited for making a DBR mirror for a VCSEL device due to the limiting of light scattering when reflecting.
In this invention, preparing a surface for a DBR mirror for resonant cavity VCSELs only uses a growth restrict mask.
This invention can be applied to make a curved mirror when a long resonant cavity for the VCSEL is desired.
This invention includes a method for realizing stress relaxation of the III-nitride ELO layers, which results in crack-free and long-lived devices, by placing one of the DBR mirrors after removing the III-nitride ELO layers from its host substrate.
The substrate can be recycled for a next batch of devices.
This method is independent of crystal orientations of the native substrate.

A few of the possible designs using this method are illustrated in the following detailed description of the invention. The invention has many benefits as compared to conventionally manufacturable device elements when combined with the cross-referenced inventions on removing semiconducting devices from a semiconducting substrate set forth above.

### BRIEF DESCRIPTION OF THE DRAWINGS

Referring now to the drawings in which like reference numbers represent corresponding parts throughout:

FIG. 1 is a schematic of a substrate, growth restrict mask, non-coalesced III-nitride epitaxial lateral overgrowth (ELO) layers, and coalesced III-nitride ELO layers, according to one embodiment of the present invention.

FIGS. 2A, 2B, and 2C illustrate that III-nitride ELO layers and III-nitride device layers together form island-like III-nitride semiconductor layers, according to one embodiment of the present invention.

FIG. 3 illustrates that the III-nitride ELO layers and III-nitride device layers are isolated from the host substrate without any contact, an open area of the substrate is used as a weak link to retain the isolated devices, and a hook layer assists a securing process to keep the isolated devices attached to the substrate.

FIG. 4 illustrates front-end process finished devices, including micro-LEDs, edge-emitting lasers and VCSELs respectively, and the tools used to remove the isolated III-nitride ELO layers and III-nitride device layers from the host substrate.

FIG. 5 includes schematics of possible devices fabricated on the wings of the III-nitride ELO layers.

FIG. 6 illustrates a process for fabricating and releasing a μLED device fabricated from the III-nitride ELO layers and III-nitride device layers.

FIG. 7 illustrates a process for fabricating and releasing a edge-emitting laser device from the III-nitride ELO layers and III-nitride device layers.

FIG. 8 illustrates a process for fabricating and releasing a VCSEL device from the III-nitride ELO layers and III-nitride device layers.

FIG. 9 is a schematic of the components of a dual-clad edge-emitting laser, where cladding on the n-side is attached externally on an interface of the wings of the III-nitride ELO layers.

FIG. 10 illustrates a process for fabricating and releasing an externally attached clad edge-emitting laser from the III-nitride ELO layers and III-nitride device layers.

FIGS. 11A, 11B, 11C and 11D are schematics of an isolation process to separate III-nitride ELO layers from the host substrate, and images from experimental demonstrations of isolation of the III-nitride ELO layers without having contact with the host substrate.

FIG. 12A illustrates an elastomer stamping process for transferring isolated III-nitride ELO layers and III-nitride device layers onto a target patterned carrier.

FIG. 12B illustrates a process for transferring isolated III-nitride ELO layers and III-nitride device layers using Spin-on-Glass (SoG) resist materials.

FIGS. 12C and 12D illustrate transferred polar c-plane III-nitride ELO layers and their interface surface roughness.

FIGS. 12E and 12F illustrate transferred semi-polar 20-21 plane III-nitride ELO layers and their interface surface roughness.

FIGS. 12G and 12H illustrate transferred non-polar 10-10 plane III-nitride ELO layers and their interface surface roughness.

FIG. 12I illustrates surface effecting strategies for the interface of the III-nitride ELO layers.

FIG. 13 includes schematics of an isolation process to separate III-nitride ELO layers and to secure them to the host substrate using a weak link at an open area.

FIGS. 14A and 14B includes schematics of an isolation process to separate III-nitride ELO layers and to secure them to the host substrate using a hook layer, and images from experimental demonstrations of the isolation of the III-nitride ELO layers without having a contact with the host substrate.

FIG. 15 includes schematics of an isolation process to separate III-nitride ELO layers and to secure them to the host substrate using a hook layer with two different approaches.

FIGS. 16A and 16B include schematics of a process for separating edge-emitting laser devices on wings of the III-nitride ELO layers and for attaching the devices to an external cladding template carrier to realize dual-clad lasers.

FIGS. 17A and 17B include schematics of a process for separating VCSEL devices on wings of the III-nitride ELO layers and for attaching the devices to an external DBR mirror template carrier.

FIG. 17C illustrates DBR mirror templates on a SiC carrier, where the DBRs are comprised of AlN/GaN or Al(Ga)N/GaN layers.

FIG. 17D includes schematics to prepare DBR layers on a GaN substrate and to transfer them onto a thermal conducting carrier using a PEC process.

FIG. 17E is a schematic to attach a porous GaN template to an interface of a removed VCSEL device as a second DBR layer.

FIG. 18, is a schematic to allocate more space for selectively picked device layers from the host substrate.

FIG. 19A is a design of a vacuum chuck to pick isolated III-nitride ELO layers and III-nitride device layers from the host substrate.

FIG. 19B is a process for picking isolated III-nitride ELO layers and III-nitride device layers from the host substrate using a vacuum chuck.

FIG. 19C is a schematic for utilizing a vacuum chuck containing III-nitride ELO layers and III-nitride device layers for further back-end processing on the interface.

FIG. 19D is a schematic for utilizing a vacuum chuck to locally repair defective devices on a targeted application such as displays.

FIG. 20 is a schematic for utilizing an elastomer PDMS stamp to pick selected devices.

FIG. 21 includes schematics illustrating the benefit a wafer-scale bonding process, as devices to be bonded are in a relaxed state due to separation from the host substrate.

FIG. 22 includes schematics for realizing larger scale wafers using the transfer process of the invention.

FIG. 23 is a flowchart and schematics of a monolithic attachment process for μLEDs onto a complementary metal-oxide-semiconductor (CMOS) integrated circuit (IC) wafer.

FIG. 24 includes a schematic of a substrate, growth restrict mask, non-coalesced III-nitride ELO layers, and coalesced III-nitride ELO layers, used in a scenario to extract multiple devices from a wing of the III-nitride ELO layers.

FIGS. 25A, 25B and 25C are a flowchart and schematics illustrating a fabrication scenario for a VCSEL device using this invention.

FIG. 26 is a flowchart illustrating a method for fabricating semiconducting devices according to this invention.

### DETAILED DESCRIPTION OF THE INVENTION

In the following description of the preferred embodiment, reference is made to a specific embodiment in which the invention may be practiced. It is to be understood that other embodiments may be utilized, and structural changes may be made without departing from the scope of the present invention.

Overview

The present invention describes a method of fabricating semiconductor devices, such as light emitting devices, including μLEDs, edge-emitting lasers, and VCSELs, using an ELO method, wherein the III-nitride semiconductor layers remain on the host substrate without a direct contact or having a very delicate contact with the host substrate. Since the ELO method is relied upon, this invention is easily applicable to foreign substrates, such as Si, SiC, sapphire, templates of semiconductor layers, or substrates containing ELO engineered layers and templates.

The present invention discloses a method of fabricating and transferring μLEDs, including micro-cavity μLEDs, edge-emitting lasers, and VCSELs, that is aimed at tolerating designs for mass production and better thermal characteristics. This invention can incorporate a curved DBR mirror on either a p-side or an n-side of the device, or can incorporate embedded DBR designs in addition to planar DBR designs.

This invention covers the following approaches:
1. μLEDs or micro-cavity LEDs can be fabricated on wings of III-nitride ELO layers that have good crystal quality, isolated from the host substrate, and then selectively picked or otherwise transferred onto a carrier such as a display back panel.
2. An edge-emitting laser's gain medium can be fabricated on the wings of the III-nitride ELO layers, the laser device can be separated from the host substrate, and the device can be picked and placed onto a heatsink carrier or attached permanently to a heat sink.
3. One of the cladding layers of a dual-clad edge-emitting laser can be epitaxially grown, for example, using AlN, and then the entire device structure, including waveguides, quantum wells, p-type and n-type layers, can be fabricated. The gain medium can be fabricated on the wings of the III-nitride ELO layers, the device can be isolated on the host substrate, the device can be attached to a carrier, and then the device can be polished from the backside until at least exposing an epitaxially grown cladding layer.
4. Short-cavity VCSELs with planar DBR mirrors can be fabricated, wherein aperture placements are made on the wings of the III-nitride ELO layers for better crystal quality.
5. Long-cavity VCSELs can be fabricated with curved DBR mirrors, which reduce diffraction losses by focusing reflected light back into an aperture. Long cavities can be useful for better thermal management, as well as increased lifetime, output power and efficiency. Long-cavity VCSELs can dissipate heat effectively from an active layer in a horizontal direction, as compared to, especially. GaN-based VCSELs, which sometimes use dielectric-layer DBRs on both sides of the cavity that are not good at heat dissipation.
6. A short-cavity or long-cavity embedded light reflecting DBR mirror design can be used for better thermal performance. This design avoids unwanted crystal quality due to coalescence.

In the following example, a process of realizing μLEDs and a transfer process are described.

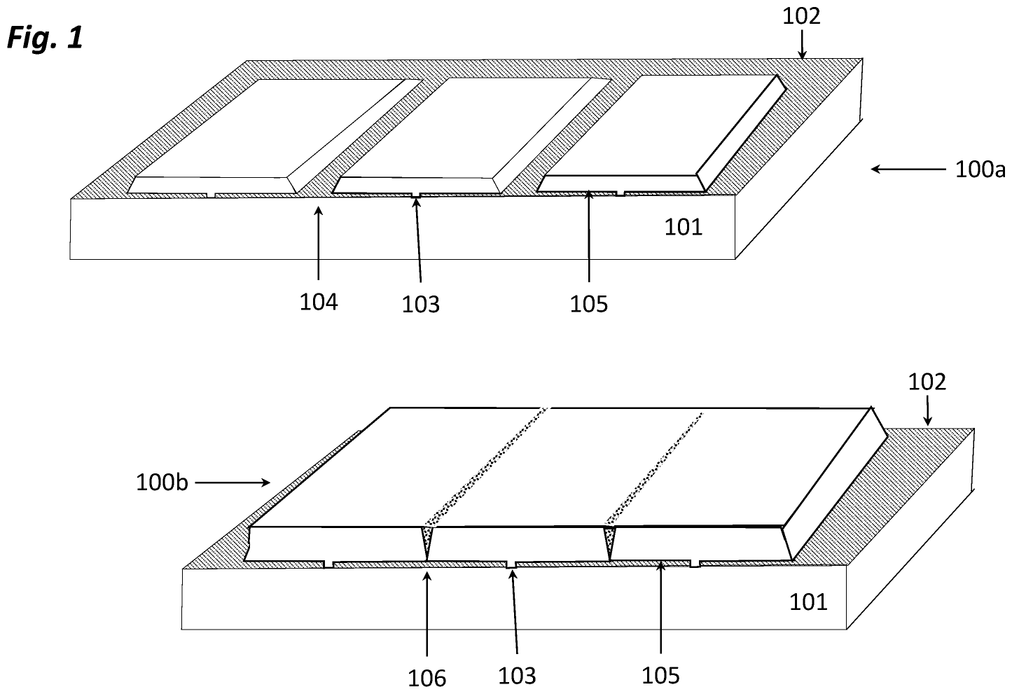

FIG. 1 illustrates a method using schematics 100A and 100B. The method first provides a III-nitride-based substrate 101, such as a bulk GaN substrate 101.

In schematic 100A, a growth restrict mask 102 is formed on or above the III-nitride based substrate 101. Specifically, the growth restrict mask 102 is disposed directly in contact with the substrate 101, or is disposed indirectly through an intermediate layer grown by MOCVD, etc., made of Iii-nitride-based semiconductor layer or template deposited on the substrate 101.

The growth restrict mask 102 can be formed from an insulator film, for example, an SiO₂ film deposited upon the base substrate 101, for example, by a plasma chemical vapor deposition (CVD), sputter, ion beam deposition (IBD), etc., wherein the SiO₂ film is patterned by photolithography using a predetermined photo mask and then etched to include opening areas 103, as well as no-growth regions 104 (which may or may not be patterned). The present invention can use SiO₂, SiN, SiON, TiN, etc., as the growth restrict mask 102.

Epitaxial III-nitride layers 105, such as GaN-based layers 105, are grown using the ELO method on the GaN substrate 101 and the growth restrict mask 102. The growth of the III-nitride ELO layers 105 occurs first in the opening areas 103, on the III-nitride based substrate 101, and then laterally from the opening areas 103 over the growth restrict mask 102. The growth of the III-nitride ELO layers 105 may be stopped or interrupted before the III-nitride ELO layers 105 at adjacent opening areas 103 can coalesce on top of the growth restrict mask 102, wherein this interrupted growth results in the no-growth regions 104 between adjacent III-nitride ELO layers 105. Alternatively, the growth of the III-nitride ELO layers 105 may be continued and coalesce with neighboring III-nitride ELO layers 105, as shown in schematic 100B, thereby forming a coalesced region 106 of increased defects at a meeting region.

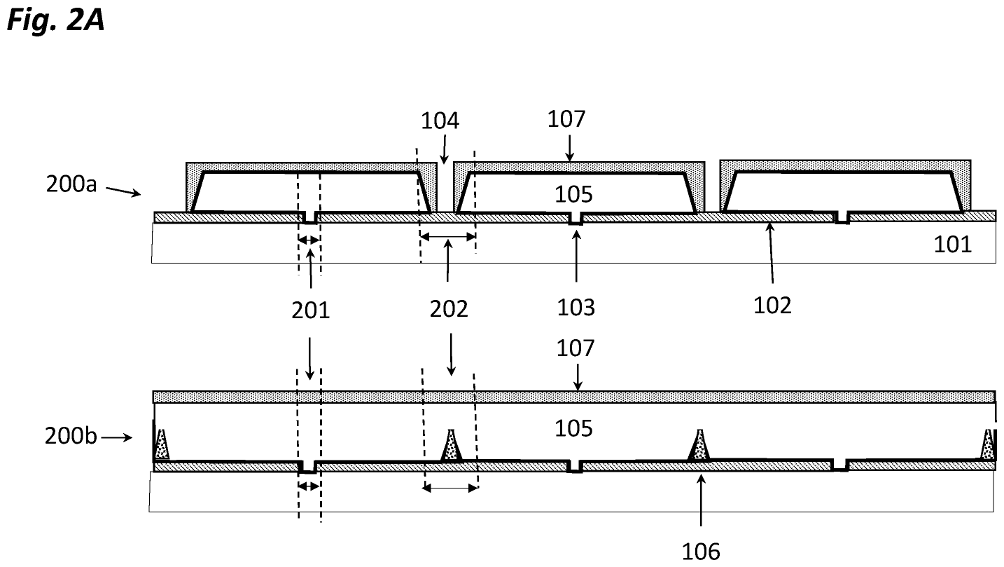

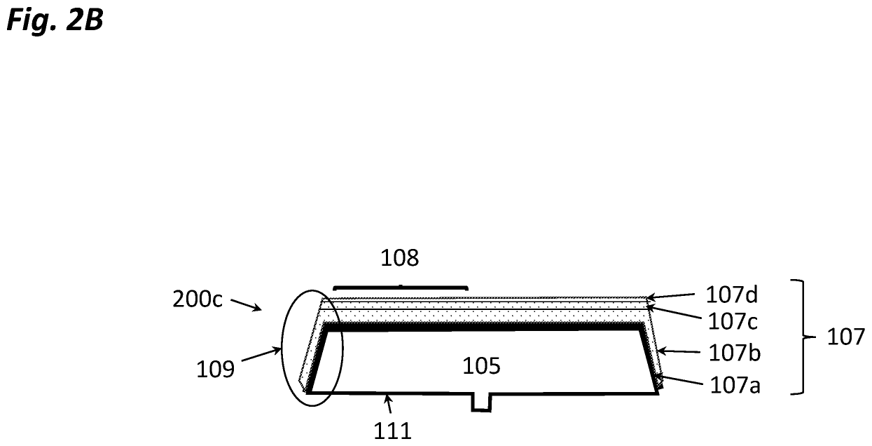

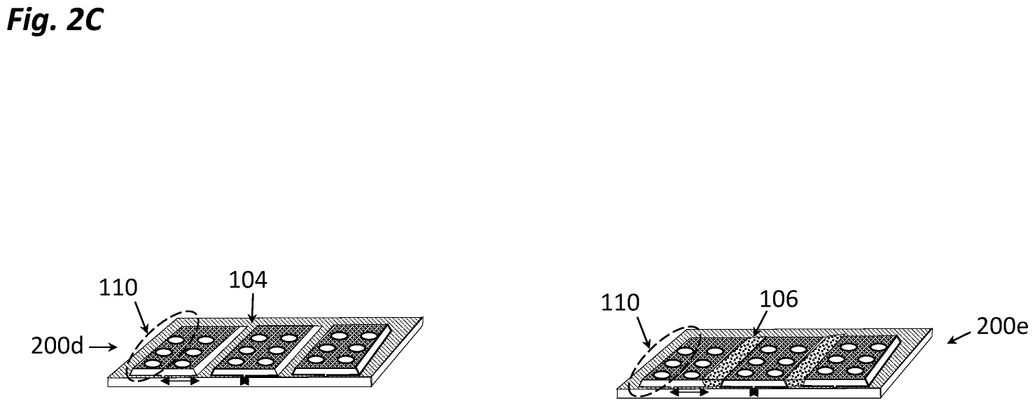

In FIGS. 2A, 2B and 2C, schematics 200a, 200b, 200c, 200d and 200e illustrate how additional III-nitride device layers 107 are deposited on or above the III-nitride ELO layers 105, and may include an active region 107a, p-type layer 107b, electron blocking layer (EBL) 107c, and cladding layer 107d, as well as other layers.

The III-nitride ELO layers 105 include one or more flat surface regions 108 and layer bending regions 109 at the edges thereof adjacent the no-growth regions 104. The width of the flat surface region 108 is at least 5 μm, and most preferably is 30 μm or more.

A light-emitting active region 107a of the devices 110 is processed at the flat surface regions 108, preferably between opening area 103 and the edge portion 109. By doing so, a bar of a device 110 will possess an array of twin or nearly identical light emitting apertures on either side of the opening area 103 along the length of the bar, as indicated in schematics 200d and 200e.

There are many methods of removing the light emitting regions from the substrate 101. For example, the present invention can utilize the ELO method for removing the light emitting devices. In the present invention, the bonding strength between the substrate 101 and the III-nitride ELO layers 105 is weakened by the growth restrict mask 102. In this case, the bonding area between the substrate 101 and the III-nitride ELO layers 105 is the opening area 103, wherein the width of the opening area 103 is narrower than the III-nitride ELO layers 105. Consequently, the bonding area is reduced by the growth restrict mask 102, so that this method is preferable for removing the epitaxial layers 105, 107.

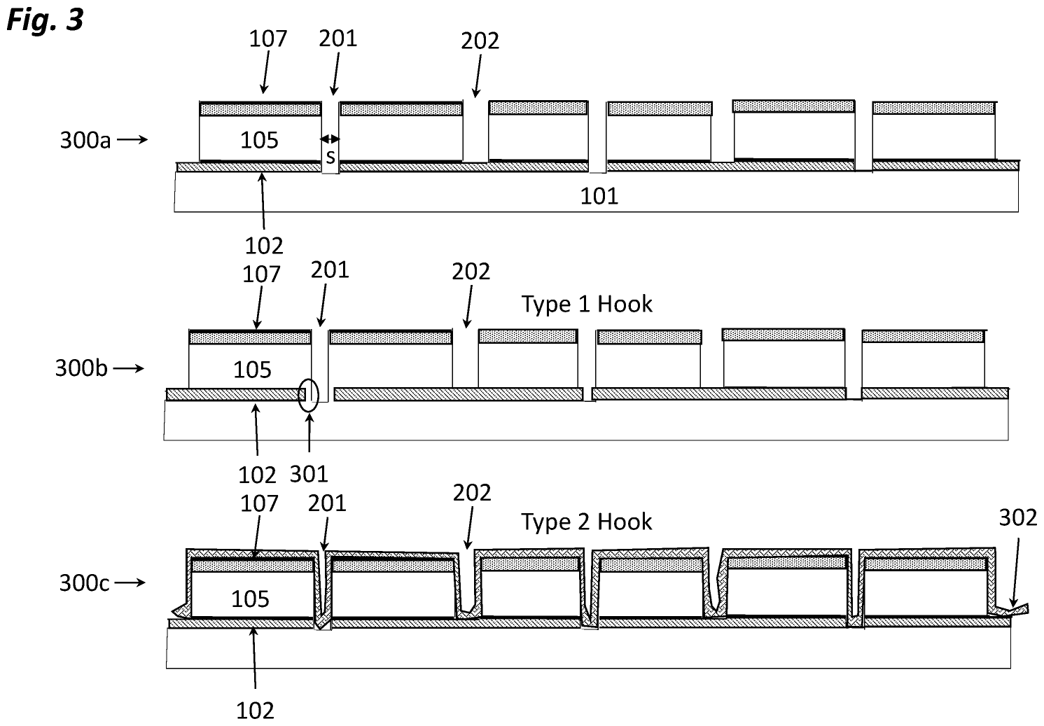

In one embodiment, the III-nitride ELO layers 105 are allowed to coalesce to each other, as shown in schematic 100b in FIG. 1. After the III-nitride ELO layers 105 coalesce, subsequent III-nitride device layers 107 are deposited. Light emitting element apertures are fabricated on wing regions of the III-nitride ELO layers 105 away from the coalesced region 106 and opening areas 103. Then, the III-nitride device layers 107 can be divided, as shown in schematics 300a, 300b, and 300c in FIG. 3, for example, using a dry etching or laser scribing, etc. A separate distance S, as shown in schematic 300a in FIG. 3, is a distance between adjacent III-nitride ELO layers 105 after etching a part which is above the opening area 103. Moreover, a width of a separate region is defined as the separate distance S. The emitting apertures mentioned above are located out of the separate region. Preferably, the edge of an emitting aperture is more than 3 μm from the edge of the separate region.

As can be seen in schematic 300a in FIG. 3, the III-nitride device layers 107 show no link with the host substrate 101, but are still held onto the host substrate 101 via Van Der Waals force or some weak interference force between the growth restrict mask 102 and the III-nitride ELO layers 105. However, for the sake of securing the isolated III-nitride ELO layers 105, two types of weak link patterns, namely, an assist layer 301 or a hook layer 302, can be imposed for separating the III-nitride ELO layers 105 and the III-nitride device layers 107 from the host substrate 101, as shown in schematics 300b and 300c.

The typical fabrication steps in this invention are described in more detail below:

Step 1: Forming a growth restrict mask 102 with a plurality of striped opening areas 103 directly or indirectly upon a substrate 101, wherein the substrate 101 is a III-nitride-based semiconductor, or the substrate 101 is a hetero-substrate, or the substrate 101 is a prepared template.

Step 2: Growing a plurality of epitaxial layers 105, 107 upon the substrate 101 using the growth restrict mask 102, such that the growth extends in a direction parallel to the striped opening areas 103 of the growth restrict mask 102, wherein the III-nitride ELO layers 105 do not coalesce in one embodiment; however, coalesced III-nitride ELO layers 105 may be used in another embodiment.

Step 3: Fabricating the device 110 on a wing region of the III-nitride ELO layers 105, which is mostly a flat surface region 108, by conventional methods, wherein, for example, in the case of VCSEL, a light reflective element structure (DBR), p-electrode, n-electrode, pads, etc., are deposited at pre-determined positions; similarly, for the case of μLEDs, p-electrode, n-electrode, pads, etc., are deposited.

Step 4: Forming a structure for separating device 110 units, wherein the devices 110 are separated from each other and the host substrate 101, and if necessary, a weak link 301, 302 can be established to secure the separated III-nitride device layers 107.

In the separation process, an open region of the III-nitride ELO layer 105 is referred to as Region 1 201 and a wing region at the which the wings of neighboring III-nitride ELO layers 105 may or may not meet is referred to as Region 2 202, as shown in FIG. 2. Region 2 202 in the non-coalesced III-nitride ELO layers 105 and III-nitride device layers 107 includes at least bending portion 109.

Region 1 201 and Region 2 202 are etched at least to expose the growth restrict mask 102, if necessary, and the III-nitride ELO layers 105 and III-nitride device layers 107 are divided into individual devices 110 or are kept together as a group of devices 110. A weak Van Der Waals force or an unknown interaction force between the growth restrict mask 102 and the III-nitride ELO layers 105 may help to keep the III-nitride device layers 107 from separating from the host substrate 101, even though the III-nitride ELO layers 105 literally possess no contact with the host substrate 101 after etching Regions 1 and 2 201, 202, as shown in schematic 300a in FIG. 3. It has been confirmed that the III-nitride ELO layers 105 still remain on the growth restrict mask 102 of the host substrate 101, for processes such as solvent cleaning, UV ozone exposer, etc. Therefore, cleaning the III-nitride ELO layers 105 and the III-nitride device layers 107 after separation using RIE or other techniques will help to remove residues and may also help to prepare surfaces for bonding processes or chemical treatments for recovering from etch damage. This is a big advantage in reducing process time and cost.

Alternatively, as indicated in schematics 300b and 300c in FIG. 3, an assist layer 301 or a hook layer 302, which connect with the host substrate 101, can secure the III-nitride ELO layers 105 and III-nitride device layers 107 to the host substrate 101, and these layers 301, 302 can be easily removed either ultrasonically or mechanically. Hook layers 302 preferably can be a dielectric layer, for example. SiO₂ may be placed between the devices 110, such that the newly placed dielectric layer rests on an exposed portion of the growth restrict mask 102. The strength of the assist layer 301 or hook layer 302 can be controlled by the thickness of the newly placed dielectric layer.

Many kinds of materials can be used as the hook layer 302 such as SiOx, SiNx, AlOx, SiONx, AlONx, TaOx, ZrOx, AlNx, TiOx, NbOx and so on (x>0). It is preferable that the hook layer 302 is a transparent layer with regard to light from the active layer 107a of the device 110, because there would be no need to remove the hook layer 302 after removing the III-nitride ELO layer 105 from the substrate 101. Alternatively, the hook layer 302 may be an insulation layer. If the hook layer 302 is not an insulation layer, and the hook layer 302 connects a p-type layer and a n-type layer of the device 110, it eventually would result in a short circuit: in this case, the hook layer 302 has to be removed.

Moreover, AlONx, AlNx, AlOx, SiOx, SiN. SiON has an effect to passivate the surfaces of the device 110, especially etched GaN. Since the hook layer 302 covers the sidewalls of the device 110, choosing these materials is preferable to reduce leakage current which flows from the sidewalls of the device 110. Moreover, the narrower the device 110 size, the more the leakage current, and thus passivating of the sidewalls of the device 110 is very important, especially at the separate region. Also, the strength of the bonding between the III-nitride ELO layer 105 and the growth restrict mask 102 can be controlled by changing the thickness of the hook layer 302.

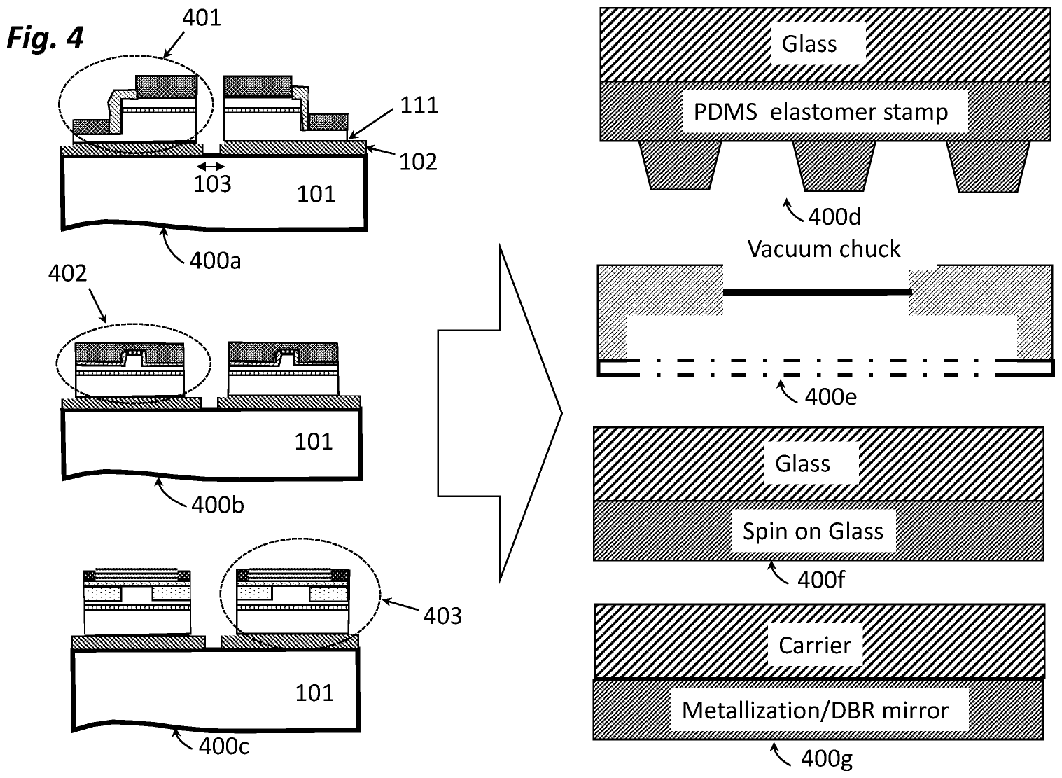

Step 5: The III-nitride ELO layer 105 and III-nitride device layers 107 are removed from the substrate 101, as shown by schematics 400a, 400b, 400c, 400d, 400e, 400f, 400g in FIG. 4. As noted above, the III-nitride ELO layer 105 and III-nitride device layers 107 are secured to the host substrate 101, as shown by schematics 400a, 400b, 400c, and can be peeled off or removed by means of a PDMS (polydimethylsiloxane) elastomer stamp 400d, or a vacuum chuck 400e, or by bonding or attaching to a carrier as shown in 400f and 400g.

For example, front-end completed process devices 110 such as μLEDs 401 and edge-emitting lasers 402 can be placed on a display back panel or a heatsink plate using tools such as the PDMS elastomer stamp 400d and vacuum chuck 400e. But, some devices 110, such as VCSELs 403, or dual-cladding edge-emitting lasers (not shown), or micro-cavity μLEDs (not shown), may need further back-end processing, for example, attaching a DBR mirror, or an external cladding layer, or polishing, etc., and in such a scenario, III-nitride layers 105, 107 can be bonded to an external carrier, such as glass, Si, SiC, Cu, CuW, etc., using spin-on-glass resist, as shown by 400f, or can be bonded to the external carrier using metallization or a DBR mirror, as shown by 400g.

If the bonding strength is weak, such as with a thin hook layer 302 or without a hook layer 302, a commercialized adhesive tape (not shown) can be used to remove the devices 110.

Step 6: After lifting off or picking the III-nitride devices 110 from the host substrate 101, the devices 110 can be placed at desired positions on a pre-patterned back panel for display applications, for example, in the case of micro-LEDs. For other kinds of devices 110, such as dual-cladding edge-emitting lasers, or VCSELs, or micro-cavity LEDs, since the interface 111 between the growth restrict mask 102 and the III-nitride ELO layers 105 is atomically smooth, in the nanometer range, the interface 111 can be bonded to a conducting DBR or a cladding layer via surface activation bonding.

The following steps are performed for devices 110 that need further back-end or post processing:

Step 7: Back-end processing.

In the case of micro-cavity LEDs 401, a substrate containing a DBR mirror may be attached onto a backside surface of the device 110 using surface activation bonding, as shown in 400g, wherein the backside surface of the device 110 comprises the interface 111 between the III-nitride ELO layers 105 and the growth restrict mask 102.

In the case of dual-clad edge-emitting lasers 402 that require a second cladding layer, a carrier containing an externally-deposited cladding layer, for example, AlN on Si or SiC, is attached to the backside surface of the device 110, such that is attached to the DBR surface by surface activation bonding, as shown in 400g.

Alternatively, an epitaxial cladding layer AlN and the laser device 110 structure can be fabricated on wings of the III-nitride ELO layers 105. Then, after attaching the isolated III-nitride device layers 107 from the host substrate 101 onto an external carrier, either by a spin-on-glass coating method as shown in 400f, or some other means, the backside surface of the device 110 may be polished to at least expose the epitaxial cladding layer.

In the case of VCSELs 403, a second light reflective element, i.e., a DBR mirror, is attached to the backside surface of the device 110. There are alternatives to placing a second DBR mirror onto the interface 111 at the wings of the III-nitride ELO layers 105.

For example, an externally prepared DBR mirror substrate can be attached to the backside surface of the III-nitride device 110, either by surface activation bonding, or diffusion pressure bonding, or by some other means, such that the top and bottom DBR mirrors of the III-nitride device 110 on the wing regions of the III-nitride ELO layers 105 can be used as a resonant cavity for the VCSEL 403; alternatively, external DBRs can be replaced with epitaxial light reflecting layers, such as AlN/GaN, AlInGaN/GaN or AlN/SiC DBRs to improve the thermal performance of the VCSEL 403. In this case, the external DBR can be grown on a thermally conductive substrate, such as Si, SiC, AlN, etc., by MOCVD, laser ablation, and sputtering. Since the DBR bonds to the III-nitride ELO layers 105 after the growth of the active region 107a of the device layers 107, the VCSEL 403 can be fabricated with a thermally conductive DBR without taking care of any lattice mis-match or internal stress to the active region.

Also, one may directly deposit DBR mirror layers onto the interface 111 of the III-nitride ELO layers 105.

Step 8 (Optional): Fabricating an n-electrode at a separate designated portion (the top and bottom electrode configuration need to be deposited after the second DBR layer is placed).

Step 9 (Optional): Breaking the bars into devices 110 (can be performed after Step 3).

Step 10 (Optional): Mounting each device 110 on a heat sink plate, such as SiC, AlN, etc.

Step 11 (Optional): Dividing the heat sink plate to separate the devices 110.

These steps are explained in more detail below.

Step 1: Forming a Growth Restrict Mask In one embodiment, III-nitride based layers 105 are grown by ELO on a III-nitride substrate 101, such as an m-plane GaN substrate 101 patterned with a growth restrict mask 102 comprised of SiO₂, wherein these III-nitride ELO layers 105 may or may not coalesce on top of the growth restrict mask 102.

The growth restrict mask 102 is comprised of stripes separated by opening areas 103, wherein the stripes between the opening areas 103 have a width of 1 μm-20 μm and an interval of 30 μm-150 μm. If a nonpolar III-nitride substrate 101 is used, then the opening areas 103 are oriented along a <0001> axis; if semipolar (20-21) or (20-2-1) plane III-nitride substrates 101 are used, then the opening areas 103 are oriented in a direction parallel to [−1014] or [10-14], respectively; other planes may be use as well, with the opening areas 103 oriented in other directions.

When using a III-nitride substrate 101, the present invention can obtain high quality III-nitride semiconductor layers 105, 107. As a result, the present invention can also easily obtain devices 110 with reduced defect density, such as reduced dislocation and stacking faults.

Moreover, these techniques can be used with a hetero-substrate 101, such as sapphire, SiC, LiAlO₂, Si, Ga₂O₃, etc., with or without buffer or template layers, as long as the substrate 101 enables growth of the III-nitride ELO layers 105 through the growth restrict mask 102.

Step 2: Growing a Plurality of Epitaxial Layers on the Substrate Using the Growth Restrict Mask

At Step 2, the III-nitride device layers 107 are grown on the III-nitride ELO layers 105 in the flat regions 108 by conventional methods. In one embodiment, MOCVD is used for the epitaxial growth, resulting in island-like III-nitride semiconductor layers including the III-nitride ELO layers 105 and the III-nitride device layers 107. The island-like III-nitride semiconductor layers are separated from each other, because the MOCVD growth is stopped before the III-nitride ELO layers 105 coalesce. In one embodiment, the III-nitride ELO layers 105 are made to coalesce and later etching is performed to remove unwanted Regions 1 and/or 2 201, 202.

Trimethylgallium (TMGa), trimethylindium (TMIn) and triethylaluminium (TMAl) are used as III elements sources. Ammonia (NH₃) is used as the raw gas to supply nitrogen. Hydrogen (H₂) and nitrogen (N₂) are used as a carrier gas of the III elements sources. It is important to include hydrogen in the carrier gas to obtain a smooth surface epi-layer.

Saline and Bis(cyclopentadienyl)magnesium (Cp₂Mg) are used as n-type and p-type dopants. The pressure setting typically is 50 to 760 Torr. III-nitride-based semiconductor layers are generally grown at temperature ranges from 700 to 1250° C.

For example, the growth parameters include the following: TMG is 12 sccm, NH₃ is 8 slm, carrier gas is 3 slm, SiH₄ is 1.0 sccm, and the V/III ratio is about 7700.

ELO of Limited Area Epitaxy (LAE) III-Nitride Layers

In the prior art, a number of pyramidal hillocks have been observed on the surface of m-plane III-nitride films following growth. See, for example, US Patent Application Publication No. 2017/0092810, which is incorporated by reference herein. Furthermore, a wavy surface and depressed portions have appeared on the growth surface, which made the surface roughness worse. This is a very severe problem when a VCSEL structure is fabricated on the surface. For that reason, it is better to grow the epitaxial layers on a nonpolar and semipolar substrate, which is well known to be difficult.

For example, according to some papers, a smooth surface can be obtained by controlling an off-angle (>1 degree) of the substrate's growth surface, as well as by using an N₂ carrier gas condition. These are very limiting conditions for mass production, however, because of the high production costs. Moreover, GaN substrates have a large fluctuation of off-angles to the origin from their fabrication methods. For example, if the substrate has a large in-plane distribution of off-angles, it has a different surface morphology at these points in the wafer. In this case, the yield is reduced by the large in-plane distribution of the off-angles. Therefore, it is necessary that the technique does not depend on the off-angle in-plane distribution.

The present invention solves these problems as set forth below:
1. The growth area is limited by the area of the growth restrict mask 102 from the edges of the substrate 101.
2. The substrate 101 is a nonpolar or semipolar III-nitride substrate 101 that has off-angle orientations ranging from −16 degrees to +30 degrees from the m-plane towards the c-plane. Alternatively, a hetero-substrate 101 with a III-nitride-based semiconductor layer deposited thereon may be used, wherein the layer has an off-angle orientation ranging from +16 degrees to −30 degrees from the m-plane towards the c-plane.
3. The island-like III-nitride semiconductor layers comprised of the III-nitride ELO layers 105 and III-nitride device layers 107 have a long side that is perpendicular to an a-axis of the III-nitride-based semiconductor crystal.
4. During MOCVD growth, a hydrogen atmosphere can be used.

This invention can be used with a hydrogen atmosphere during a non-polar and a semi-polar growth. Using this condition is preferable because hydrogen can prevent an excessive growth at the edge of the opening area 103 from occurring in the initial growth phase.

Those results have been obtained by the following growth conditions.

In one embodiment, the growth pressure ranges from 60 to 760 Torr, although the growth pressure preferably ranges from 100 to 300 Torr to obtain a wide width for the island-like III-nitride semiconductor layers the growth temperature ranges from 900 to 1200° C. degrees; the V/III ratio ranges from 10-30,000; the TMG is from 2-20 sccm; NH₃ ranges from 0.1 to 10 slm; and the carrier gas is only hydrogen gas, or both hydrogen and nitrogen gases. To obtain a smooth surface, the growth conditions of each plane needs to be optimized by conventional methods.

After growing for about 2-8 hours, the III-nitride ELO layers 105 had a thickness of about 8-50 μm and a bar width of about 20-150 μm.

Step 3: Fabricating the Device

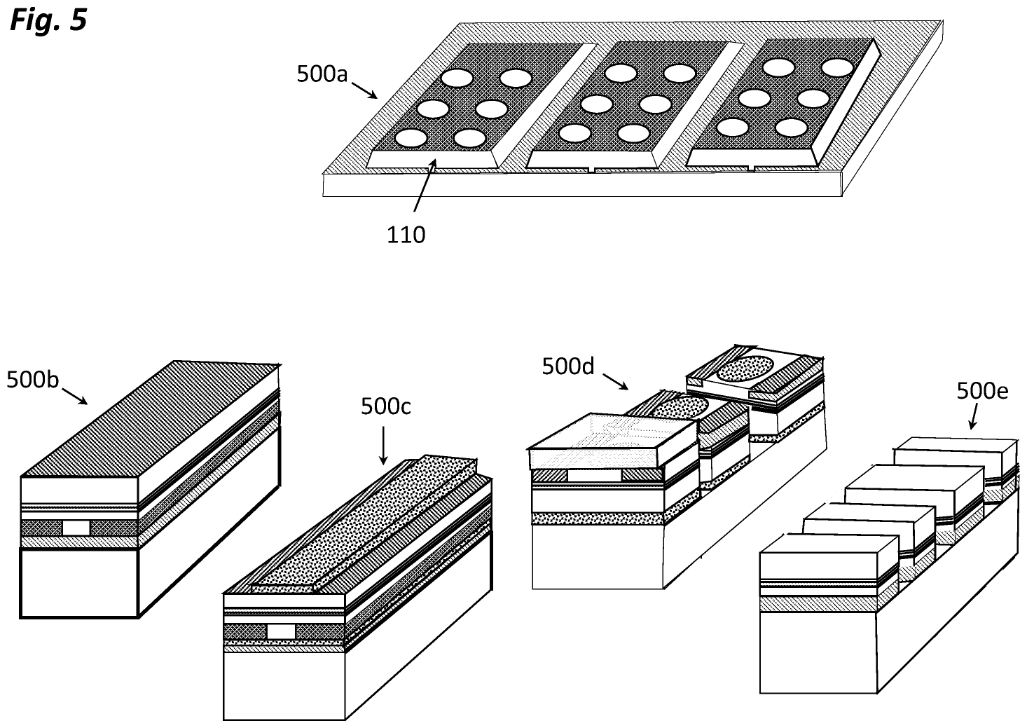

At Step 3, the device 110 is fabricated at the flat surface region 108 by conventional methods. Various device 110 designs are possible, as shown by multiple aperture devices 500a, laser 500b, edge-emitting laser 500c, VCSEL 500d, and μLED 500e in FIG. 5.

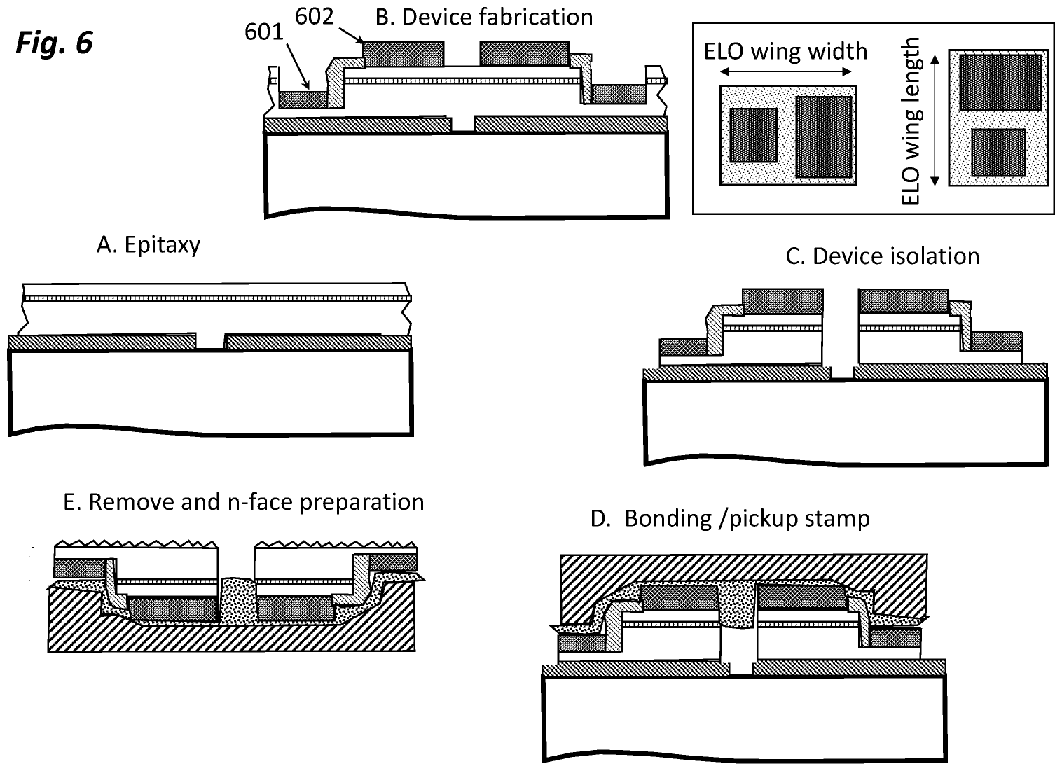

For μLEDs 500e, p-pads 601 and n-pads 602 can be fabricated either along the length or width of a wing of the III-nitride ELO layers 105, as shown in Steps A (epitaxy), B (device fabrication), C (device isolation), D (bonding/pickup stamp) and E (remove and n-face preparation) in FIG. 6.

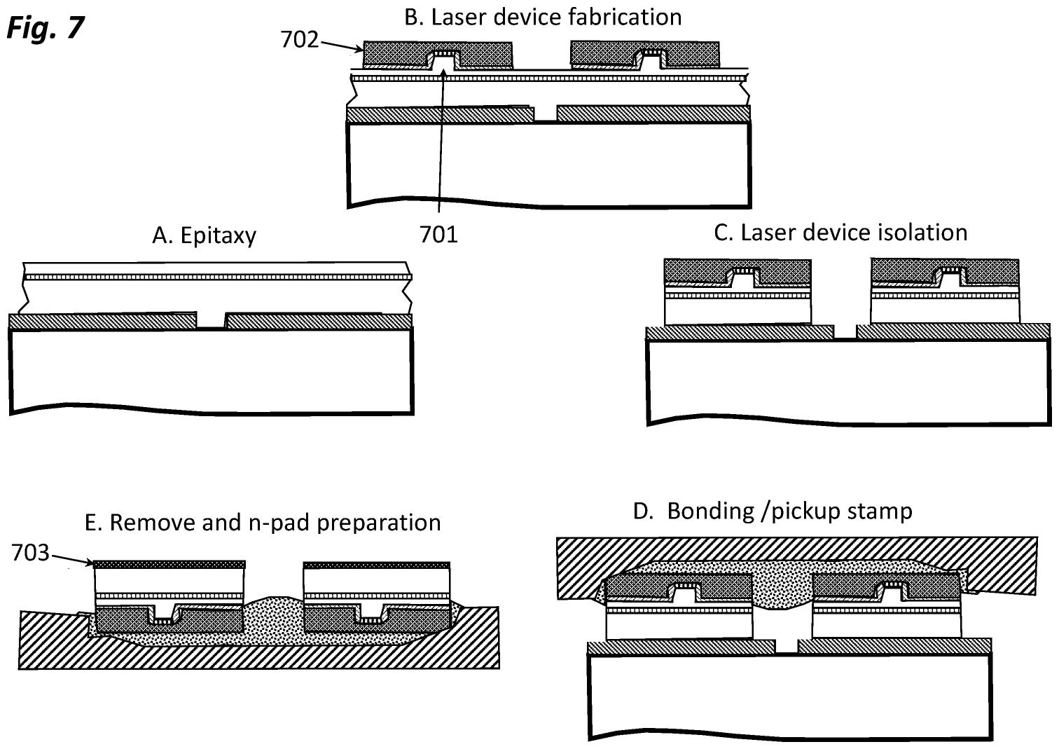

For edge-emitting lasers 500c, ridge formation 701, n-pad 702, and p-pad 703 are defined on a wing of the III-nitride ELO layers 105, as shown in Steps A (epitaxy), B (laser device fabrication), C (laser device isolation), D (bonding/pickup stamp) and E (remove and n-pad preparation) in FIG. 7.

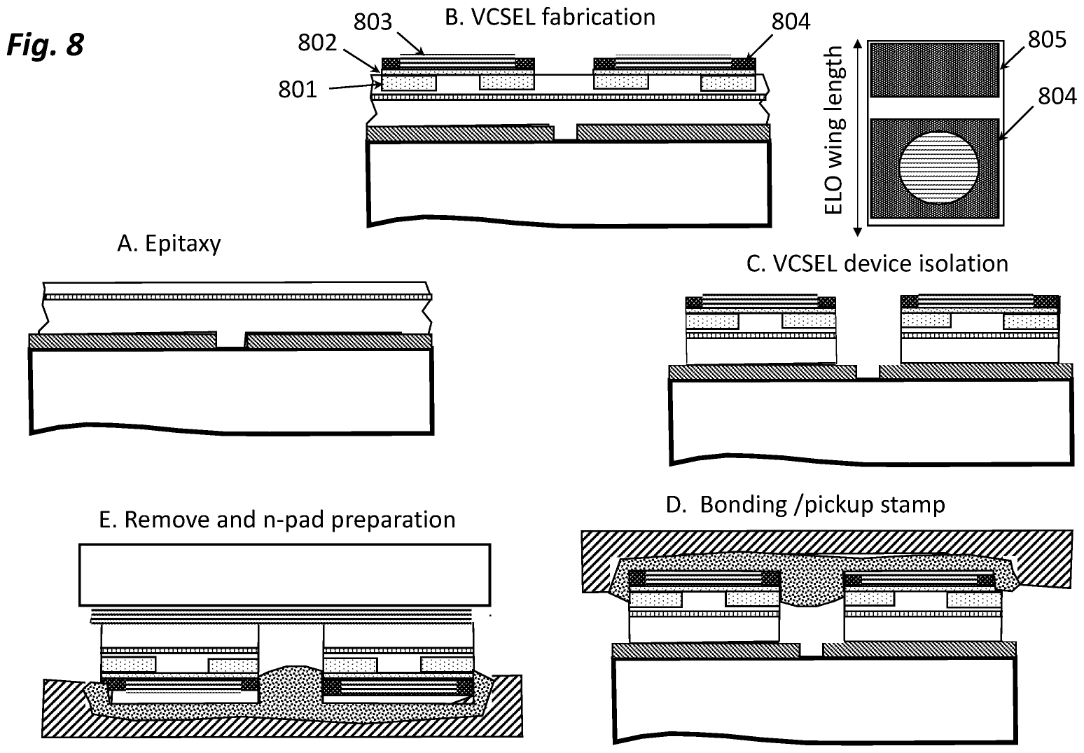

For VCSELs 500d, as shown in Steps A (epitaxy), B (VCSEL device fabrication), C (VCSEL device isolation), D (bonding/pickup stamp) and E (remove and n-pad preparation) in FIG. 8, a light reflecting mirror was designed at a designated portion of wing regions of the III-nitride ELO layers 105 by defining a current confinement region 801 on the p-GaN side. Later, a current spreading layer 802, a contact layer, for example, ITO, is deposited on the region comprising the current confinement aperture. A light reflecting DBR mirror 803 is a combination of dielectric layers with different refractive indices placed over the current confinement aperture such that contact layer lies between p-GaN and DBR. A p-pad 804 and n-pad 805 are lithographically defined.

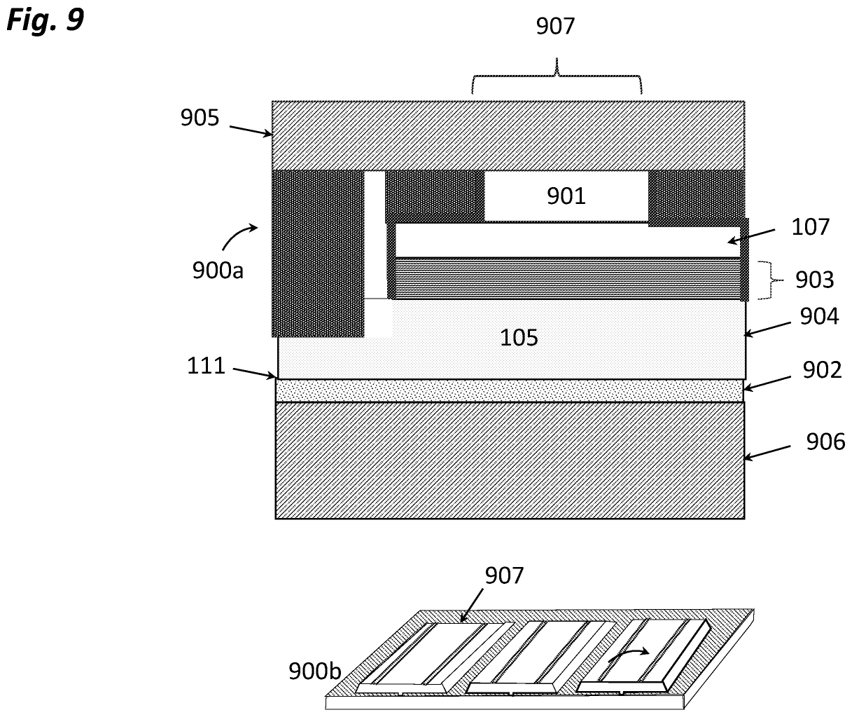

Also, for the case of unique designs, such as dual-clad edge-emitting lasers, as shown in the schematics 900a, 900b of FIG. 9, which require cladding layers 901, 902, for example, ITO and AlN, in close proximity to the gain medium 903 and waveguide 904 to confine the laser mode in the gain medium 903, and may also require additional processing after removing the III-nitride device layers 107 from the host substrate 101, for example, ridge processing. In such a scenario, for firm holding of the removed III-nitride device layers 107, a permanent bonding or a slightly stronger bonding is necessary.

In a conventional scenario of bonding a processed device wafer to a carrier wafer, wafer bowing may limit the yield; however, in this invention, bowing may not be a primary cause of yield reduction as the devices 110 are already in a relaxed state, since they were isolated from the host substrate 101.

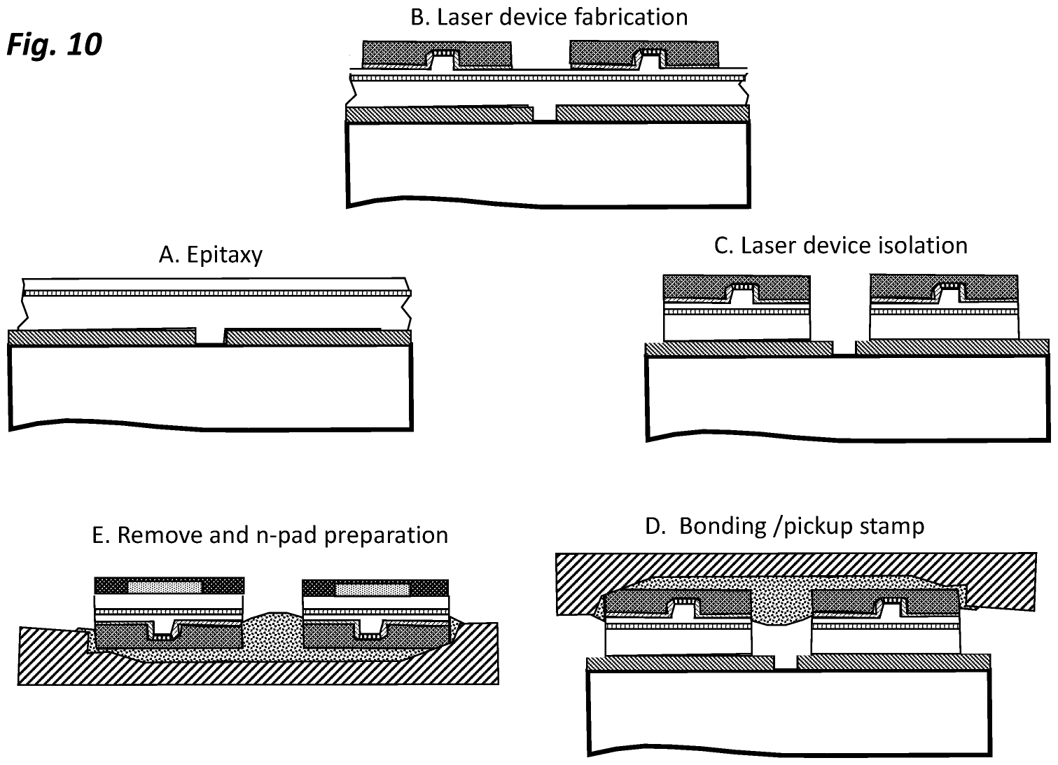

The dual-cladding 901, 902 can be realized in several alternative ways in this invention:
1. An epitaxial cladding layer 902, such as AlN, can be grown on the III-nitride ELO layers 105 before other III-nitride device layers 107 are grown. In such a scenario, isolated III-nitride device layers 107 must be bonded to a slightly stronger carrier plate 905 in order to hold the lifted III-nitride device layers 107 while performing post processing, such as polishing. Polishing the lifted III-nitride device layers 107 on the interface 111 to at least expose epitaxial cladding and then bonding to a carrier plate 906, which is a heatsink, one may realize a thin dual-cladding laser device 110, shown in FIG. 9.
2. One may also use either a vacuum chuck or a PDMS elastomer stamp to pick isolated III-nitride device layers 107 from the host substrate 101 and then perform a surface activation bonding onto an externally clad deposited carrier wafer, as shown in FIG. 10, which illustrates a process cycle of Steps A (epitaxy), B (laser device fabrication), C (laser device isolation), D (bonding/pickup stamp) and E (remove and n-pad preparation), for fabricating and releasing a III-nitride ELO layer device 110, in particular, an externally attached clad edge-emitting laser. The surface roughness of the interface 111 at the growth restrict mask 102 is smooth enough to facilitate surface activation bonding. Surface activation bonding is very helpful to avoid thermal discontinuity and unwanted light scatterings.

Step 4: Forming a Structure for Separating Device Units

The aim of this step is to prepare the III-nitride device layers 107 for isolation from the host substrate 101, wherein the III-nitride device layers 107 comprise elements such as current confinement, current spreading, DBRs, p-electrode and n-electrode. By using a selective etching mask, the III-nitride device layers 107 are separated from the host substrate 101 by etching Region 1 201 and Region 1 202 at least to expose the growth restrict mask 102.

The separation or dividing may also be performed via scribing by a diamond tipped scriber or laser scriber, for example, tools such as RIE (Reactive Ion Etching) or ICP (Inductively Coupled Plasma); but is not limited to those methods also be used to isolate device units.

Alternatively, several methods described in FIG. 3, such as placing an assist layer 301 or leaving a hook layer 302, etc., helps to prevent the isolated III-nitride device layers 107 from floating away from the host substrate 101.

There are several ways to keep the isolated III-nitride device layers 107 on the host substrate 101 before transferring them onto a separate carrier, as described below:

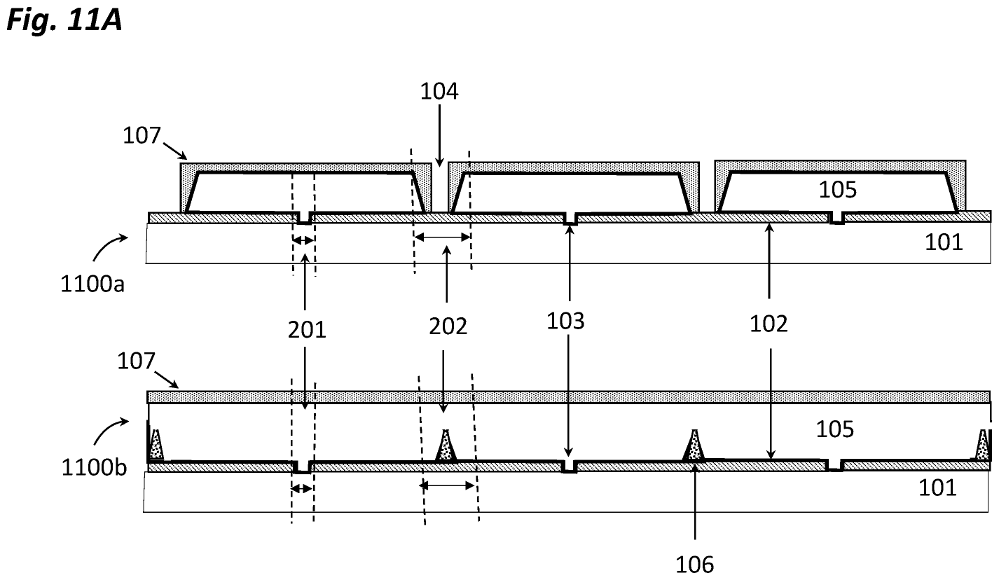

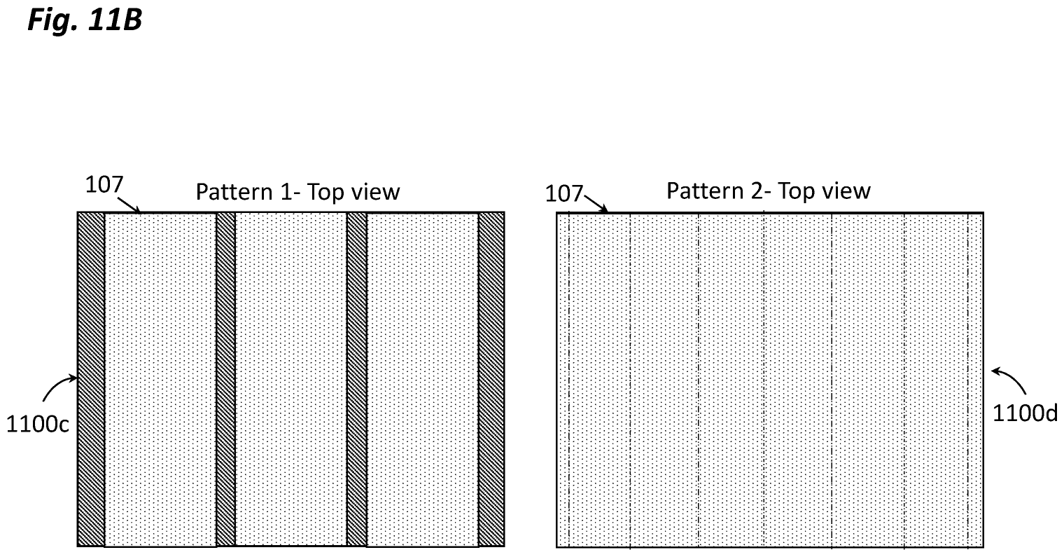

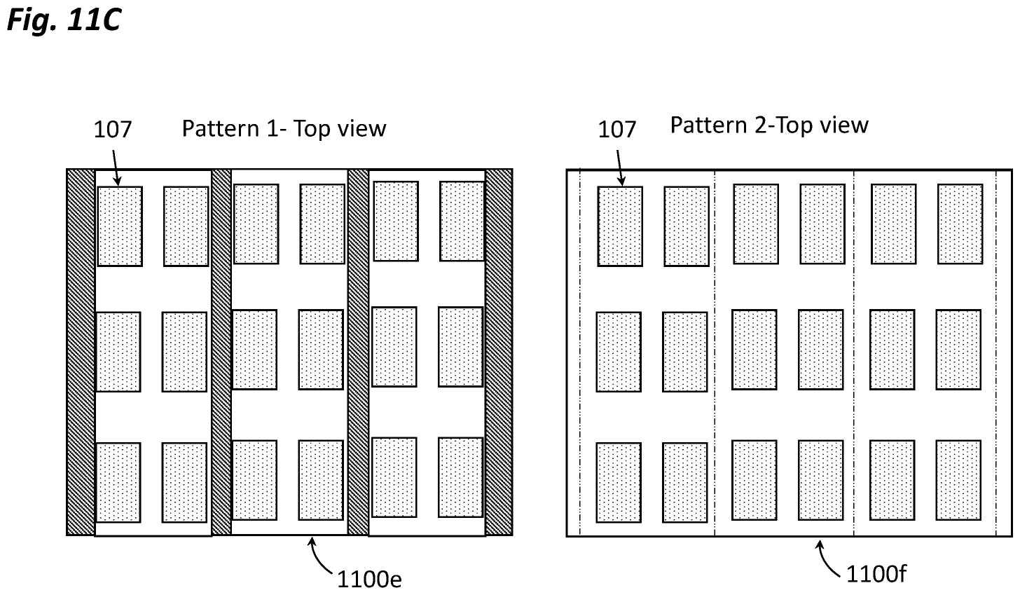

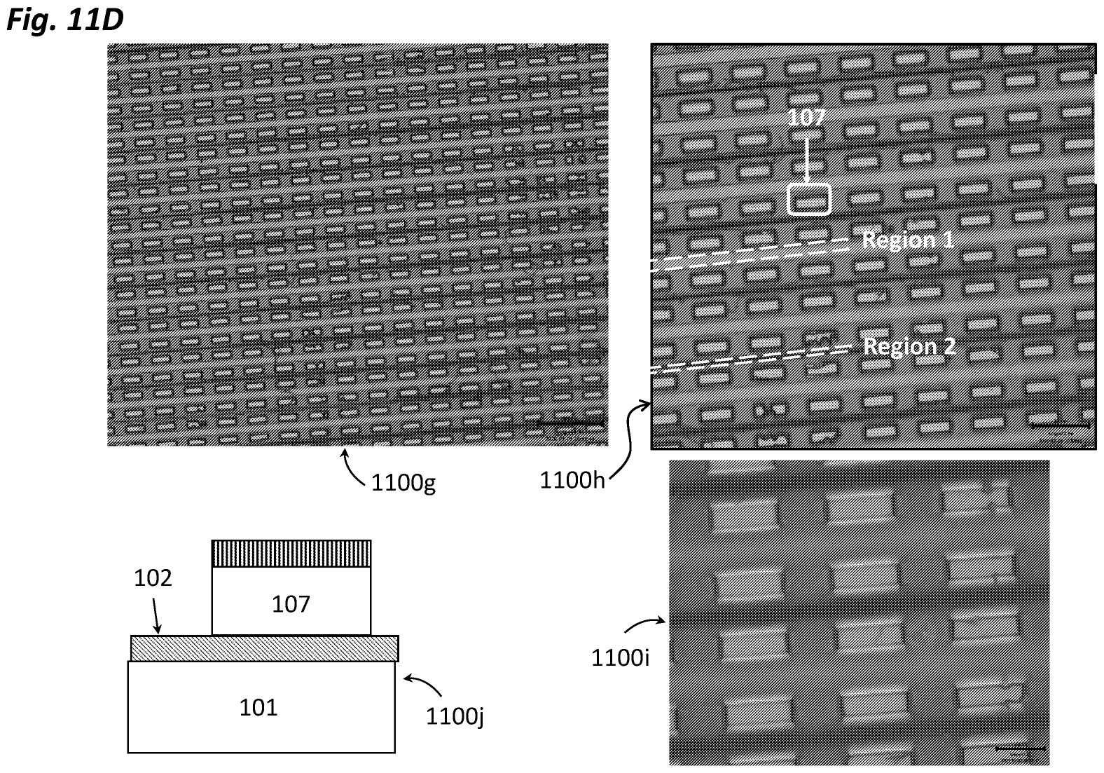

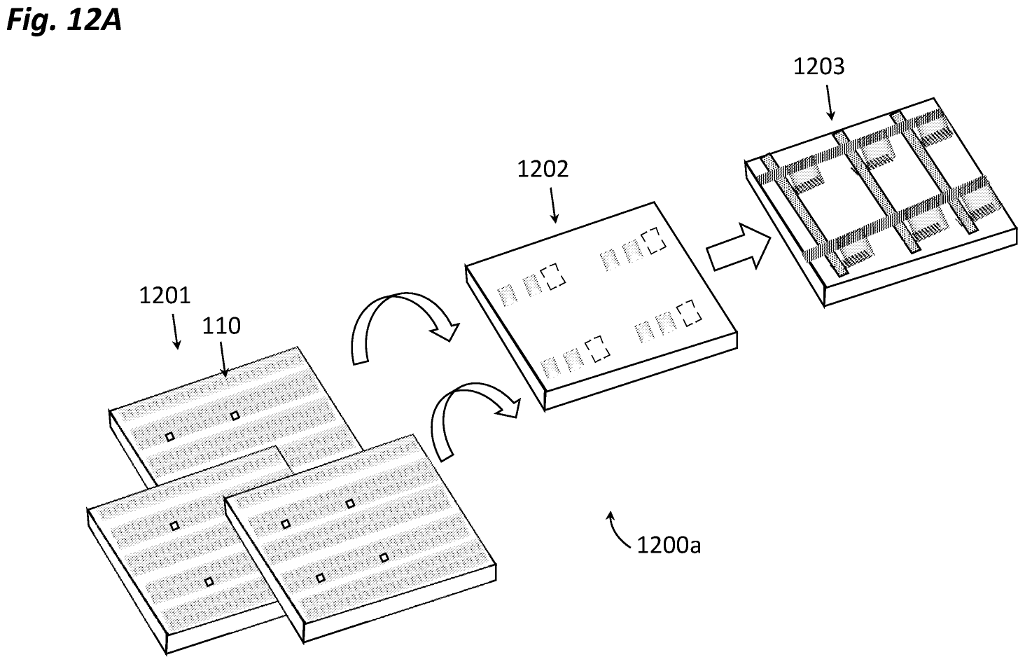

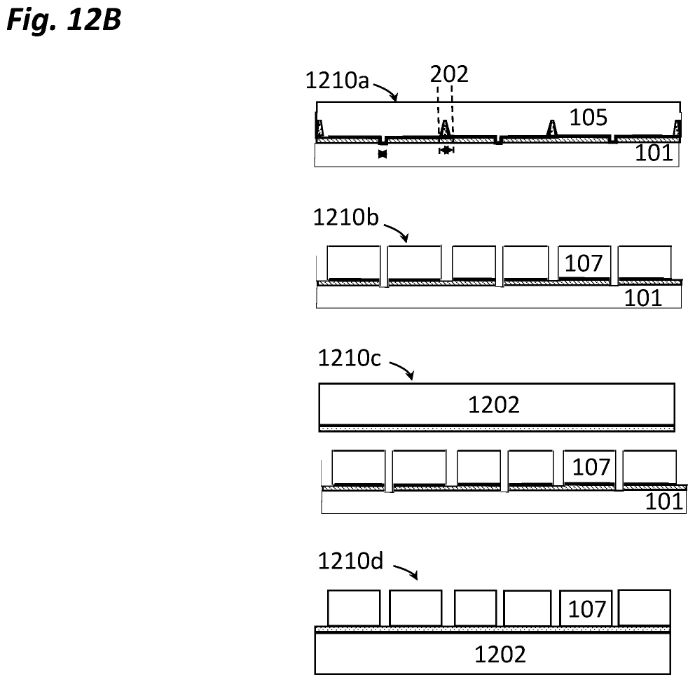

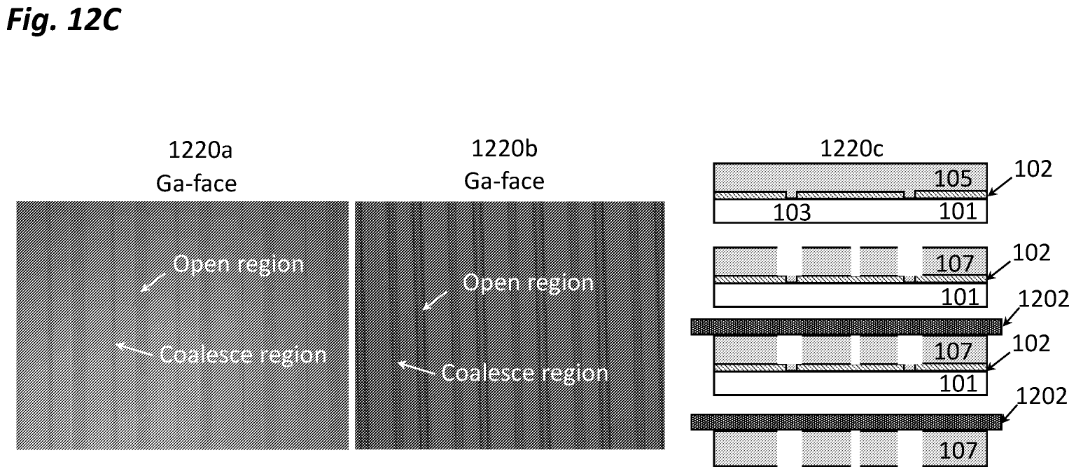

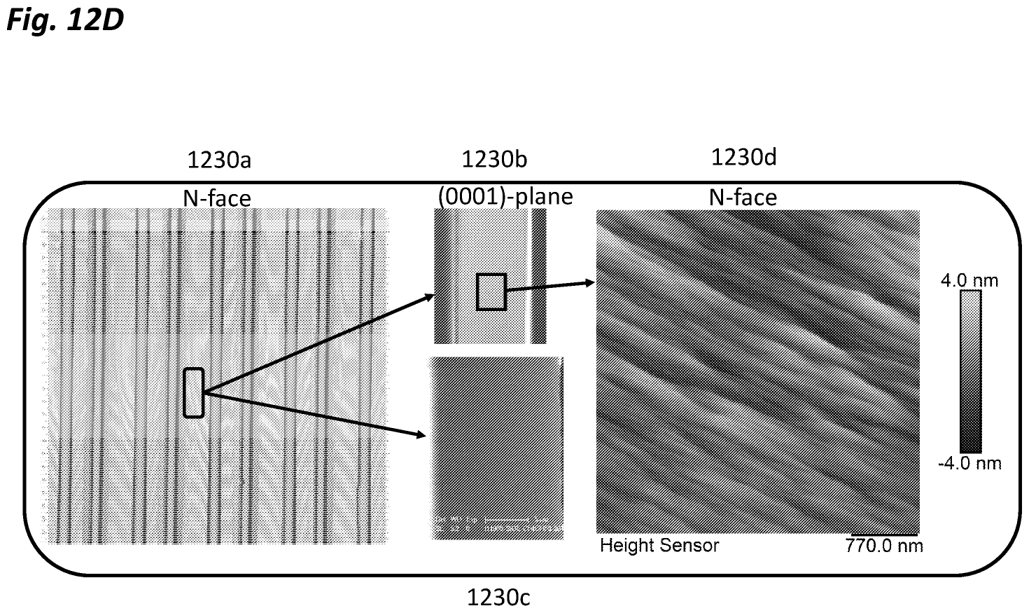

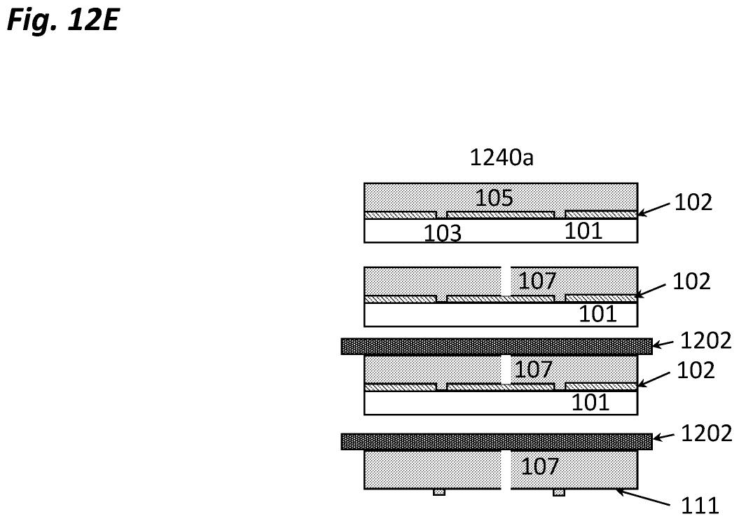

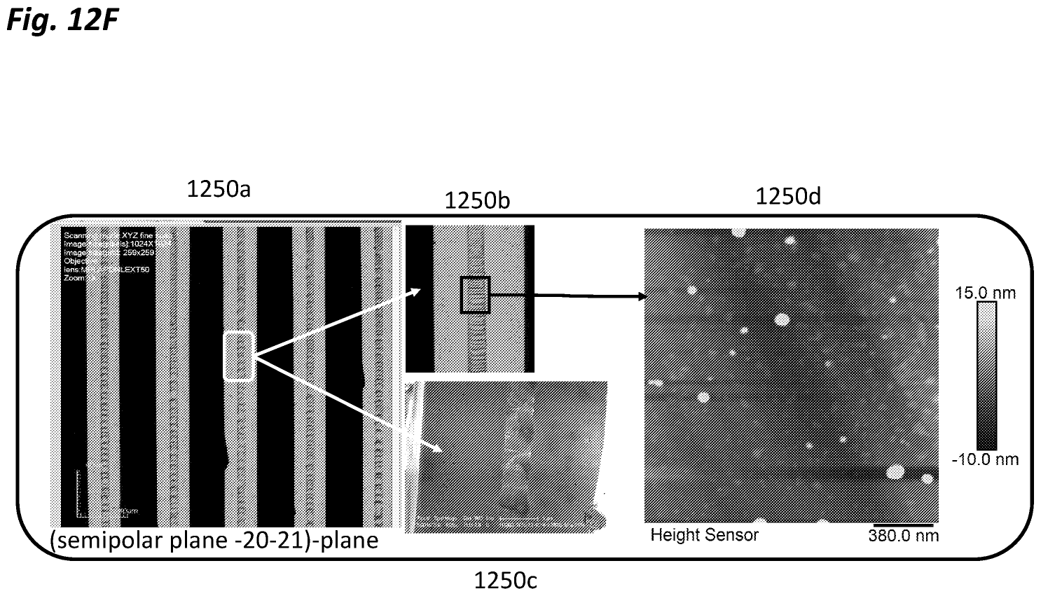

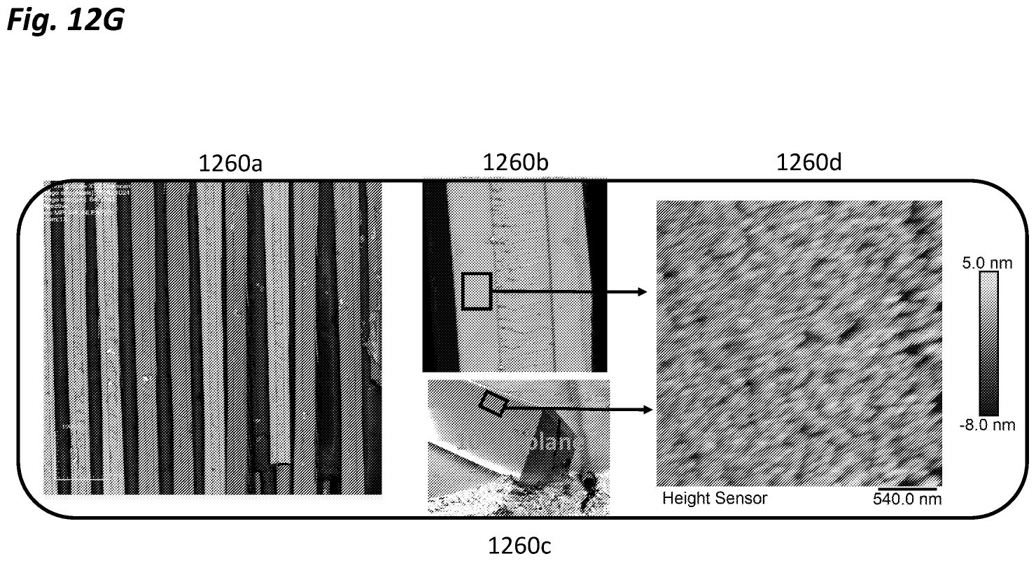

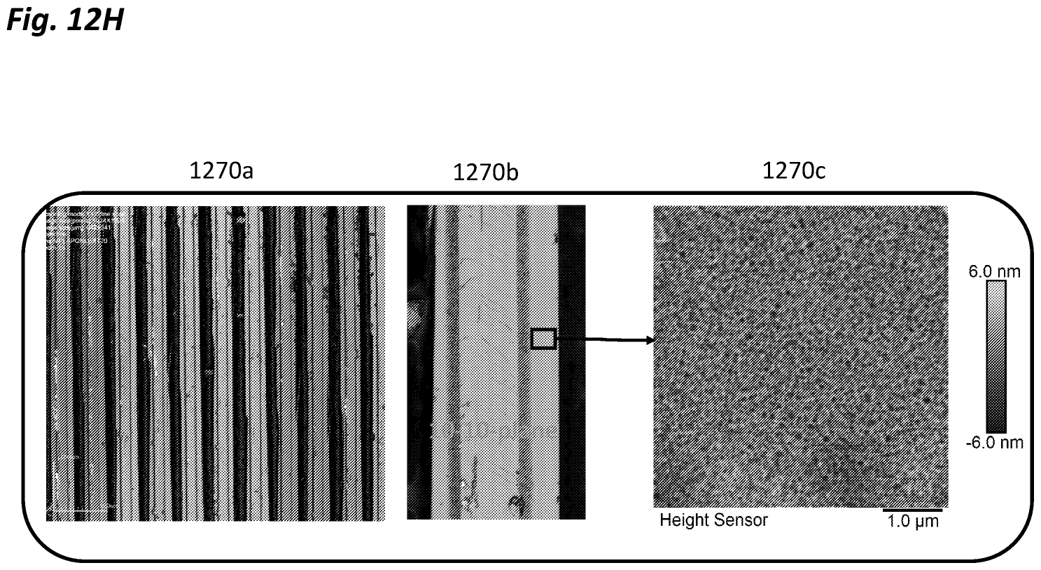

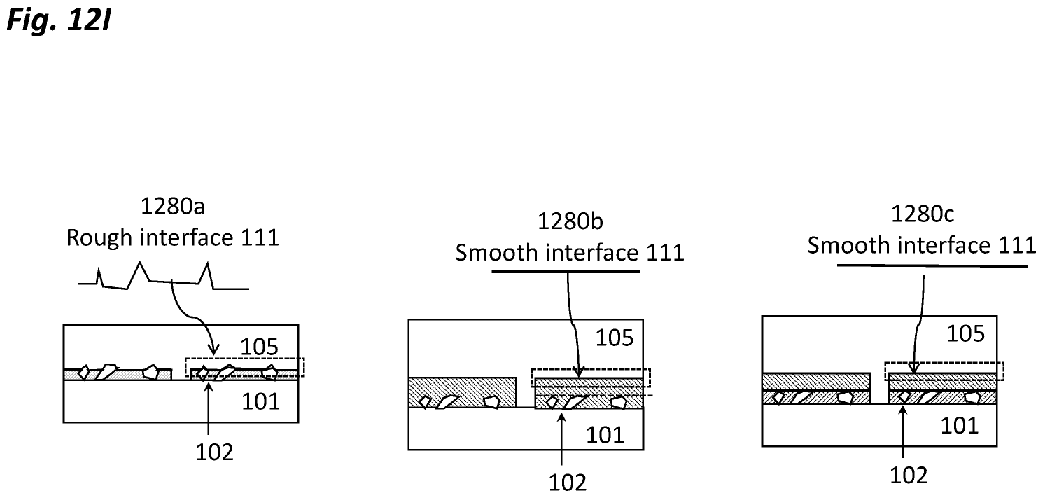

1. Without hooking:
After fabricating a desired device 110 on the wings of the III-nitride ELO layers 105. Regions 1 and 2 201, 202 are selectively etched to expose the underlying growth restrict mask 102. Even though no protection was provided to secure the isolated III-nitride device layers 107, it was found that the isolated III-nitride device layers 107 stay on the host substrate 101. It is assumed that interaction between the growth restrict mask 102 and the III-nitride ELO layers 105 at elevated temperatures during MOCVD growth might have formed a weak bond and that bond may be keeping the III-nitride device layers 107 from flying away from the host substrate 101. Schematics of the isolated III-nitride device layers 107 after exposing the underlying growth restrict mask 102 by etching Regions 1 and 2 201, 202 in Patterns 1 and 2 are shown in schematics 1100a, 1100b of FIG. 11A, schematics 1100c, 1100d in FIG. 11B, schematics 1100e, 1100f in FIG. 11C, and a coalesced version of the ELO layers 105 is shown in images 1100g, 1100h, 1100i and schematic 1100j in FIG. 11D. This invention proposes that isolated III-nitride device layers 107, in the case of no hooking, can be easily picked from their host substrate 101 either by PDMS elastomer stamps or vacuum chucks selectively and then placed onto a target carrier. This is discussed in FIGS. 12A, 12B, 12C, 12D, 12E, 12F, 12G, 12H and 121 generally, and a schematic 1200a of such is shown in FIG. 12A, wherein multicolored III-nitride devices 110 from multiple different source wafers 1201 can be picked selectively and transferred by a PDMS elastomer stamp 1202 onto a target substrate 1203, such as a patterned back panel.
Alternatively, this approach may also be used selectively pick devices 110 such as VCSELs, edge-emitting lasers to transfer onto a different carrier wafer.

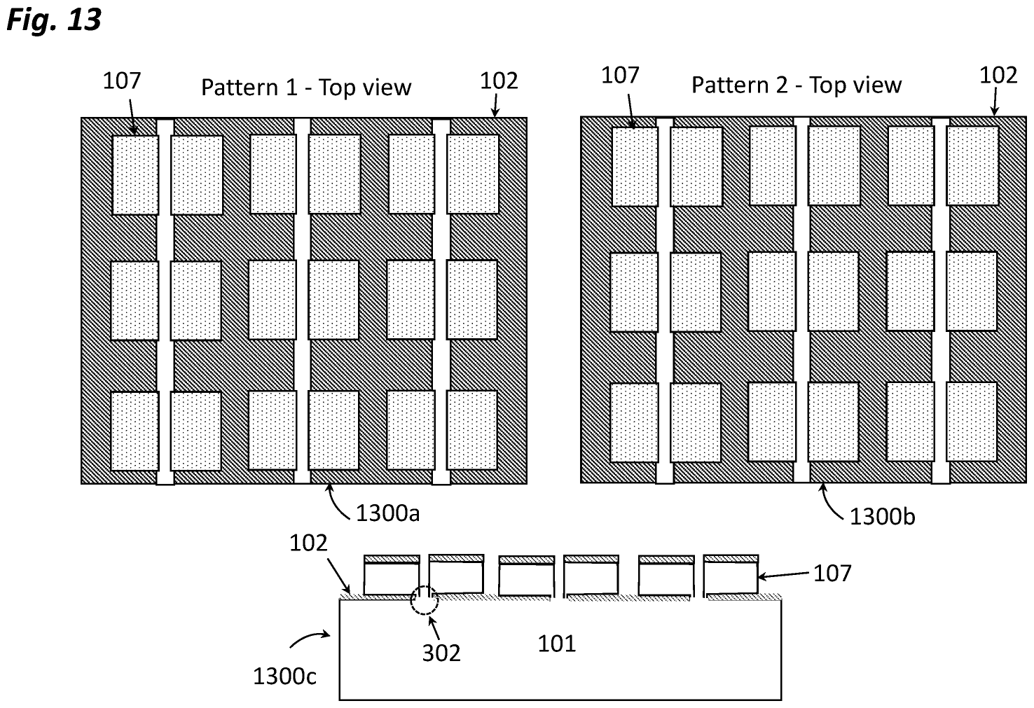

2. Hooking type 1:
It is also possible to make sure the isolated III-nitride device layers 107 stay on the host substrate 101 by modifying the growth restrict mask 102. Region 1 201, which connects the III-nitride ELO layers 105 directly with the host substrate 101, may be modified in such a way that a weak link with the host substrate 101 still remains even after exposing the growth restrict mask 102 at Region 1 202, as shown in elements 1300a, 1300b, 1300c in FIG. 13.

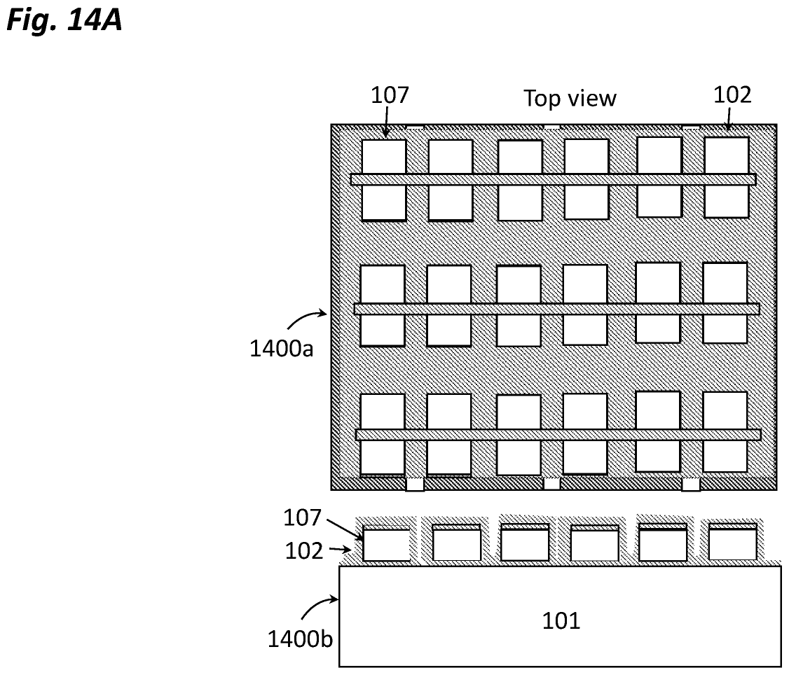

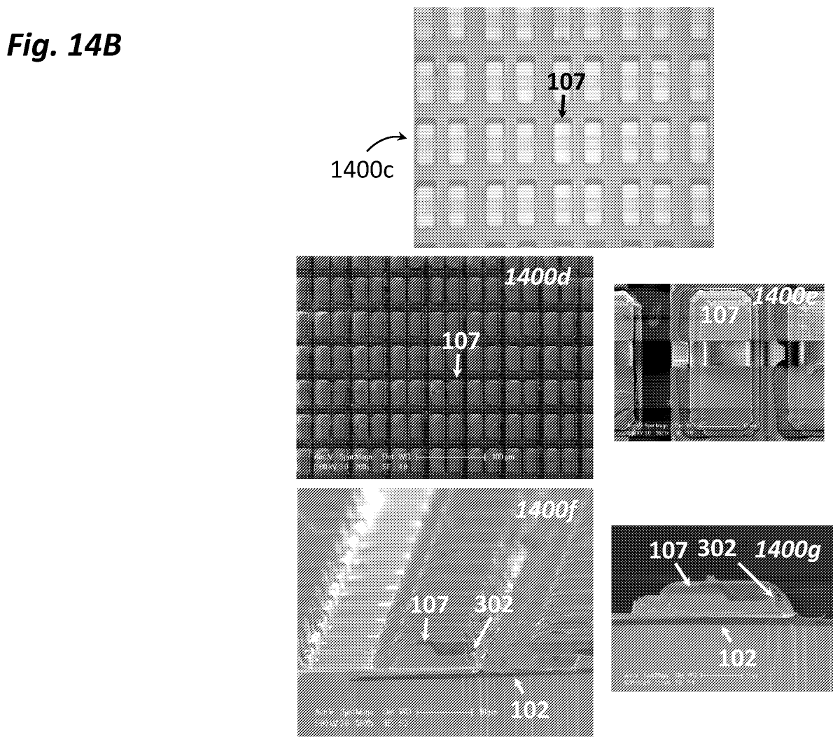

3. Hooking type 2:
This type of hooking is performed after isolating the III-nitride device layers 107 as described in the “without hooking” process. A thin layer of the hook layer 302, which preferably is a similar material as the growth restrict mask 102, is placed over the III-nitride device layers 107, as indicated in schematics 1400a, 1400b, and images 1400c. 1400d, 1400e, 1400f, 1400g in FIGS. 14A and 14B. This hook layer 302 anchors the III-nitride device layers 107 from being flown away from the substrate 101. The strength of the hook layer 302 can be controlled by its thickness.

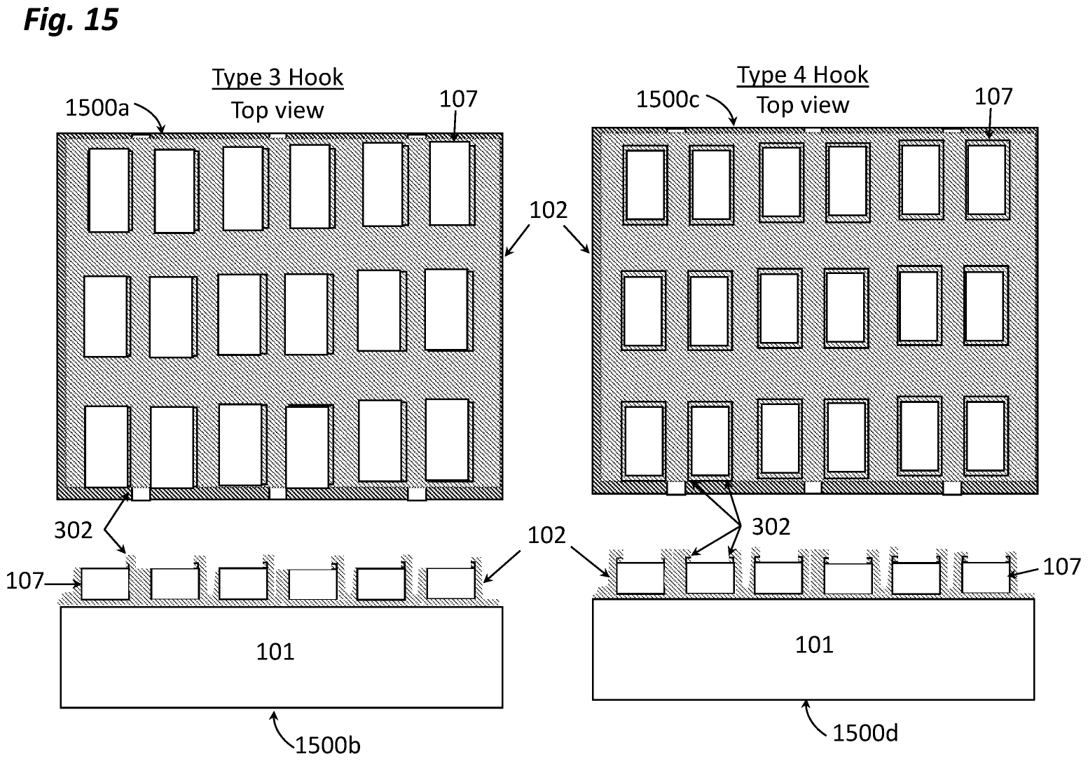

4. Hooking Type 3 and Type 4:
Type 3 and Type 4 Hooks are shown in the schematics of 1500a. 1500b, 1500c, 1500d in FIG. 15, and comprise an extension to Type 2 Hooks. Alternatively, the hooking layer 302 pattern can be modified in several ways to secure the III-nitride device layers 107. The hooking layer 302 must be anchored to at least one side of the III-nitride device layers 107 as indicated in schematics 1500a, 1500b for Type 3 or may be fully secured to all the sides of the III-nitride device layers 107 as indicated in schematics 1500c, 1500d for Type 4.

Step: 5. III-Nitride Device Layers are Removed from the Substrate

The assist layer 301 and hook layer 302 is very delicate, and thus ultrasonic waves or a small impact are enough to break the layers 301, 302; alternatively, one may use chemical treatment to release the layers 301, 302. The III-nitride device layers 107 with or without the assist layer 301 or hook layer 302 may be transferred from their host substrate 101 using one or more of the following methods:

1. Elastomer stamps (PDMS stamps):
As shown in schematic 400d in FIG. 4, PDMS stamps are flexible to pick the isolated III-nitride device layers 107 from their host substrate 101. One may also pick selectively in order to transfer the III-nitride device layers 107 onto a target substrate, such as a back panel, as indicated by schematic 1200a in FIG. 12A.

2. Vacuum chuck:
This invention proposes a new way to pick isolated III-nitride device layers 107 from their host substrate 101. As the III-nitride device layers 107 have a very weak or no connection to the host substrate 101, it is simple to use a vacuum controlled chuck, as shown in schematic 400e in FIG. 4, to remove these III-nitride device layers 107. In addition, a local repair may be performed by selective picking using a vacuum chuck.

3. Spin-on-Glass (SoG) resist:
As the isolated III-nitride device layers 107 are front-end processed, their surface is smooth; however, small variations in the surface elevation in the isolated III-nitride device layers 107 can be neglected when a spin-on-glass (SoG) material is used for planarization. Also, it is helpful when SoG materials are used to bond the isolated III-nitride device layers 107, further robust processes, such as polishing or resist reflow at elevated temperatures, can be performed on the growth restrict mask 102 and the interface 111 of the III-nitride ELO layers 105.
A demonstration of picking of the isolated III-nitride device layers 107 using SoG is shown as schematics 1210a, 1210b, 1210c, 1210d, in FIG. 12B, wherein schematic 1210a shows coalesced III-nitride ELO layers 105, schematic 1210b shows isolated III-nitride device layers 107 after removing Regions 1 and 2 201, 202, schematic 1210c shows SoG on sapphire substrate 1202 attached to the isolated III-nitride device layers 107, and schematic 1210d shows the III-nitride device layers 107 attached to the SoG on sapphire substrate 1202.
In a first step, a coalesced version of the III-nitride ELO layers 105 is grown on a patterned host substrate 101. In a second step. Region 1 201 and Region 1 202 are removed using dry etching at least to expose the growth restrict mask 102. This embodiment does not use an assist layer 301 or hook layer 302 to hold the isolated III-nitride device layers 107 after etching.
Then, a separate carrier substrate, for example, sapphire, is coated with SoG material and the separate carrier substrate with SoG is placed over the isolated III-nitride device layers 107 containing the host substrate 101 and kept in a temperature furnace for oxidation at 300° C. to 450° C. The isolated III-nitride device layers 107 were successfully transferred onto the separate carrier substrate with SoG, exposing the III-nitride ELO layers 105 and the interface 111 with the growth restrict mask 102. The surface roughness of the interface 111 was found to be less than 1 nm for a scan over 5 μm×5 μm using Atomic Force Microscopy (AFM).
Moreover, a carrier containing an epitaxial DBR, such as AlN/GaN DBR pairs on SiC, or an epitaxial structure, or deposited cladding layers, such as AlN/SiC or Cu, may be attached to the interface 111 using surface activation bonding. More details of such process can be found in Step 6. This process can use any material such a liquid or a gel, which are hardened by heating or UV irradiation and so on after bonding.

4. Permanent bonding:
Devices 110 that may require polishing, or a DBR mirror, or external cladding layers, can be attached directly to the isolated III-nitride device layers 107. In this case, one may attach the carrier for the DBR mirror or external cladding layers directly to the III-nitride device layers 107 on the host substrate 101, or onto a separate carrier using SoG materials. Depending on the type of device 110 one may choose a suitable process.
Edge-emitting lasers may be permanently bonded from the host substrate 101 through an intermediate layer onto a heatsink carrier wafer.
In this step, a heat sink plate comprised of AlN is prepared. An Au—Sn solder is disposed on the heat sink plate, the heat sink plate is heated over the melting temperature of the solder, and the isolated III-nitride devices 110 on the host substrate 101 are bonded to the heat sink plate using the Au—Sn solder. The devices 110 can be mounted on the heat sink plate in two ways: (1) an n-electrode can be prepared separately on the backside, at the interface 111 of growth restrict mask 102 and the III-nitride ELO layers 105, or (2) a p-electrode is directly attached, which results in a junction-down configuration.

Steps 6-11: Post-Processing of Devices after Separation from the Host Substrate

Some devices 110, such as micro-cavity LEDs, dual-clad edge-emitting lasers, or VCSELs, need to utilize the surface of the interface 111 or an n-type layer of the III-nitride device layers 107. Generally, several researchers utilize the backside of the host substrate 101 by thinning to a level where there is a negligible absorption of entering light. However, it is preferred to remove unwanted absorption and introducing controllable doping on an n-side of the device 110, which is only possible when the III-nitride device layers 107 are controlled epitaxially. In this invention, since only the III-nitride device layers 107 that are grown epitaxially are used, there are a number of advantages:
1. Epitaxial doping control is possible for a cavity layer.
2. Homogeneous substrates 101 can be used.
3. When the III-nitride device layers 107 are grown on a heterogenous substrate 101, either a laser liftoff or chemical liftoff must be used to selectively pick the III-nitride device layers 107, which will induce damage into the cavity layer and limit the design space. However, the approach of this invention of removing the III-nitride device layers 107 will not induce damage into the cavity layer or limit the design space.
4. Epitaxial layers grown on the wings of the III-nitride ELO layers 105 are generally of better quality as compared to epitaxial layers grown directly on the host substrate 101.
5. The III-nitride device layers 107 on an n-side of the device 110 have an interface 111 with the growth restrict mask 102, which is crystal orientation independent. For example, when a chemical lift off, such as photo electrical chemical etching (PEC), is utilized when removing the III-nitride device layers 107 from the substrate 101, the surface roughness of the interface 111 is crystal orientation dependent. In the case of III-nitride device layers 107 comprised of c-polar GaN, the interface 111 is N-polar, which is roughened by PEC etching with KOH. However, in this invention, the surface of the interface 111 only depends on the surface of the growth restrict mask 102.
6. Even if the surface of the interface 111 is not utilized, a dry etch, or chemical etch, or polishing, may be used on the interface 111 to obtain a desired value for the surface roughness, instead of polishing the whole host substrate 101 from the backside.
7. The surface roughness of the growth restrict mask 102 and the interface 111 with the III-nitride ELO layers 105 is at a nanometer level, e.g., <2 nm, which can even be manipulated by the material and thickness of the growth restrict mask 102. This surface is smooth enough to employ surface activation bonding with a DBR or cladding layer.
8. Dual-clad lasers need a cladding layer, for example, AlN. The greater the Aluminum composition or thickness, the greater the chances of cracking, thereby effecting the epitaxial quality of the device 110. Therefore, an epitaxial cladding layer prepared separately as a template can be directly attached to the isolated edge-emitting laser device 110 after picking the device 110 from the host substrate 101. Alternatively, a cladding layer may be epitaxially grown directly on the III-nitride ELO layers 105, since the III-nitride ELO layers 105 must be relaxed in a non-coalesced form, and are more strain relaxed as compared to the host substrate 101, thereby allowing a larger composition of Aluminum or thicker Aluminum layers without cracking.
The surface roughness of the interface 111 between the growth restrict mask 102 and the III-nitride ELO layers 105 is in the nanometer range (<2 nm) and the surface of the interface 111 is independent of the crystal orientation of the host substrate 101. The interface 111 for various crystal orientations are shown in images 1220a and 1220b, and schematic 1220c in FIG. 12C; images 1230a. 1230b, 1230c, and 1230d in FIG. 12D; schematic 1240a in FIG. 12E; images 1250a, 1250b, 1250c, 1250d in FIG. 12F; images 1260a, 1260b, 1260c, 1260d in FIG. 12G; images 1270a. 1270b, 1270c in FIG. 12H; and schematics 1280a, 1280b, 1280c in FIG. 12I. The surface of the growth restrict mask 102 only replicates on the III-nitride ELO layers 105. The surface morphology of the interface 111 can be controlled by characteristics of the growth restrict mask 102 and growth parameters of the III-nitride ELO layers 105.

FIGS. 12C, 12D, 12F, 12G and 12H include images of the surface of the interface 111, Specifically, images 1230a, 1230b, 1230c, 1230d, 1250a, 1250b, 1250c, 1250d, 1260a, 1260b, 1260c, 1260d, 1270a, 1270b, 1270c, represent experimental results of three different crystal orientations, namely, polar c-plane (1000), semipolar (20-21) and nonpolar (10-10), as well as a thinner growth restrict mask 102, a thicker growth restrict mask 102, and a multilayered growth restrict mask 102, respectively.

Images 1220a, 1220b and schematic 1220c in FIG. 12C illustrate the results obtained by implementing a removal method described in this invention. In these results, the III-nitride ELO layers 105 and III-nitride device layers 107 are grown from polar c-plane substrate 101, the III-nitride ELO layers 105 and III-nitride device layers 107 are etched to expose the growth restrict mask 102, a carrier is attached to the III-nitride device layers 107, and the III-nitride ELO layers 105 and III-nitride device layers 107 are removed from the substrate 101.

Images 1230a, 1230b, 1230c, 1230d in FIG. 12D show the transferred III-nitride ELO layers 105 comprised of c-plane III-nitrides. The growth restrict mask 102 in this case was 1 μm thick SiO₂. Image 1230a in FIG. 12D is a back surface of the III-nitride ELO layers 105.

The surface shown in the image 1230a is an N-polar surface, which, in principle, when exposed to chemicals, such as potassium hydroxide (KOH), will become rough. For example, when a PEC etching method is used to remove Ga-polar semiconductor layers, the surface which is exposed to the chemicals cannot be used to make DBR mirrors. In this method, the as-grown III-nitride ELO layers 105 on the growth restrict mask 102 are used to make the DBR mirrors.

Magnified images of the surface of the interface 111 viewed through a laser microscope are shown in image 1230b, and an image taken using a Secondary Electron Microscope (SEM) is shown in image 1230c. Atomic force microscopy (AFM) conducted on the surface of the interface 111 resulted in the image 1230d. The surface roughness was found to be from sub-nanometer to 1 or 2 nanometers, which are best for placing a second DBR mirror to complete a resonant cavity of a VCSEL device 110.

Schematics 1240a in FIG. 12E, images 1250a, 1250b, 1250c, 1250d in FIG. 12F, images 1260a, 1260b, 1260c, 1260d in FIG. 12G, and images 1270a, 1270b. 1270c in FIG. 12H show the results of removed as-grown III-nitride ELO layers 105 from semipolar 20-21 and nonpolar 10-10 substrates 101.

Images 1250a, 1250b, 1250c, 1250d in FIG. 12F are images of the transferred III-nitride ELO layers 105 from the semipolar 20-21 plane substrate 101. The growth restrict mask 102 in this case was 0.2 μm thick SiO₂.

Image 1250a is a back surface of the III-nitride ELO layers 105, and more specifically, a 20-21 surface.

A magnified image of the surface of the interface 111 viewed through a laser microscope is shown in image 1250b and an SEM image is shown in image 1250c. An AFM image conducted on one of the back surfaces, particularly on a wing region of the III-nitride ELO layers 105, is shown in image 1250d. The surface roughness was found to range from sub-nanometer to a few nanometers, which are best for placing a second DBR mirror to complete a resonant cavity of a VCSEL device 110.

Similarly, images 1260a, 1260b, 1260c, 1260d in FIG. 12G represent the transferred III-nitride ELO layers 105 comprised of a nonpolar 10-10 plane. The growth restrict mask 102 in this case was 1 μm thick SiO₂. Image 1260a is a back surface of the III-nitride ELO layers 105, which is a 10-10 surface. In this method, the as-grown III-nitride ELO layers 105 on the growth restrict mask 102 are used to make DBR mirrors.

A magnified image of the surface of the interface 111 viewed through a laser microscope is shown in image 1260b and a SEM image is shown in image 1260c. An AFM image conducted on one of the back surfaces, particularly on a wing region of the III-nitride ELO layers 105, is shown in image 1260d. The surface roughness was found to be from sub-nanometer to a few nanometers, which are best for placing a second DBR mirror to complete a resonant cavity of a VCSEL device 110.

Images 1270a, 1270b, 1270c in FIG. 12H represent transferred III-nitride ELO layers 105 of nonpolar 10-10 plane. The growth restrict mask in this case was a multi-layer of 50 nm SiN and 1 μm thick SiO₂, where the SiN faces the interface of the ELO surface. Image 1270a is a back surface of the III-nitride ELO layers 105. The surface shown in the image is a back surface of the 10-10 surface. In this method, as-grown III-nitride ELO layers 105 on the growth restrict mask are used to make the DBR mirrors.

A magnified image of the surface of the interface 111 viewed through a laser microscope is shown in image 1270b. An AFM image conducted on the surface, particularly on a wing region of the III-nitride ELO layer 105, is shown in image 1270c. The AFM results of images 1260d and 1270c indicate the surface roughness of the wings of the III-nitride ELO layers 105 when they lie on SiO₂ and SiN, respectively. On the SiN surface, the III-nitride ELO layers 105 have finer grain structure as compared to III-nitride ELO layers 105 on the SiO₂ surface. The surface roughness was found to be from sub-nanometer to a few nanometers, which are best for placing a second DBR mirror to complete a resonant cavity of a VCSEL device 110.

As explained above, the growth restrict mask 102 may have an influence on the back surface. However, controlling the interface 111 when chemicals are not involved is a much simpler way of doing things than chemically or mechanically polishing, or PEC etching. Preferably, yields at the interface 111 can be improved using thicker growth restrict masks 102 and/or multiple growth restrict masks 102.

Alternatively, placing metal-layers on top of growth restrict mask 102, which can withstand the temperatures used for forming the III-nitride ELO layers 105, may give a mirror-like finish at the interface 111 of the removed III-nitride ELO layers 105. The interface 111 at the wings of the removed III-nitride ELO layers 105 can later be used to place a second DBR mirror for the resonant cavity of the VCSEL 110.

This invention helps in obtaining better crystal quality and smoother surfaces for DBR mirrors of the resonant cavity of VCSEL devices 110. Also, this approach is independent of crystal orientation, whereas other techniques are either tedious, chemically sensitive to crystal orientations, or less tolerances for mass production.

The essence of this invention lies not only in using ELO technology to obtain better crystal quality for the device layers 107, and smooth interfaces for DBR mirrors of the resonant cavity, but also to control cavity thickness and recycle expensive host substrates 101, for example, III-nitride substrates 101. Also, without having an intermediate layer, a second DBR mirror layer, preferably epitaxial grown, conducting and better thermal performing, can be attached to the interface 111 by surface activation bonding.

Case 1: As shown in the rough surface 1280a of the interface 111 in FIG. 12I, a thinner growth restrict mask 102, for example, a thickness of 10 nm-50 nm, may deteriorate at higher MOCVD growth temperatures while performing the epitaxial lateral overgrowth. In this case, interdiffusion between the 11-nitride ELO layers 105 and the substrate 101 or an underlayer below the growth restrict mask 102 may occur though the growth restrict mask 102, thus producing non-controllable open areas (pits or small voids) in the growth restrict mask 102. These non-controllable open areas can be refilled along with the pre-determined opening area 103 during the growth of the III-nitride ELO layers 105, resulting in connecting paths between the substrate 101 and III-nitride ELO layers 105. The diffused epitaxial layers at these non-controllable open areas may result in a rough interface 111. In this case, the yield having a smooth surface at the interface 111 at the wings of the removed III-nitride ELO layer 105 may be reduced.

Case 2: As shown in the smooth surface 1280b of the interface 111 in FIG. 12I, a thicker growth restrict mask 102, for example, a thickness of 100 nm-1000 nm, or more typically 1000 nm, can restrict a deteriorated region to within the growth restrict mask 102, such as a damaged region, at a higher MOCVD growth temperatures while performing epitaxial lateral overgrowth. Thus, non-controllable open areas can be eliminated by increasing the height of the growth restrict mask 102, which translates to a better interface between the III-nitride ELO layer 105 and the growth restrict mask 102.

Case 3: Alternatively, as shown in the smooth surface 1280c of the interface 111 in FIG. 12I, instead of a thicker growth restrict mask 102, a combination of growth restrict masks 102 will also function as Case 2. One growth restrict mask 102 may be used for easy liftoff, for example, SiO₂, and another growth restrict mask 102 may be used for stability at higher temperature, for example, SiN, resulting in a combined growth restrict mask 102. A combined thickness of 100 nm-1000 nm or more is preferred, and typically 1000 nm. By choosing a thermally stable growth restrict mask 102 at the interface 111 of the III-nitride ELO layers 105, a better surface can be obtained for the interface 111 on the removed devices 110.

(a) Attaching a Cladding Layer

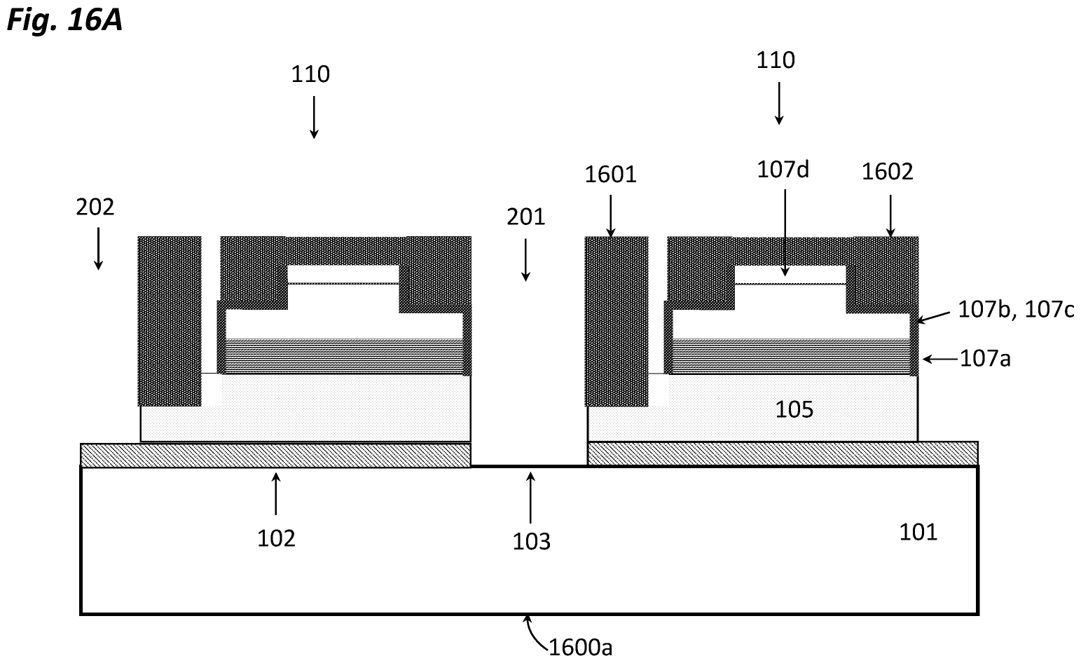

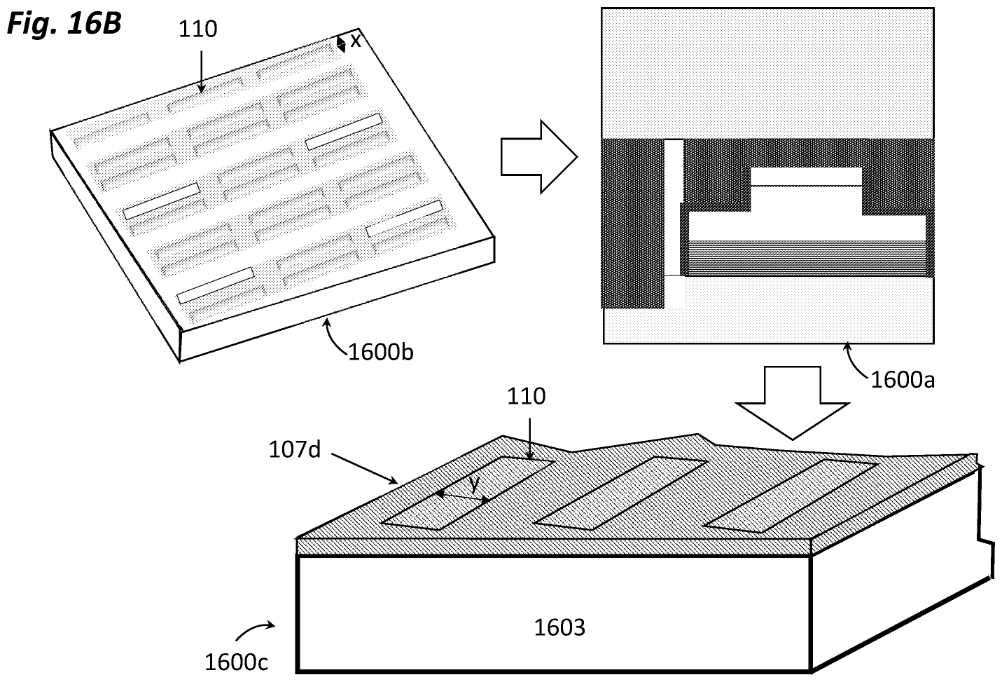

A low refractive index cladding layer, for example, AlN, may be attached onto the interface 111 of the growth restrict mask 102 and the III-nitride ELO layers 105 after picking the isolated III-nitride ELO layers 105 and III-nitride device layers 107 from the host substrate 101. Schematic 1600a in FIG. 16A shows fabricated and isolated III-nitride laser devices 110 on the host substrate 101, that includes III-nitride device layers 107 deposited on or above the n-type III-nitride ELO layers 105, wherein the III-nitride device layers 107 include active region 107a, p-type layer 107b, electron blocking layer (EBL) 107c, and cladding layer 107d, as well as other layers. An n-contact 1601 and p-contact 1602. Etched Regions 1 and 2 201, 202 are also shown.

FIG. 16B includes schematic 1600b of a picking process for the device 110 and schematic 1600c of reattaching the device 110 onto a heatsink carrier substrate 1603. Conventional laser structures where cladding layers 107d are epitaxially integrated into the device layers 107 can be used, and then a plate that can be used as the heatsink carrier 1603 is attached. Picking and re-attaching the devices 110 onto the heatsink carrier 1603 adds an advantage of allocating a larger size to the device 110. For example, as indicated in FIG. 16B, more space y can be allocated to the device 110, even when lateral dimensions of the device 110 are smaller, when reattaching it onto the carrier plate 1603, which helps in improving thermal stability by spreading heat to more area and thereby removes heat efficiently.

Alternatively, instead of picking and placing devices 110 onto a desired position, one may directly attach the heatsink carrier 1603 onto a selected number of devices 110 picked using a SoG or permanent bonding method.

(b) Attaching a DBR Mirror for VCSEL Device

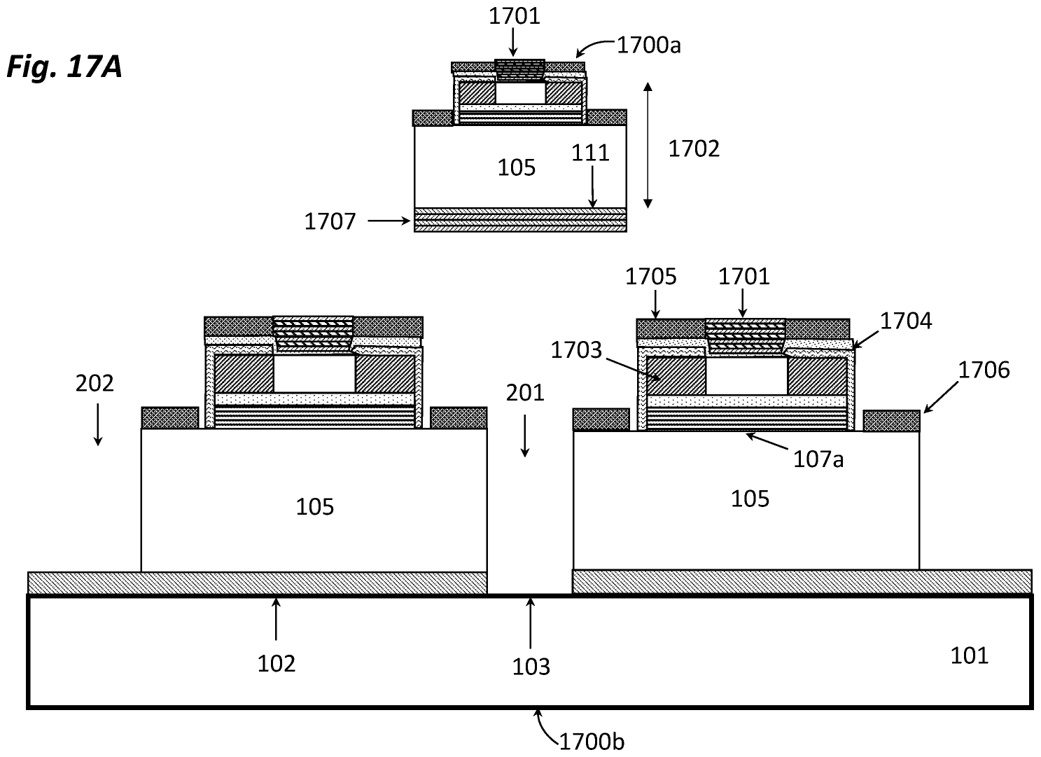

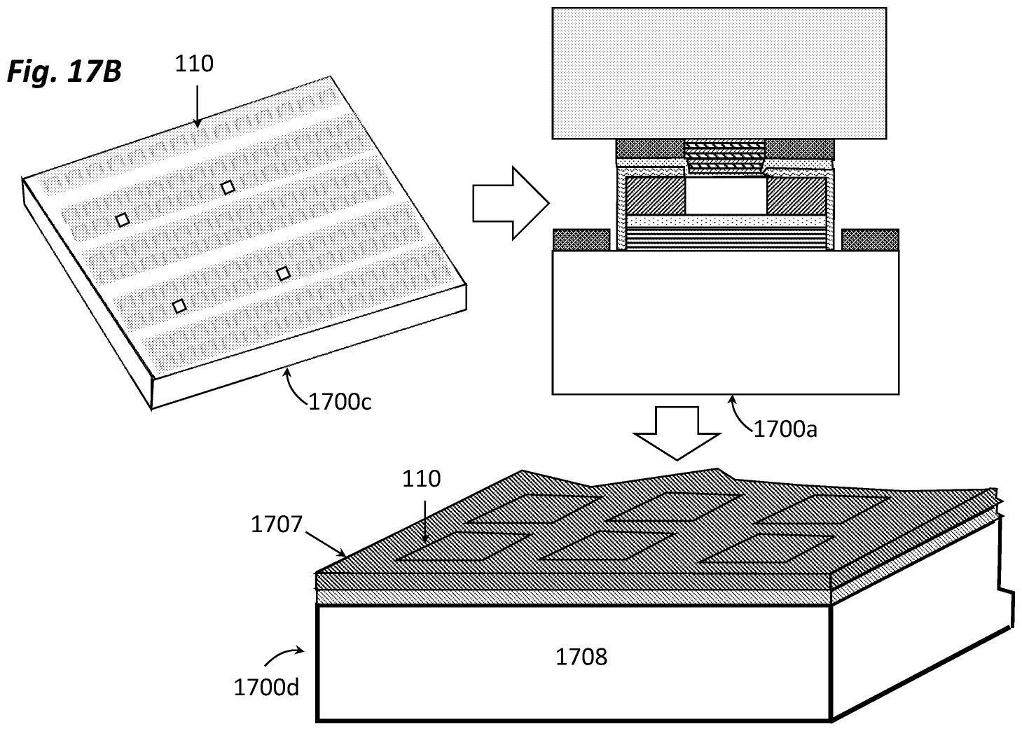

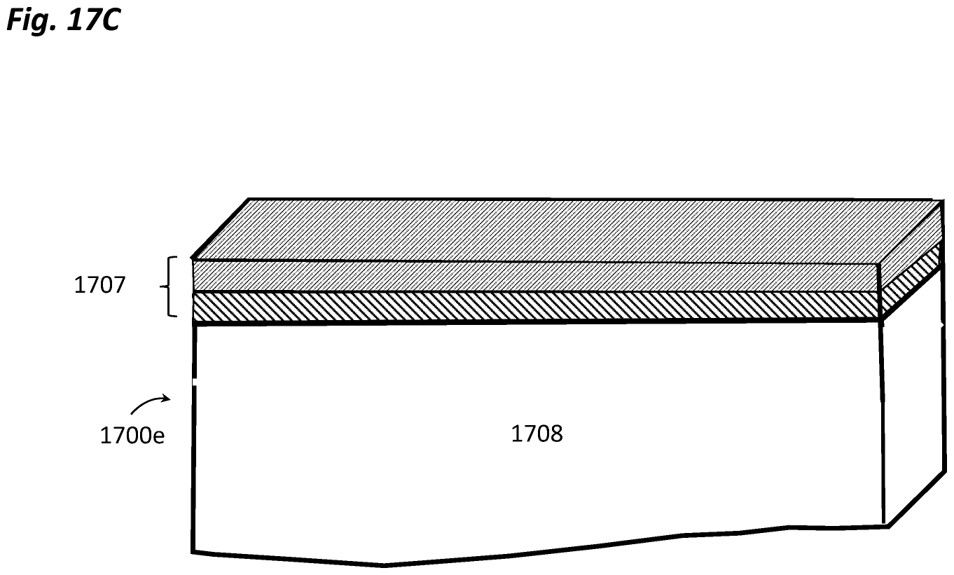

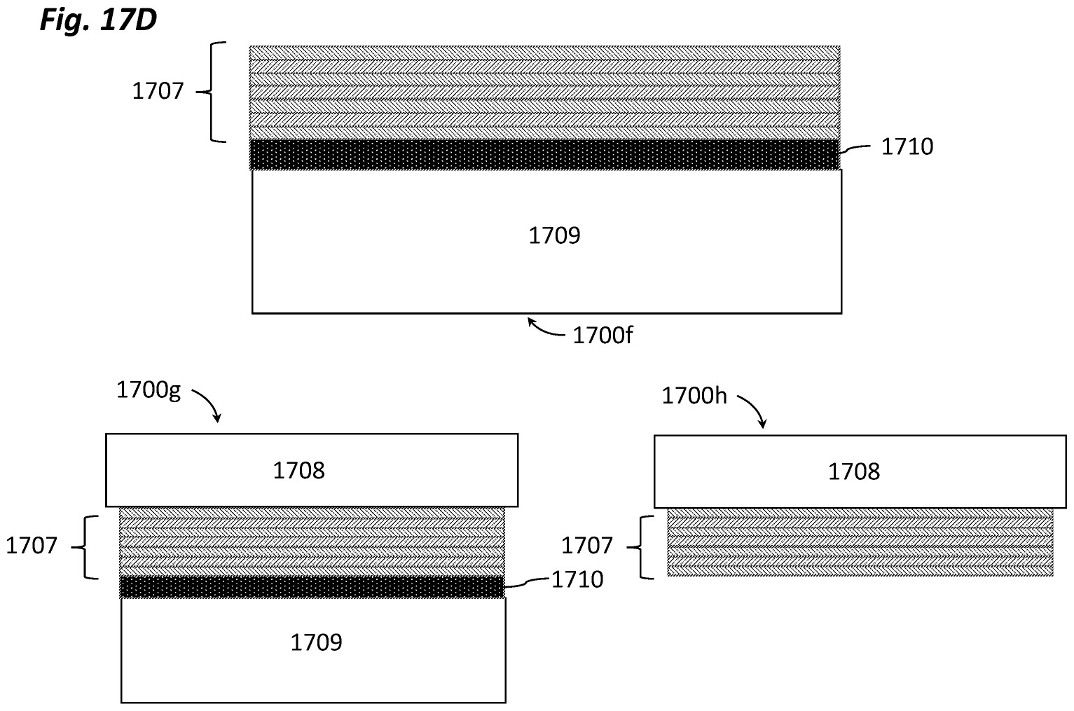

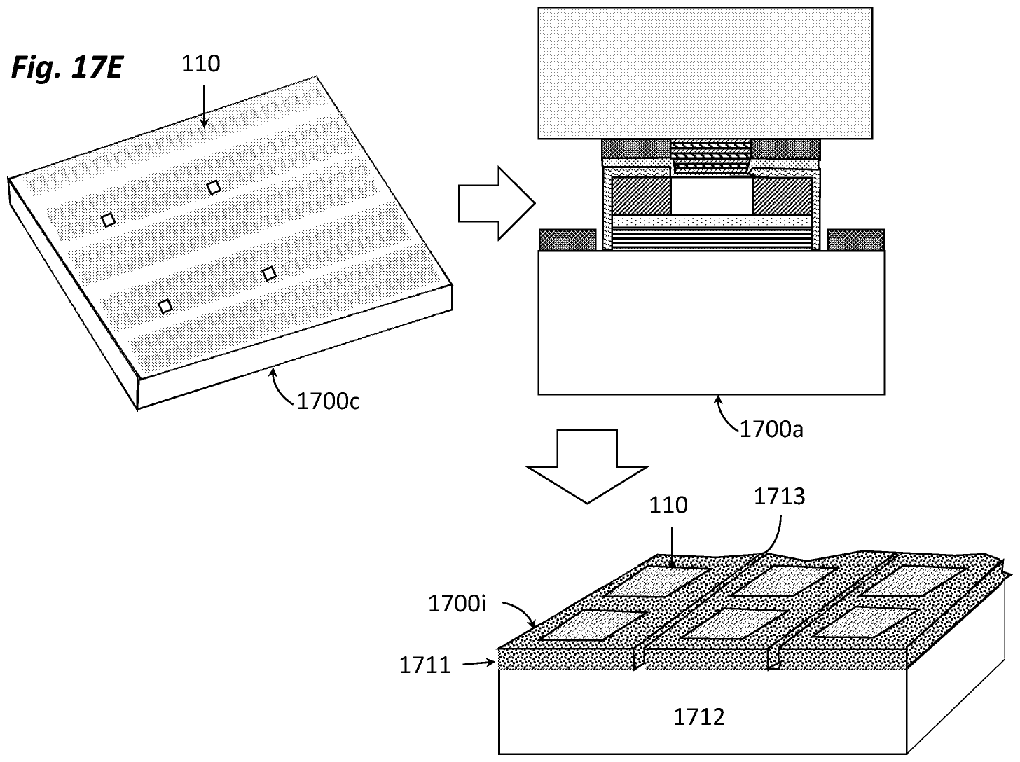

The isolated III-nitride ELO layers 105, or the front-end processed VCSEL device 110, represented by schematics 1700a, 1700b in FIG. 17A, need a second DBR mirror 1701 to close the resonant cavity 1702 in the VCSEL device 110.

This invention can have several degrees of freedom to a desired VCSEL design. There have been proposals for using short cavity VCSEL, i.e., roughly 7λ cavity length, where λ is desired light output wavelength or long wavelength cavities (roughly 23λ cavity length or more) for better thermal performances. As the cavity is controlled epitaxially, the cavity length can be precisely engineered or even the n-type coalesced III-nitride ELO layers 105 may be polished before epitaxially integrating other III-nitride device layers 107 of the VCSEL design. A typical VCSEL device 110 is fabricated on the front-end with all the desired elements, such as current blocking layer 1703, current spreader 1704, DBR mirror 1701, p-pad 1705 and n-pad 1706, etc. Then, the VCSEL devices 110 are isolated from the host substrate 101 by removing Region 1 201 and/or Region 1 202.

As shown in schematics 1700c, 1700d in FIG. 17B, the isolated hooked or non-hooked VCSEL devices 110 are then picked with one of the tools described above from the processed VCSEL wafer as shown in 1700c and a final DBR mirror 1707 is attached onto the interface 111 of the III-nitride ELO layers 105 and the growth restrict mask 102 to realize the VCSEL 110, as shown in 1700d.

Specifically, FIG. 17B includes schematic 1700c of a picking process for the VCSEL devices 110 from the processed VCSEL wafer and schematic 1700d of adding a DBR mirror 1707 of the second type to the device 110 using a DBR carrier substrate 1708.

There may be several options in choosing a DBR mirror of the second type.

1. Epitaxial DBR:
This is shown as 1700e in FIG. 17C. On a carrier substrate 1708, such as Si, SiC, sapphire or GaN, epitaxial DBR pairs 1707, such as AlN/GaN, AlInN/GaN. Al(Ga)N/GaN or AlInGaN/AlInGaN, are prepared and attached to the interface 111 of the isolated III-nitride ELO layers 105 of the VCSEL 110, either using surface activation bonding or through some intermediate layer. Preferably, surface activation bonding may work as the surface roughness of the interface 111 is in the nanometer range.
Preparation of the epitaxial DBR pairs 1707 includes:
(a) AlN/GaN quarter wavelength thick layers 1707 can be epitaxially grown on a SiC, Si or sapphire carrier substrate 1708 and then the carrier substrate 1708 is attached to the interface 111 of the isolated III-nitride ELO layers 105 of the VCSEL 110 via surface activation bonding. Surface activation bonding is preferred as it avoids unwanted light scattering and thermally discontinuity is minimized.
(b) As shown in schematics 1700f, 1700g, 1700h in FIG. 17D, a GaN or sapphire substrate 1709 is provided, and a sacrificial layer 1710 is grown thereon, where the sacrificial layer 1710 comprises alloys of In, Ga and N. Then, n pairs of AlN/GaN epitaxial DBR mirror layers 1707 are grown on the sacrificial layer 1710. Later, the DBR mirror 1707 comprising n pairs of AlN/GaN layers is attached to a thermally conducting substrate 1708 by removing the sacrificial layer 1710, such as by PEC etching or electro-chemical etching. Then, the newly established template substrate 1708 comprising DBR mirror layers 1707 is attached to the interface 111 of the isolated III-nitride ELO layers 105 of the VCSEL device 110.

2. Nanoporous template:
This is shown in schematics 1700c, 1700a, 1700i of FIG. 17E. A highly doped GaN layer 1711 is grown on a foreign substrate 1712, such as SiC, Si or sapphire, wherein porosity is introduced into the highly doped GaN layer 1711, which effectively reduces the refractive index, and then the layer 1711 is attached, via carrier 1712, to the interface 111 of the isolated III-nitride ELO layers 105 and III-nitride device layers 107 of the VCSEL device 110. For better uniformity of porosity on the layer 1711, several trenches 1713 are recommended for the layer 1711, so that uniform porosity over the whole layer 1711 can be achieved.

Alternatively, dielectric DBR layers, for example, pairs of SiO₂/Nb₂O₅ layers, may be deposited; typically, 10 pairs can be deposited onto the interface 111 of the isolated III-nitride ELO layers 105 for realizing a VCSEL device 110. Preferably, thermally conductive DBR layers are epitaxially grown on a thermal conducting carrier and then surface bonded to the interface 111 without any intermediate layers.

In GaN VCSELs, it is well known that growing an epitaxial DBR and active layer on the substrate continuously by MOCVD is difficult. The difference in the lattice mismatch and the thermal expansion co-efficiency hinders growing a high-crystal quality layer. The laser characteristics obtained through the conventional process are not so good. Thus, the yield of this type of GaN VCSELs is extremely low.

In the present invention, the device 110, including the active layer, the epitaxial DBR with the substrate 101, and the heat sink, can be prepared independently. Then, these elements can be bonded to each other using a surface activation process, etc. By doing this, the present invention can avoid the above issues, and can obtain a high-yield in a mass-production process.

Generally, surface activated bonding and other bonding methods are used for wafer-based bonding, because they have to bond a large area. In this case, since the device 110 is very small, bonding failures caused by twisting or bowing of wafers can be prevented, which increases the yield.

Mounting the Device on a Heat Sink Plate

After Step 5, the divided/isolated devices 110 are lifted using the approaches described above: (1) PDMS stamp; (2) vacuum chuck; (3) carrier plate structure containing SoG material used for surface bonding; and (4) permanent bonding can be placed at a desired location instead of crowding the devices 110 together.

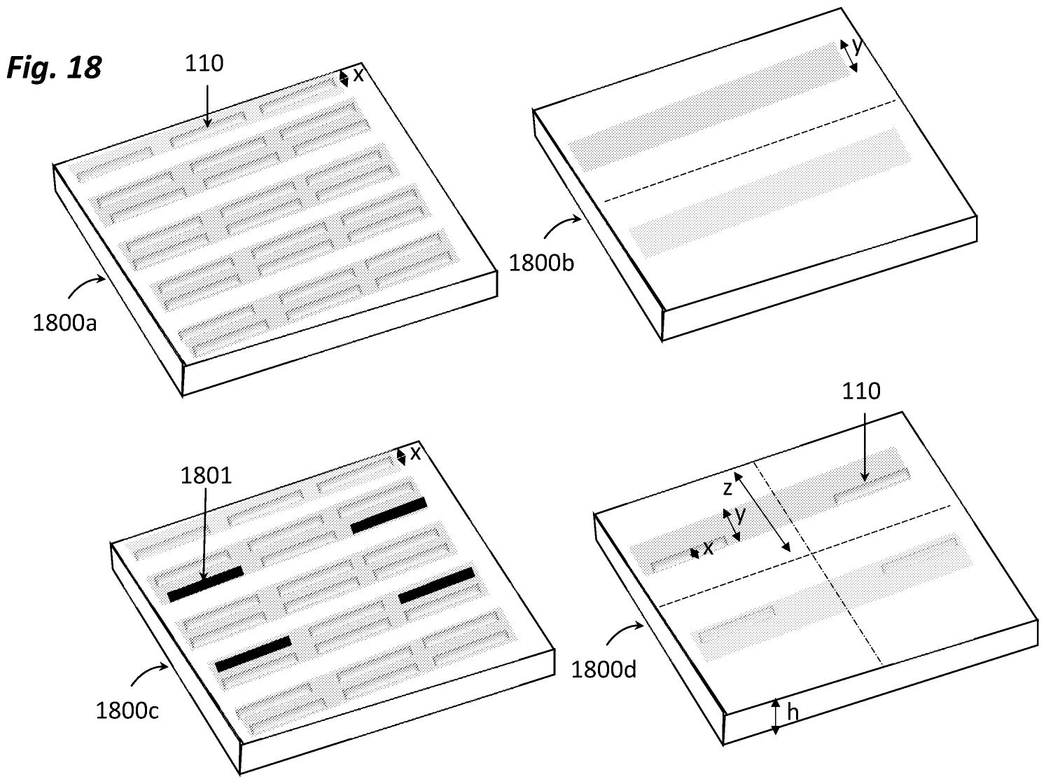

For example, as shown in schematics 1800a, 1800b, 1800c, 1800d in FIG. 18, a device source wafer 1800a, 1800c containing the devices 110 is attached to a selectively patterned heatsink plate 1800b, 1800d, wherein schematic 1800a is a fully populated device 110 source wafer and schematic 1800c is a device 110 source wafer where some devices 110 have been removed. The devices 110 initially have a lateral dimension x, which is smaller than the wing of the III-nitride ELO layers 105, and thus can be allocated more space on the heatsink plate shown in schematics 1800b, 1800d, having a lateral dimension z>>x with a thickness h, which helps to spread the heat more efficiently.

Also, another advantage is that since the devices 110 on the host substrate 101 are isolated from the host substrate 101, they possess less stress than devices fabricated on a host substrate directly. Therefore, in this invention, after isolating the III-nitride ELO layers 105 and III-nitride device layers 107, one may attach a DBR template, or a cladding template, or a heatsink, at a wafer scale. Wafer bowing tolerances can be forgiven in the way this invention translates a device 110 out of its host substrate 101 and therefore the yield can be improved in industrial practice.

Using a Vacuum Chuck to Pick III-Nitride ELO Device Layers and Local Repair Methods

This invention provides a solution to the problem of mass transferring of smaller light emitting apertures, alternatively called emissive inorganic pixels, when targeted sizes are below 50 μm. VCSELs or μLEDs 110, fabricated on the wings of the III-nitride ELO layers 105, can be removed as mentioned above. In particular, these devices 110 preferably have larger wing regions of the III-nitride ELO layers 105 and smaller open regions resulting from etching Region 1 201, that is, a ratio between the wing region and open region should be more than 1, more preferably 5-10, and in particular, open regions should be around 1-5 μm. Therefore, devices 110 can be removed from the substrate 101 more easily and can be transferred to external carriers or processed in further steps in an easy manner.

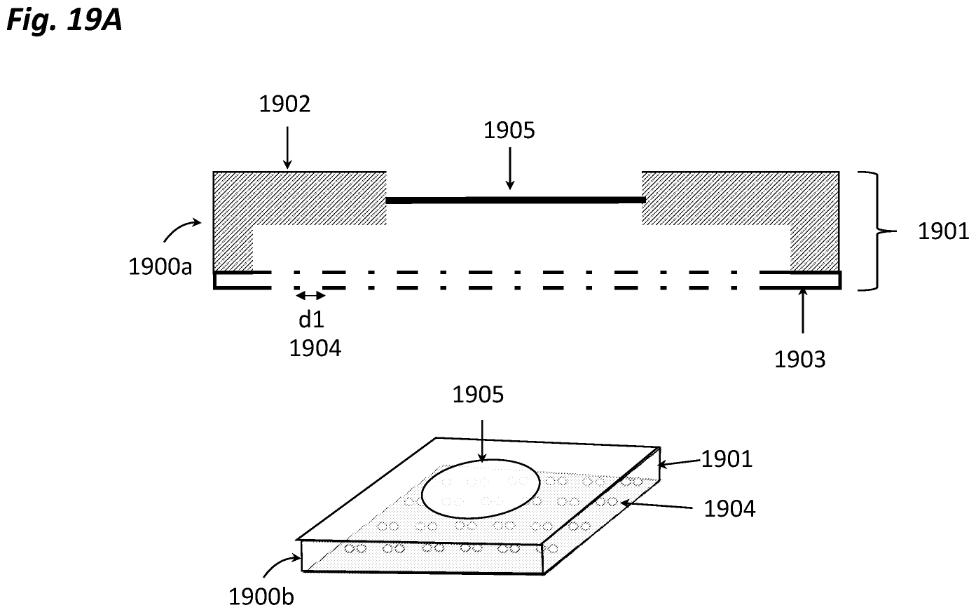

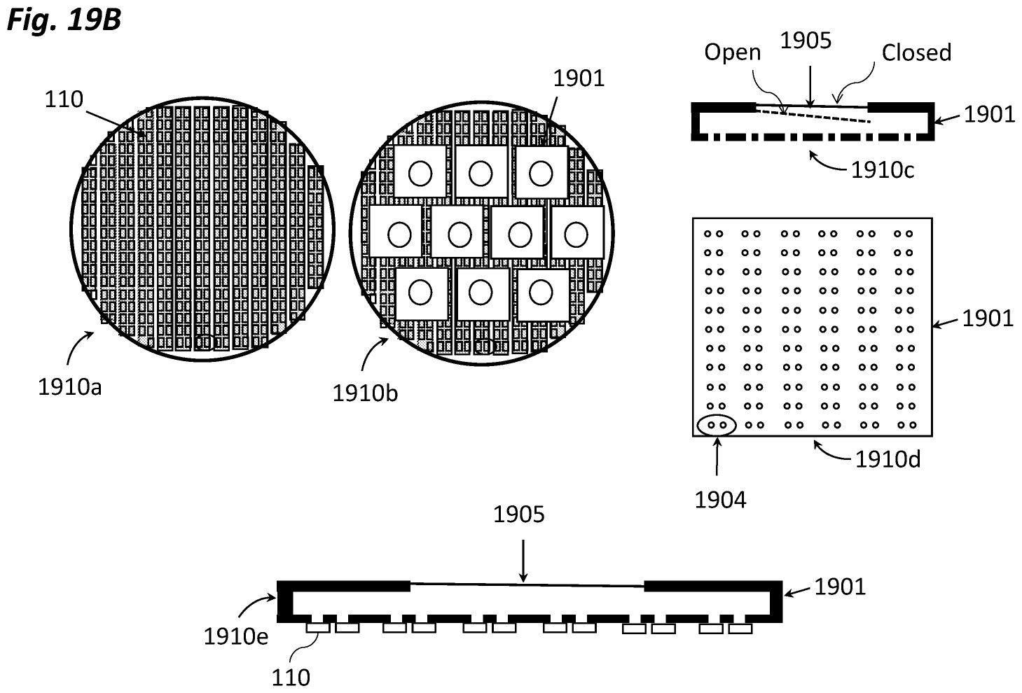

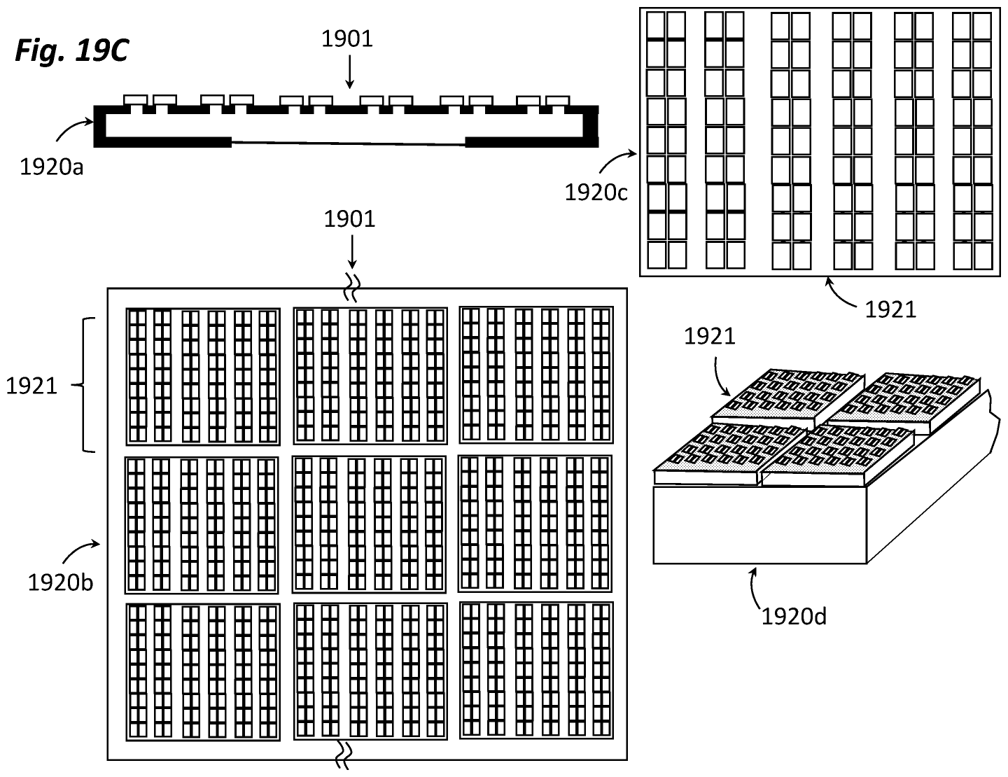

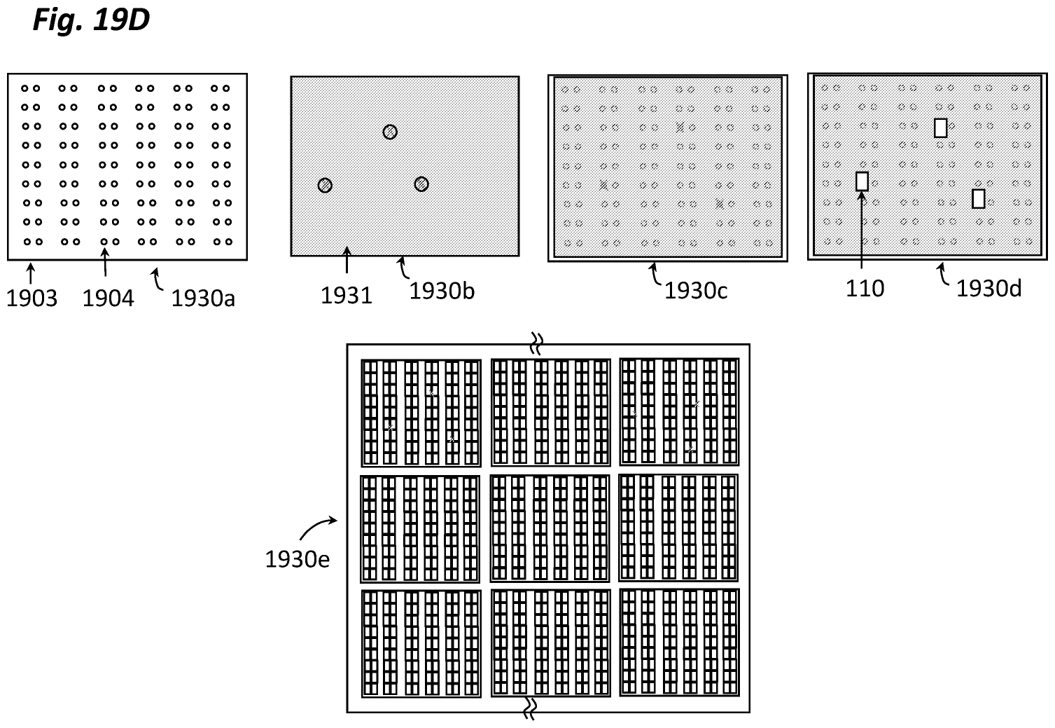

As shown in schematics 1900a and 1900b in FIG. 19A, and schematics 1910a, 1910b, 1910c, 1910d, 1910e, in FIG. 19B, a vacuum chuck 1901 is combination of at least two plates 1902, 1903, wherein a bottom plate 1903 has vacuum holes with dimensions d1 1904 slightly smaller than the device 110 to be lifted from the host substrate 101, and a top plate 1902 has a larger vacuum hole 1905, which can be controlled either electrically or magnetically for physically extracting isolated devices 110 out of the host substrate 101.

The vacuum chuck 1901 is placed over the isolated devices 110 on the host substrate 101 and the devices 110 are extracted out of the host substrate 101 by turning on a vacuum and opening the vacuum hole 1905.

As shown in schematics 1910a and 1910b in FIG. 19B, the devices 110 contained by the vacuum chuck 1901 are either placed on a processed carrier plate, or directly attached onto a display back panel, or a DBR template, or a cladding template, or a heatsink.

In FIG. 19C, schematic 1920a is a side view of the vacuum check 1901, schematic 1920b is a top view of the vacuum chuck 1901, schematic 1920c is a top view of an enlarged portion 1921 of the vacuum chuck 1901, and schematic 1920d is a plan view of the enlarged portions 1921 of the vacuum chuck 1901.

As shown in schematics 1930a, 1930b, 1930c, 1930d, 1930e in FIG. 19D, a unique application of this invention, when using the vacuum chuck 1901, is realized when a defective device 110 needs replacement due to failure. A selective hole containing mask 1931 as shown in schematic 1930a is attached to the bottom plate 1903 as shown in schematic 1930b, the defective devices 110 are picked from the host substrate 101 as shown in schematic 1930c, and then non-defective devices 110 are re-attached at the defective locations on the display panel as shown in schematic 1930d, resulting in the repair of local pixels as shown in schematic 1930e.

### Definitions of Terms

III-Nitride-Based Substrate

The III-nitride-based substrate 101 may comprise any type of III-nitride-based substrate, as long as a III-nitride-based substrate 101 enables growth of III-nitride-based semiconductor layers 105, 107, through a growth restrict mask 102, for example, any GaN substrate 101 that is sliced on a {0001}, {11-22}, {1-100}, {20-21}, {20-2-1}, {10-11}, {10-1-1} plane, etc., or other plane, from a bulk GaN, and AlN crystal substrate 101.

Hetero-Substrate

Moreover, the present invention can also use a hetero-substrate 101. For example, a GaN template or other III-nitride-based semiconductor layer may be grown on a hetero-substrate 101, such as sapphire, Si, GaAs, SiC, Ga₂O₃, etc., prior to the deposition of the growth restrict mask 102. The GaN template or other III-nitride-based semiconductor layer is typically grown on the hetero-substrate 101 to a thickness of about 2-6 μm, and then the growth restrict mask 102 is disposed on the GaN template or other III-nitride-based semiconductor layer.

Growth Restrict Mask

The growth restrict mask 102 comprises a dielectric layer, such as SiO₂, SiN, SiON. Al₂O₃, AlN, AlON, MgF, ZrO₂, TiN etc., or a refractory metal or precious metal, such as W, Mo, Ta, Nb, Rh, Ir, Ru, Os, Pt, etc. The growth restrict mask 102 may be a laminate structure selected from the above materials. It may also be a multiple-stacking layer structure chosen from the above materials.

In one embodiment, the thickness of the growth restrict mask 102 is about 0.05-3 μm. The width of the mask 102 is preferably larger than 20 μm, and more preferably, the width is larger than 40 μm. The growth restrict mask 102 is deposited by sputter, electron beam evaporation, plasma-enhanced chemical vaper deposition (PECVD), ion beam deposition (IBD), etc., but is not limited to those methods.

On an m-plane free standing GaN substrate 101, the growth restrict mask 102 comprises a plurality of opening areas 103, which are arranged in a first direction parallel to the 11-20 direction of the substrate 101 and a second direction parallel to the 0001 direction of the substrate 101, periodically at intervals extending in the second direction. The length of the opening area 103 is, for example, 200 to 35000 μm; the width is, for example, 2 to 180 μm; and the interval of the opening area 103 is, for example, 20 to 180 μm. The width of the opening area 103 is typically constant in the second direction but may be changed in the second direction as necessary.

On a c-plane free standing GaN substrate 101, the opening areas 103 are arranged in a first direction parallel to the 11-20 direction of the substrate 101 and a second direction parallel to the 1-100 direction of the substrate 101.

On a semipolar (20-21) or (20-2-1) GaN substrate 101, the opening areas 103 are arranged in a direction parallel to [−1014] and [10-14], respectively.

Alternatively, a hetero-substrate 101 can be used. When a c-plane GaN template is grown on a c-plane sapphire substrate 101, the opening area 103 is in the same direction as a free-standing c-plane GaN substrate; when an m-plane GaN template is grown on an m-plane sapphire substrate 101, the opening area 103 is same direction as a free-standing m-plane GaN substrate. By doing this, an m-plane cleaving plane can be used for dividing the bar of the device 110 with the c-plane GaN template, and a c-plane cleaving plane can be used for dividing the bar of the device 110 with the m-plane GaN template; which is much preferable.

III-Nitride-Based Semiconductor Layers

The III-nitride ELO layers 105 and the III-nitride device layers 107 can include In, Al and/or B, as well as other impurities, such as Mg, Si, Zn, O, C, H, etc.

The III-nitride-based device layers 107 generally comprise more than two layers, including at least one layer among an n-type layer, an undoped layer and a p-type layer. The III-nitride-based device layers 107 specifically comprise a GaN layer, an AlGaN layer, an AlGaInN layer, an InGaN layer, etc. In the case where the device has a plurality of III-nitride-based device layers 107, the distance between the island-like III-nitride device layers 107 adjacent to each other is generally 30 μm or less, and preferably 10 μm or less, but is not limited to these figures.

Merits of Epitaxial Lateral Overgrowth

The crystallinity of the III-nitride ELO layers 105 grown upon the growth restrict mask 102 from a striped opening are 103 of the growth restrict mask 102 is very high. Consequently, the III-nitride device layers 107 also have high crystal quality.

Furthermore, two advantages may be obtained using a III-nitride-based substrate 101. One advantage is that high-quality III-nitride device layers 107 can be obtained on the wings of the III-nitride ELO layers 105, such as with a very low defects density, as compared to using a sapphire substrate.

The use of a hetero-substrate 101, such as sapphire (m-plane, c-plane), LiAlO₂, SiC. Si, etc., for the growth of the epilayers 105, 107 is that these substrates are low-cost substrates. This is an important advantage for mass production.

When it comes to the quality of the device 110, the use of a free standing III-nitride-based substrate 101 is more preferable, due to the above reasons. On the other hand, the use of a hetero-substrate 101 makes it cheaper and scalable.

Also, as the growth restrict mask 102 and the III-nitride ELO layers 105 are not bonded chemically, the stress in the III-nitride ELO layers 105 can be relaxed by a slide caused at the interface between the growth restrict mask 102 and the III-nitride ELO layers 105.

Flat Surface Region

The flat surface region 108 is between layer bending regions 109. Furthermore, the flat surface region 108 is in the region of the stripes of the growth restrict mask 102.

Fabrication of the semiconductor device 110 is mainly performed on the flat surface region 108. The width of the flat surface region 108 is preferably at least 5 μm, and more preferably is 10 μm or more. The flat surface region 108 has a high uniformity of thickness for each of the semiconductor layers 105, 107.

Layer Bending Region

Schematic 200c in FIG. 2B illustrates the layer bending regions 109. If the layer bending region 109 that includes the active layer 107a remains in the device 110, a portion of the emitted light from the active layer 107a is reabsorbed. As a result, it is preferable to remove at least a part of the active layer 107a in the layer bending region 109 by etching.

If the layer bending region 109 that includes an active layer 107a remains in the VCSEL device 110, the laser mode may be affected by the layer bending region 109 due to a low refractive index (e.g., an InGaN layer). As a result, it is preferable to remove at least a part of the active layer 107a in the layer bending region 109 by etching.

The emitting region formed by the active layer 107a is a current injection region. In the case of a VCSEL 110, the emitting region is a resonant cavity aperture structure vertically above a p-side of the device 110, or below an n-side of the device, or vice versa.

For a VCSEL device 110, the edge of the emitting region should be at least 1 μm or more from the edge of the layer bending region 109, and more preferably 5 μm.

From another point of view, an epitaxial layer of the flat surface region 108 except for the opening area 103 has a lesser defect density than an epitaxial layer of the opening area 103. Therefore, it is more preferable that the aperture structures should be formed in the flat surface region 108 including on a wing region of the III-nitride ELO layers 105.

Semiconductor Device

The semiconductor device 110 is, for example, a Schottky diode, a light-emitting diode, a semiconductor laser, a photodiode, a transistor, etc., but is not limited to these devices. This invention is particularly useful for VCSEL devices 110. This invention is especially useful for a semiconductor laser device 110, which requires smooth regions for cavity formation.

Heat Sink Plate

As noted above, the removed devices 110 may be transferred to a heat sink plate, which may be AlN, SiC, Si. Cu, CuW, and the like. Solder may be used to attach devices 110 onto a heatsink, which may be Au—Sn, Su—Ag—Cu, Ag paste, and the like, is disposed on the heat sink plate. Then, an n-electrode or p-electrode is bonded to the solder. The devices 110 can also be flip-chip bonded to the heat sink plate.

In the case of bonding devices 110 to the heat sink plate, the size of the heat sink plate does not matter, and it can be designed as desired.

DBR Mirror

The light reflecting layer mentioned in this invention is also referred to as a DBR mirror, which can be comprised of dielectric or epitaxial layers. A dielectric DBR mirror is comprised of, for example, a semiconductor multilayer film or a dielectric multilayer film. Examples of a dielectric materials include but not limited to Si, Mg, Al, Hf, Nb, Zr, Sc, Ta, Ga, Zn, Y, B, Ti, etc., or nitrides of these elements, like SiN, AlN, AlGaN, GaN, BN, etc., or oxides of these elements, like SiOx, TiOx, NbOx, ZrOx, TaOx, ZnOx, AlOx, HfOx, SiNx, AlNx, etc. The light reflecting layer can be obtained by alternatively laminating one or more dielectric materials having different refractive indices. The materials of different refractive indices, different thickness and various number of material layers chosen to obtain desired light reflectance. The thickness of each film of dielectric layer can be adjusted depending on the material and the oscillation wavelength of the emitted light from the resonant cavity.

Preferably, the thickness of these layers as odd multiples of a quarter of oscillation wavelengths. The reflectance of the two light reflective elements, one on the top and one on the bottom are different. These two light reflecting elements including an active layer, an n-GaN layer, and part of a p-GaN layer, collectively are called a resonant cavity. In general, the light emitting side of the device's light reflecting layer reflectance is smaller than the other side. One of the DBR mirrors can be dielectric and the other can be an epitaxial DBR.

Epitaxial DBR mirrors may comprise AlN/GaN DBR mirror layers that are epitaxially integrated on a substrate. In addition, the epitaxial DBR mirrors may comprise (Ga)N/GaN or AlInN/GaN. The substrate may comprise SiC, Si, GaN, or sapphire.

Current Confinement Region

A resonant cavity can be created using a current confinement region by shaping current flowing through a VCSEL device 110 narrow enough to confine within the diameter of an aperture of the resonant cavity. This can be achieved by making the layers around the aperture where the current injection takes place more conductive than a neighboring region. For example, using reactive ion etching, or plasma etching, or dielectric masks, the neighboring region of the aperture can be made resistive.

### Alternative Embodiments

The following describes alternative embodiments of the present invention.

### First Embodiment

A III-nitride-based semiconductor device 110, and a method for manufacturing the device 110, are described according to a first embodiment.

In the first embodiment, as shown by elements 100a and 100b in FIG. 1, a base or host substrate 101 is first provided, and a growth restrict mask 102 that has a plurality of striped opening areas 103 is formed on the substrate 101.

In this embodiment, the III-nitride ELO layers 105 do not coalesce and form island-like III-nitride semiconductor layers, as shown in schematic 100a in FIG. 1, or the III-nitride ELO layers 105 are allowed to coalesce and/or contact neighboring III-nitride ELO layers 105 in order to form a foundation layer, as shown in schematic 100b in FIG. 1. Thereafter, device layers 107, such as multi quantum well structures, waveguides, electron blocking layer, p-GaN, etc., are grown on the above the III-nitride ELO layers 105. Devices 110 such as μLEDs, micro-cavity LEDs, edge-emitting lasers, and VCSELs, are fabricated on the wing regions of the III-nitride ELO layers 105. For example, at least one of the DBR mirrors of a VCSEL device 110 is fabricated in a front-end processing step: similarly, for edge-emitting lasers, all the front-end processes, such as fabricating the ridge, p-pads and n-pads and their isolation layers, are defined.

Ten, the III-nitride ELO layers 105 and III-nitride device layers 107 are divided into individual devices 110 or groups of devices 110 by etching Region 1 201 and Region 1 202 to expose the underlying growth restrict mask 102, as shown in FIGS. 2A and 3. At this stage, the III-nitride ELO layers 105 and III-nitride device layers 107 literally have no connection to the host substrate 101. The only force that may keep the III-nitride ELO layers 105 and III-nitride device layers 107 on the host substrate 101 is a weak interaction force (Van der Waals forces) at the interface 111 between the growth restrict mask 102 and the III-nitride ELO layers 105.

Then, the III-nitride ELO layers 105 and III-nitride device layers 107 are transferred onto a carrier using tools such as a PDMS elastomer stamp, vacuum chuck, SoG material bonding, bonding through an intermediate layer, surface activation bonding, etc. After lifting the III-nitride ELO layers 105 and III-nitride device layers 107 off of the host substrate 101, further processing may be needed, or the devices 110 may be directly transferred for targeted applications.

A number of devices 110, such as dual-cladding lasers or hybrid DBR mirror VCSELs, are realizable using this invention. An experimental observation of the back surfaces of the III-nitride ELO layers 105, at the interface 111 between the growth restrict mask 102 and the III-nitride ELO layers 105, indicate a surface roughness in the nanometer range (<2 nm) irrespective of crystal orientation. Therefore, surface activation bonding of an epitaxial DBR (AlN/GaN) on a SiC substrate may be used for realizing a hybrid DBR VCSEL device 110, or attaching an external low refractive index cladding layer, such as AlN, may be used for realizing a dual-clad laser device 110. The advantages of not introducing additional intermediate layers between the interface 111 and the DBR or cladding layer is that it improves thermal performance and avoids unwanted light scattering.

This invention is advantageous for obtaining smooth interfaces 111 for fabricating DBR mirrors of a VCSEL device 110. General approaches, such as thinning the substrate or removing semiconductor layers by PEC etching, are tedious and crystal orientation dependent. However, the approach of this invention is robust and crystal plane independent. Moreover, substrates 101 that are used to produce device layers 107 can be recycled several times for similar fabrication. The approach of this invention not only provides a smooth interface 111 for DBR mirrors, but also a good crystal quality device 110, as this invention proposes fabricating a resonant cavity completely on the wing regions of the III-nitride ELO layers 105. Preferably, this does not include the opening area 103 of the growth restrict mask 102 from where the III-nitride ELO layers 105 are grown on the substrate 101.

### Second Embodiment

The second embodiment removes the III-nitride ELO layers 105 using a hooking process, comprising an assist layer 301 or hook layer 302 as shown in FIG. 3, which temporarily holds the III-nitride ELO layers 105 and releases them onto a temporary carrier substrate, permanent bonding substrate, CMOS panel, TFT back panel, etc. Using the ELO method, larger wings can be obtained for the III-nitride ELO layers 105, wherein several devices 110, such as VCSELs, LEDs, power electronic devices, etc., can be fabricated on these wings. By doing so, these devices 110 have reduced defects as compared to devices fabricated from conventional substrates.

In a first part of the booking process, using either separate or coalesced III-nitride ELO layers 105, such as shown in 100a and 100b in FIG. 1, respectively, the device 110 is fabricated on top of the III-nitride ELO layers 105. The III-nitride ELO layers 105 are masked, for example, with an SiO₂ layer deposited via chemical vapor deposition, atomic layer deposition, or sputtering. The mask can be patterned in such a way as to extract a useful chip on the wing of the III-nitride ELO layers 105 by placing one of two different types of hook designs.

For example, in a Type 1 Hook pattern, as shown in schematic 300b in FIG. 3, Region 1 202 is etched through the growth restrict mask 102, and a remaining assist layer 301 acts as the hook to hold the devices 110.

In another example, in a Type 2 Hook pattern, as shown in schematic 300c in FIG. 3, a dielectric layer is deposited as the hook layer 302, which also enables other types of Hook patterns, for example, Type 3 and Type 4 Hook patterns, as shown in schematics 1500a, 1500b, 1500c, 1500d in FIG. 15. This process may be performed after front-end processes have been performed on separate or coalesced III-nitride ELO layers 105 and III-nitride device layers 107.

For example, in the case of small size LED devices 110, the device 110 fabricated on the wings of the III-nitride ELO layers 105 includes p-electrodes and n-electrodes on a top side of the III-nitride device layers 107. The mask used for etching the III-nitride ELO layers 105 and the III-nitride device layers 107 on the host substrate 101 can also serve as a passivation layer to protect from electrical leaks or to improve efficiencies for small sized LED devices 110.

Using a mask, typically SiO₂, desired chip dimensions are etched to at least expose the growth restrict mask 102. Then, in a Type 2 Hook pattern, a hook layer 302 is placed to contact the exposed growth restrict mask 102. Alternatively, the hook layer 302 may contact the host substrate 101 at the open ELO window. Also, the process of etching the III-nitride ELO layers 105 and the III-nitride device layers 107 to expose the underlying growth restrict mask 102 can be done in two steps, for example, in the case of thicker III-nitride semiconducting layers 105, 107, e.g., >10 μm, a hard mask is first used to etch to slightly above the growth restrict mask 102, so that underlying growth restrict mask 102 is not exposed, and then, in a second step, a soft layer, such as photoresist, is used to at least expose the underlying growth restrict mask 102. This configuration leads to one of the hooking designs labeled as Pattern 1 in the Type 2 Hook. Alternative methods may expose the underlying growth restrict mask without two etching steps.

In the Type 2 Hook, after exposing the underlaying growth restrict mask 102, the etched layers 105, 107 possess no support from the host substrate 101, as shown in FIG. 3, except they are sandwiched between the growth restrict mask 102 and the etched open ELO windows of the mask. At this stage, the devices 110 remain on the host substrate 101. Experimentally, all of the devices 110 were observed remaining on the growth restrict mask 102 after exposing growth restrict mask 102, as shown in the optical microscope image 1100g in FIG. 11D. The III-nitride semiconducting layers 105, 107 at this time are sandwiched between the growth restrict mask 102 and the mask used for exposing the growth restrict mask 102. This is a unique configuration that only achievable using the approach of this invention. Even though the initial growth restrict mask 102 for the ELO process was prepared at low temperature, −300° C., during formation of the III-nitride ELO layers 105 and III-nitride device layers 107 in the MOCVD rector chamber, the growth restrict mask 102 was exposed to higher temperatures around 1200° C., which must have facilitated a weaker bond, for example, Van der Waals forces, between the growth restrict mask 102 and the backside of the III-nitride ELO layers 105.

Alternatively, a further securing process may be possible by placing a thin layer, known as a chip securing layer (preferably, dielectric SiO₂), having a thickness of 10 nm to 300 nm on top of the etched mask, as indicated in both FIGS. 3 and 15. Several hook designs, known as Type 2, Type 3 and Type 4, are possible by selectively opening the chip securing layer and the etching mask combination. Schematics 1400a, 1400b in FIG. 14A and images 1400c, 1400d, 1400e, 1400f, 1400g in FIG. 14B illustrate an experimentally demonstrated Type 2 hook design, where the chip securing layer protects the chip with a stripe running across width of the chip.

Now, a carrier wafer, which can be temporary or permanent, may be attached to the chips. Using ultrasonic, mechanical or thermal treatments, the only supporting hook layer can be broken, and the chips can be transferred onto the carrier wafer.

This unique process is helpful not only in solving the present micro-LEDs mass transfer problem, but also helps to realize unique designs of VCSELs and dual-clad edge-emitting Fabry-Perot lasers.

VCSEL: n-Side Curved Mirror on Epitaxial Layer No Substrate Involved

After placing a chip securing layer, the devices 110 are transferred onto a temporary wafer using a crystal bond, or an electron wax, or a temporary attachment layer, as indicated by schematics 1210a, 1210b, 1210c, 1210d in FIG. 12B. After transferring onto a temporary carrier wafer, the back side of the device 110 is patterned in a concave manner by reflowing resist, and a curved mirror is fabricated on the epitaxial layer, before the devices 110 are transferred back onto a permanent bonding wafer for packaging, wherein light will be extracted from the p-side of the device 110. Using this process for removing the substrate 101, light emission from the p-side of the device 110 is possible for VCSEL devices 110, whereas in other processes, such as PEC etching, or electro-chemical etching, an n-side curved mirror on the removed epitaxial layers may not be possible.

Dual-Clad Fabry-Perot (FP) Laser

Unlike dividing III-nitride ELO layers 105 and III-nitride device layers 107 into small sized LED or VCSEL devices 110, an FP laser device 110 can be designed on the wing regions of the III-nitride layers 105 by placing a ridge structure and confinement layers on the III-nitride device layers 107 on the wing regions. For example, placing an ITO layer externally as one cladding layer before removing the laser device 110 by any of the above discussed hooking techniques and, after removal, another cladding layer, such as Aluminum Nitride (AlN), is placed externally. This process is more controllable to achieve dual-clad FP laser devices 110, as the thickness of the wing regions of the III-nitride ELO layers 105 can be controlled epitaxially for the very critical designs of long wavelength laser devices 110, and exactly designed epitaxial layers 105, 107 for the laser devices 110 are removed from the growth restrict mask 102. Two cladding layers are externally placed using, for example, sputter, electron beam, electron cyclotron resonance (ECR), chemical vapor deposition (CVD), etc. Alternatively, in the case where a back surface of the wing regions of the III-nitride ELO layers 105 is not necessarily flat. Even if the thickness of the n-GaN layers in the III-nitride device layers 107 exceeds the desired dimension, one can etch back to the desired value after transferring the FP laser device 110 onto a carrier substrate before placing a second cladding layer. In this configuration, junction down or sandwich cooling techniques can be imposed on the final device 110 for better thermal management.

### Third Embodiment

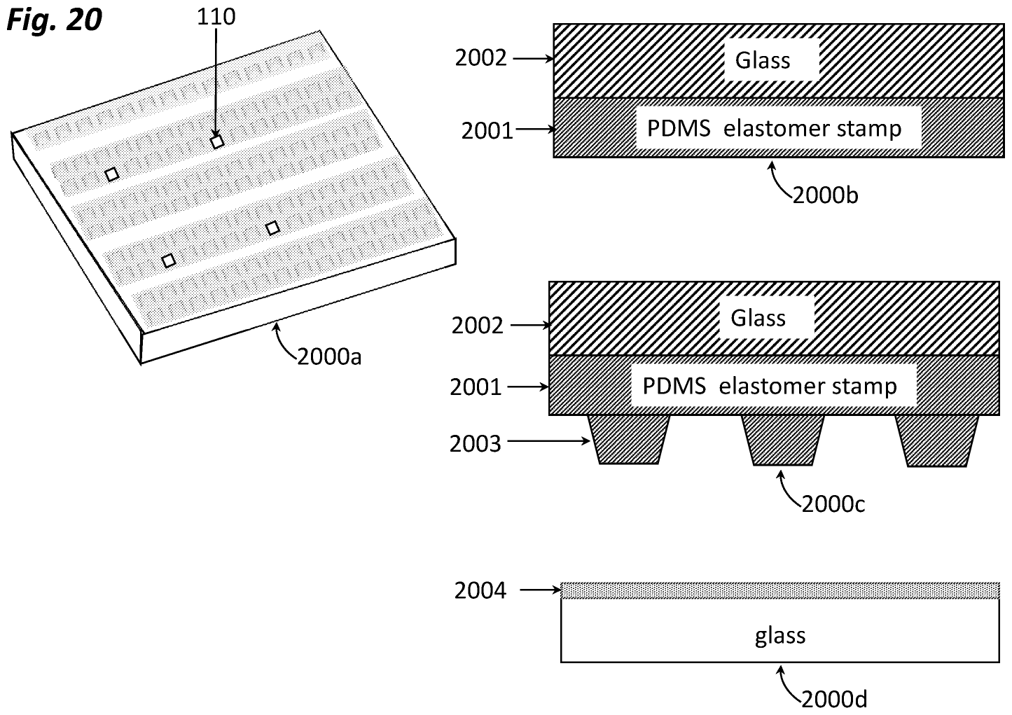

As shown in schematics 2000a, 2000b, 2000c, 2000d in FIG. 20, this embodiment describes on how to remove isolated devices 110 from their host substrate 101 using a PDMS stamp 2001. As the isolated III-nitride ELO layers 105 are free of connection with the host substrate 101, or even if there is a very fragile connection created at the open region resulting from the etching of Region 1 201, or a hook layer 302, this connection can be easily broken by movement of the PDMS stamp 2001. The PDMS stamp 2001 can be designed either to pick the isolated III-nitride ELO layers 105 and III-nitride device layers 107 together or even selectively pick some of them.

Stick and stamp method:
1. A stiff carrier 2002, such as glass or Si, is attached to the PDMS stamp 2001, in order to gather several isolated devices 110.
2. In addition to a flat PDMS stamp 2001, PDMS teeth structures 2003 may also be used. Using PDMS teeth structures 2003, one may selectively pick the isolated devices 110 out of the host substrate 101. For example, it is possible to spin coat uncured PDMS material on a glass and then bring the teeth structure 2003 in contact to the uncured PDMS 2004, so that a small amount of uncured PDMS 2004 will be transferred onto the PDMS teeth structure 2003. Then, the PDMS teeth structure 2003 with uncured PDMS 2004 may be brought into contact with the isolated devices 110, and the uncured PDMS 2004 allowed to cure. After curing, one may remove the selected devices 110 from the host substrate 101.

### Fourth Embodiment

The fourth embodiment is about picking isolated III-nitride ELO layers 105 and III-nitride device layers 107 out of the host substrate 101 using a vacuum chuck 1901, wherein the vacuum chuck 1901 is designed to contain at least two plates 1902, 1903, as shown in FIG. 19A. Plate 1903 contains finite dimension holes which are smaller than the dimension of the removed devices 110; plate 1902 has a larger dimension vacuum hole 1905 in order to control the holding process. The vacuum hole 1905 may be controlled by mechanical, electromagnetic, or hydraulic methods.

One may also use the vacuum chuck 1901 to pick up only selected devices 110 by closing undesired vacuum holes 1904 on the plate 1903, as shown in FIG. 19D. One may also use the vacuum chucks 1901 containing the removed devices 110 in post processing.

### Fifth Embodiment

The fifth embodiment is about picking isolated III-nitride ELO layers 105 and III-nitride device layers 107 from the host substrate 101 using a low temperature oxidization of SoG materials. SoG materials are disposed onto a glass or Si substrate, wherein the surfaces are placed in physical contact at room temperature and subsequently annealed at 425° C. with an applied pressure. The isolated III-nitride ELO layers 105 and III-nitride device layers 107 oxidize and form a bond with the SoG material and self-separate from the host substrates 101: alternatively, ultrasonic waves or a small impact may isolate the III-nitride ELO layers 105 and III-nitride device layers 107 from the host substrate 101.

This invention may also be practiced without applied pressure, or room temperature surface activation bonding, or low temperature oxygen plasma assisted wafer bonding, etc. The III-nitride ELO layers 105 and III-nitride device layers 107, after isolation from the host substrate 101, may be prepared to assist the room temperature surface activation bonding or low temperature oxygen plasma assisted wafer bonding.

This invention may use surface activation bonding on at least two places, wherein one is to separate the isolated III-nitride ELO layers 105 and III-nitride device layers 107 from the host substrate 101, and another is to reattach the interface 111 of the III-nitride ELO layers 105 and the growth restrict mask 102 for post processing surfaces, such as external cladding layers for dual-cladding laser devices 110, or DBR mirrors for VCSEL devices 110, or a heatsink plate for better thermal performance, or for integrating the III-nitride ELO layers 105 and III-nitride device layers 107 onto a Si-photonics substrate, such as a Silicon Nitride (SiN) waveguide containing CMOS compatible substrates.

### Sixth Embodiment

The sixth embodiment is about using the interface 111 of the removed III-nitride ELO layers 105 and III-nitride device layers 107. It has been experimentally observed that the interface 111 at the growth restrict mask 102 and the III-nitride ELO layers 105 is extremely smooth. AFM scans reveal a surface roughness of about <2 nm; in some cases, it is in the sub-nanometer regime. In the post processing of devices 110, such as VCSELs, externally clad attached dual-cladding lasers, or edge-emitting lasers, an external carrier containing either DBR mirror layers, cladding layers, or a heatsink, must be attached to the removed III-nitride ELO layers 105 at the interface 111. As the surface of the interface 111 is smooth, one may attach the above post processing elements at room temperature either by surface activation bonding, or by plasma-associated bonding mechanisms. The smooth surface assists to avoid intermediate layers for successful attachment and thus obtains a better performing device 110.

### Seventh Embodiment

In a seventh embodiment, AlGaN layers are used in the III-nitride ELO layers 105 and/or III-nitride device layers 107, and in the resulting island-like III-nitride semiconductor layers. The AlGaN layers may be grown as the III-nitride ELO layers 105 on various off angle substrates 101. The AlGaN layers can have a very smooth surface using the present invention. Using the present invention, the AlGaN layers can be removed, as the III-nitride ELO layers 105 and III-nitride device layers 107, and island-like III-nitride semiconductor layers, from various off angle substrates 101.

In this case, an active laser device 110, which emits UV-light (UV-A or UV-B or UV-C), can be grown on the AlGaN ELO layers 105. After removal, the AlGaN ELO layers 105 and the III-nitride device layers 107 comprises a UV-device 110 with a pseudo-AlGaN substrate. By doing this, one can obtain a high-quality UV-LED or laser device 110 without absorption by the substrate 101.

### Eighth Embodiment

In the eighth embodiment, the III-nitride ELO layers 105 are grown on various off-angle substrates 101. The off-angle orientations range from 0 to +15 degrees and 0 to −28 degrees from the m-plane towards the c-plane. The present invention can remove a bar of the device 110 from the various off-angle substrates 101 without breaking the bar. When various crystal plane substrates 101 are used, the removed region of the bar at the opening area 103 may include cleaved surfaces, like a staircase, when the bar is removed mechanically, making the opening area 103 not suitable for fabricating DBR mirrors for VCSEL devices 110: however, independent of crystal orientation, the surface of the wing regions of the III-nitride ELO layers 105 are smooth enough to fabricate such delicate DBR mirrors for a VCSEL device 110. For example, when a semi-polar bar of a device 110 is removed from its host substrate 101 comprising a semi-polar plane, 20-2-1 or 20-21, the open region resulting from the etching of Region 1 201 may contain a cleaved non-polar plane, 10-10 or like, which is at an angle 75 or 15 degrees from the semi-polar plane of the host substrate 101, which looks like a staircase pattern at the open region, as shown in FIGS. 12B, 12C, 12D and 12E; however, the wing region of the III-nitride ELO layers 105 of the bar contains a smoother surface than the open region. So, this invention's proposal of fabricating DBR mirrors for VCSEL devices 110 on the wing region of the III-nitride ELO layers 105 is the best solution independent of crystal planes. This is a big advantage for this technique, as various off-angle orientations semiconductor plane devices 110 can be realized without changing the fabrication process.

### Ninth Embodiment

In a ninth embodiment, the III-nitride ELO layers 105 are grown on c-plane substrates 101 with two different mis-cut orientations. Then, the III-nitride ELO layers 105 and III-nitride device layers 107 are removed from the substrate 101 after processing into a desired device 110 using the invention described in this application.

### Tenth Embodiment

In a tenth embodiment, a sapphire substrate 101 is used with a buffer layer. The resulting structure is almost the same as the first embodiment, except for using the sapphire substrate 101 and the buffer layer. In this embodiment, the buffer layer may also include an additional n-GaN layer or undoped GaN layer. The buffer layer is grown at a low temperature of about 500-700° C. degrees. The n-GaN layer or undoped GaN layer is grown at a higher temperature of about 900-1200° C. degrees. The total thickness is about 1-3 μm. Then, the growth restrict mask 102 is disposed on the buffer layer and the n-GaN layer or undoped GaN layer.

On the other hand, it may not be necessary to use the buffer layer. For example, the growth restrict mask 102 can be disposed on a hetero-substrate 101 directly. After that, the III-nitride ELO layer 105 and/or III-nitride device layers 107 can be grown. In this case, the III-nitride ELO layer 105 separates easily from the substrate 101 due to the hetero-interface, which includes a lot of defects.

Employing the present invention, smooth interfaces 111 of the III-nitride ELO layers 105 can be obtained, for example, for a resonant cavity, even using the hetero-substrate 101, because a wing region of the III-nitride ELO layers 105, and the interface 111 between the growth restrict mask 102 and the III-nitride ELO layers 105, are used as mirrors for the resonant cavity in the device 110.

The use of the hetero-substrate 101 also has a large impact for mass production. For example, the hetero-substrate 101 used can be a low cost and large size substrate 101, such as sapphire, GaAs and Si, as compared to a free standing GaN substrate 101. This results in low cost devices 110. Moreover, sapphire and GaAs substrates are well known as low thermal conductivity materials, so devices 110 using these substrates 101 have thermal problems. However, using the present invention, since the device 110 is removed from the hetero-substrate 101, it can avoid these thermal problems.

Furthermore, in the case when using the ELO growth method for removing the bar of the device 110, this method can drastically reduce dislocation density and stacking faults density, which has become a critical issue in the case of using hetero-substrates 101.

Therefore, this invention can solve many of the problems resulting from the use of hetero-substrates 101.

### Eleventh Embodiment

There is a large demand to expand the wavelength range of operation to much shorter wavelengths, all the way to 400 nm or lower for e.g., displays, augmented reality (AR)/virtual reality (VR) displays, quantum related technologies, general metrology and spectroscopy including bio-sensing, etc. Many demonstrations have utilized photonic integrated circuits (PICs) based on silicon nitride (SiN), lithium niobate (LiNbO₃), tantalum pentoxide (Ta₂O₅), aluminum nitride (AlN), aluminum oxide (Al₂O₃), or other suitable materials with a large bandgap energy, to address the short wavelength range. However, in all these demonstrations, lasers were either externally coupled or assembled in a process that does not scale to the large volumes and low costs necessary for wide deployment.

To address the new emerging markets, a wafer-scale process providing on-chip sources and amplifiers to common passive platforms operating down to a 400 nm wavelength is needed, preferably one that can easily be transferred to a state-of-the-art fabrication facility. In addition, the approach described in this invention, which does not require intermediate layers, enables utilization of the full transparency range of passive waveguide material without being limited by the bandgaps of those intermediate layers.

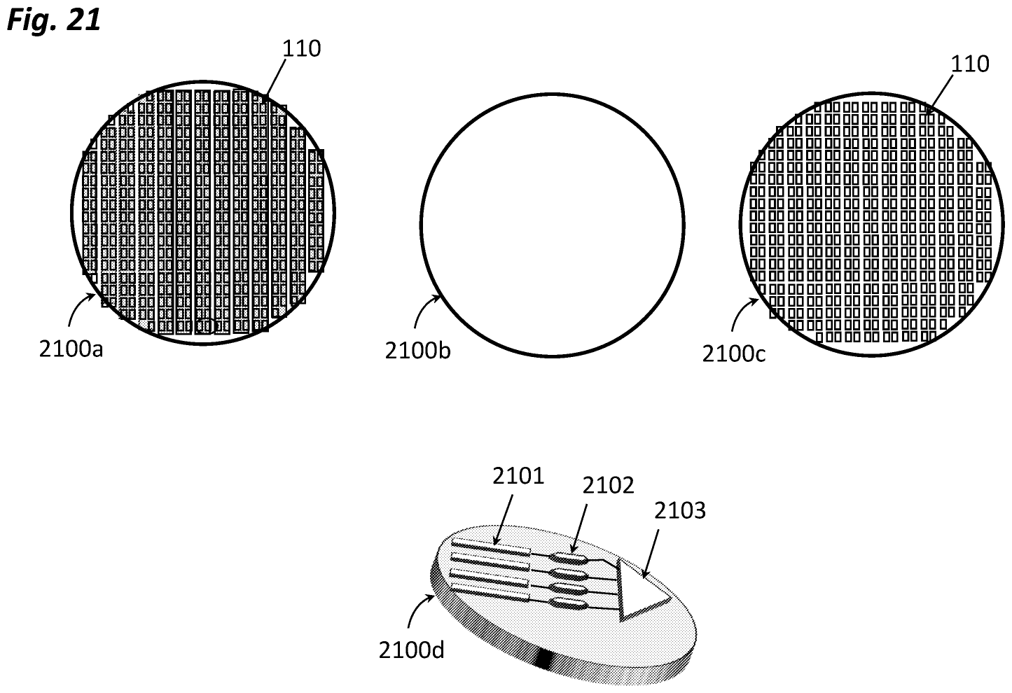

This invention can be used to heterogeneously integrate electrically-pumped GaN lasers and detectors coupled to SiN or TiO₂ waveguides with very high device uniformity using wafer-scale processes. The technology promises to revolutionize many fields including displays, volumetric light projection, AR/VR displays, position, navigation and timing (PNT), quantum sensing, and computing, by enabling wafer-scale manufacture of photonic integrated chips with on-chip sources using high-volume, high-quality CMOS facilities, as shown in schematics 2100a, 2100b. 2100c. 2100d in FIG. 21, wherein schematic 2100a represents a semiconductor layer wafer comprised of isolated devices 110, schematic 2100b represents a carrier wafer, schematic 2100c represents the devices 110 attached to the carrier wafer 2100b, and schematic 2100d represents an application where laser devices 2101, modulators 2102, and a multiplexor 2103 are combined on the carrier wafer 2100b.

### Twelfth Embodiment

A twelfth embodiment has the advantage of improved yields using the processes of this invention. This invention first separates the III-nitride ELO layers 105 and III-nitride device layers 107 on a host substrate 101, and yet the separated/isolated III-nitride ELO layers 105 and III-nitride device layers 107 remain on the growth restrict mask 102 of the host substrate 101 by relying on a weak interaction force and/or a weak link 301, 302. By doing so, the devices 110 are already in a relaxed state, so wafer bowing or cracking of device layers 107 due to stress, etc., may not be a problem when transferring devices 110 at wafer scale. See, e.g., schematics 2100a, 2100b, 2100c, 2100d in FIG. 21.

### Thirteenth Embodiment

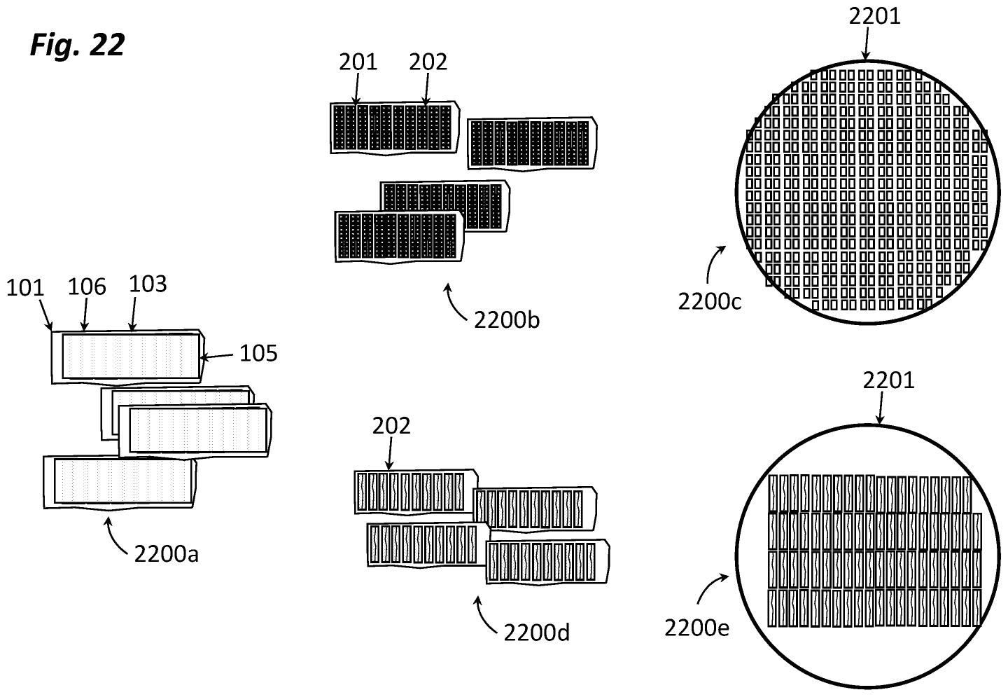

As shown by schematics 2200a, 2200b, 2200c, 2200d, 2200e in FIG. 22, a thirteenth embodiment is about making large scale substrates using the transfer process of epitaxial layers. Enlarged III-nitride substrates with better epitaxial quality can be obtained by altering some processes of the present invention. Coalesced III-nitride ELO layers 105 on the host substrate 101 as shown in schematic 2200a can be separated from the host substrate 101 in small groups by etching Regions 1 and 2 201, 202 as shown in schematic 2200b, and then tiled onto a larger carrier substrate 2201, such as Si, sapphire, etc., as shown in schematic 2200c. Once tiled onto a larger carrier substrate 2201, device 110 epitaxy can be performed by introducing the tiled epitaxy layers containing carriers 2201 into an MOCVD reactor.

This method is especially useful when special orientations, such as semi-polar or non-polar III-nitride substrates 101 are required. Semi-polar or non-polar crystal orientation substrates are sub-products of a conventional c-plane manufacturing process. HVPE processed c-plane substrate boules are sliced to various crystal orientations to produce semi-polar substrates. Cracking issues between III-nitride layers and the carrier substrate of HVPE prevents the manufacture of thicker boules, thus limiting the achievable dimensions for semi-polar and non-polar substrates.

However, using this invention, one may use smaller available special orientation substrates 101 to generate base III-nitride ELO layers 105, and then separate them from their host substrate 101, and tile them onto a bigger carrier wafer 2201, either using surface activation bonding or some intermediate layer, which can withstand MOCVD temperatures when III-nitride device layers 107 are grown. Using the process of integration described in FIG. 22, one may realize larger size III-nitride wafers.

Also, the same processes may be applied in device 110 processing. For example, one may first separate high-quality III-nitride ELO layers 105 and n-type III-nitride device layers 107 from the host substrate 101 as shown in schematic 2200d, transfer them onto a carrier substrate 2201 as shown in schematic 2200e, and then reintroduce the carrier substrate 2201 into the MOCVD reactor to grow any remaining III-nitride device layers 107, such as active layers and p-type layers. After completing growth of the III-nitride device layers 107 on the carrier wafer 2201, the desired device 110 can be fabricated.

### Fourteenth Embodiment

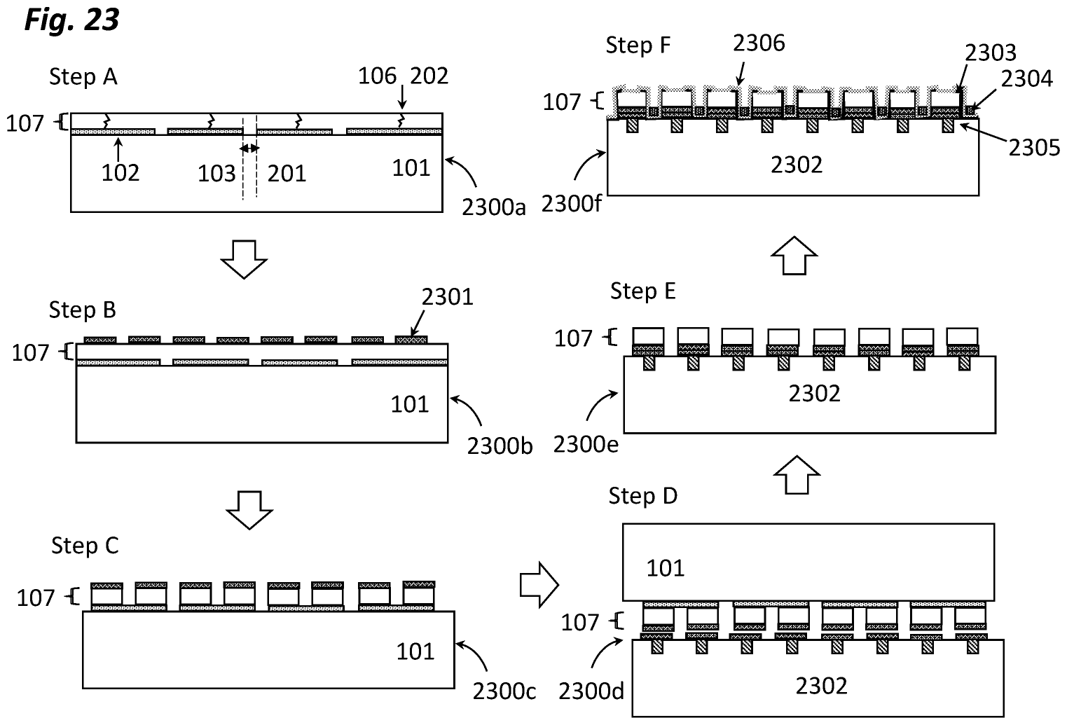

A fourteenth embodiment is about realizing small-pixel-per-inch devices 110 for AR/VR display applications, as shown in schematics 2300a, 2300b, 2300c, 2300d, 2300e, 2300f in FIG. 23. The III-nitride device layers 107 in schematic 2300a of Step A are isolated on the growth restrict mask 102 with a p-pad metal layer 2301 as a selective etchant mask as shown in schematic 2300b of Step B and schematic 2300c of Step C. Then, the III-nitride device layers 107 and substrate 101 are flipped, and a CMOS integrated controls (IC) wafer 2302 is attached or bonded to the selective pitch of the separated III-nitride device layers 107 on the host substrate 101 as shown in schematic 2300d of Step D, and the host substrate 101 is eliminated as shown in schematic 2300e of Step E. An n-contact layer 2303 and an electrical pad 2304 are processed on the n-type layer, which is the interface 111 of the III-nitride ELO layers 105. To avoid obstructing the emitting light, one may place a transparent conducting layer 2305 on the interface 111 of the III-nitride ELO layers 105 as indicated in schematic 2300f of Step F, and displace the reflective n-metal contact 2303 onto the CMOS IC wafer. Moreover, a passivation layer 2306 may be deposited on the III-nitride device layers 107.

### Fifteenth Embodiment

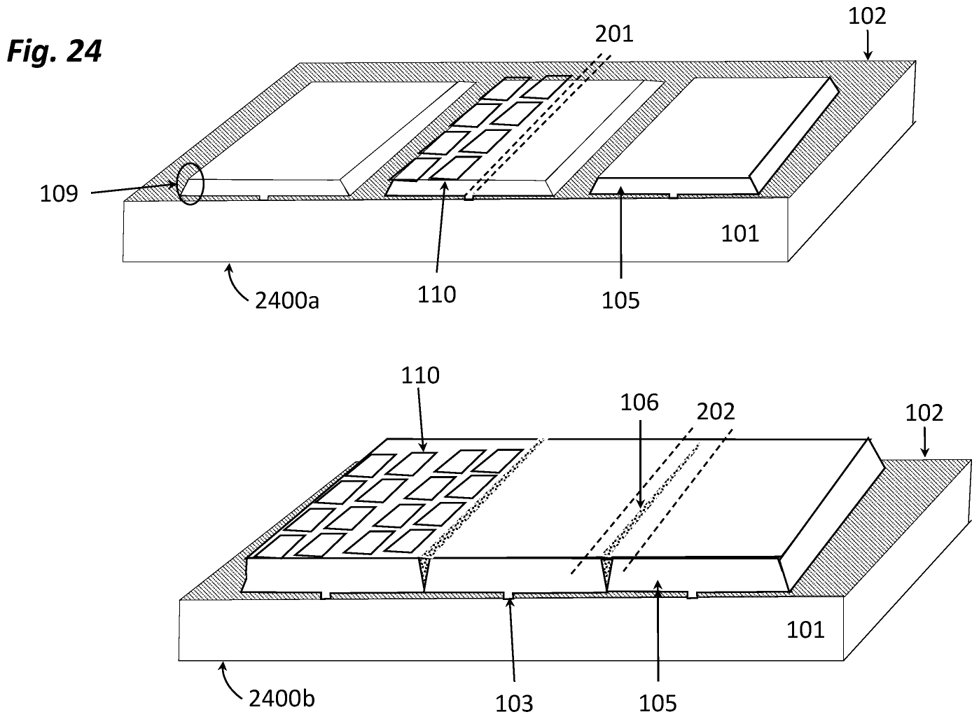

As shown in schematics 2400a, 2400b in FIG. 24, the fifteenth embodiment describes a method to obtain multiple light emitting devices 110 from a single wing of the III-nitride ELO layers 105. When required light emitting device 110 dimensions are in the range of 1 μm-50 μm (along a single side in the case of non-circular or diameter dimensions), etching regions to isolate the devices 110, such as Region 1 201 and Region 1 202, are separated such that multiple devices 110 can be extracted from a single wing of the III-nitride ELO layers 105 as shown in schematics 2400a, 2400b in FIG. 24. This method of extraction reduces the number of bending regions 109 in the uncoalesced III-nitride ELO layers 105 as shown in schematic 2400a, and reduces the number of coalesced III-nitride ELO layers 105 on the substrate 101 as shown in schematic 2400b, and thus this increases the useful device 110 extraction area from a single wafer and leads to an increased yield.

### Sixteenth Embodiment

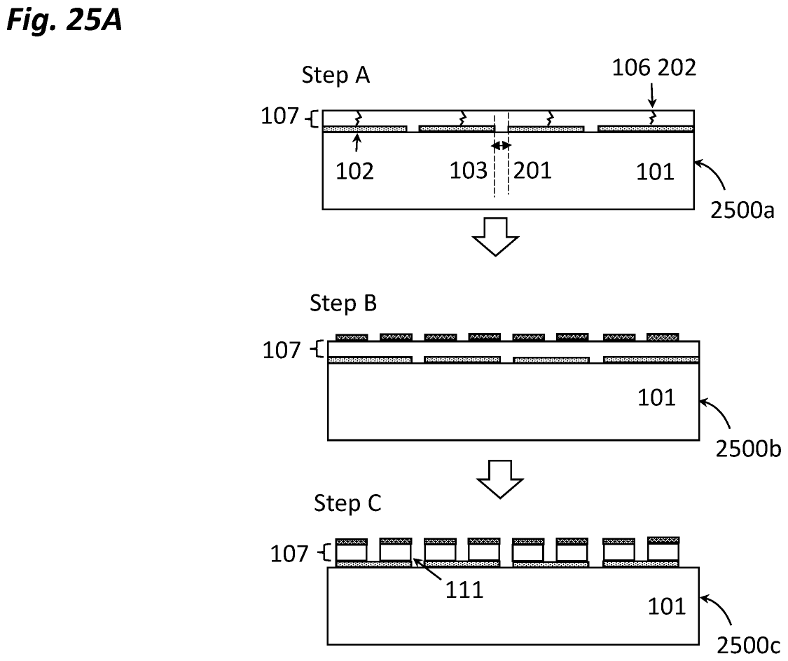

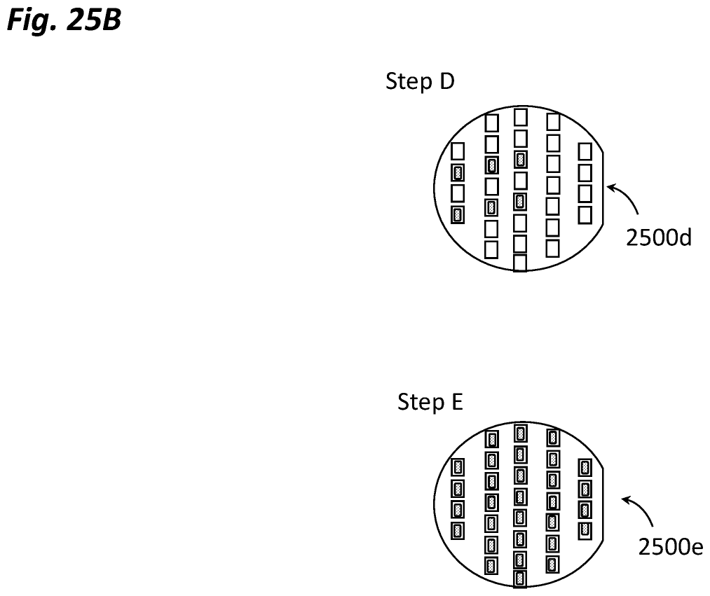

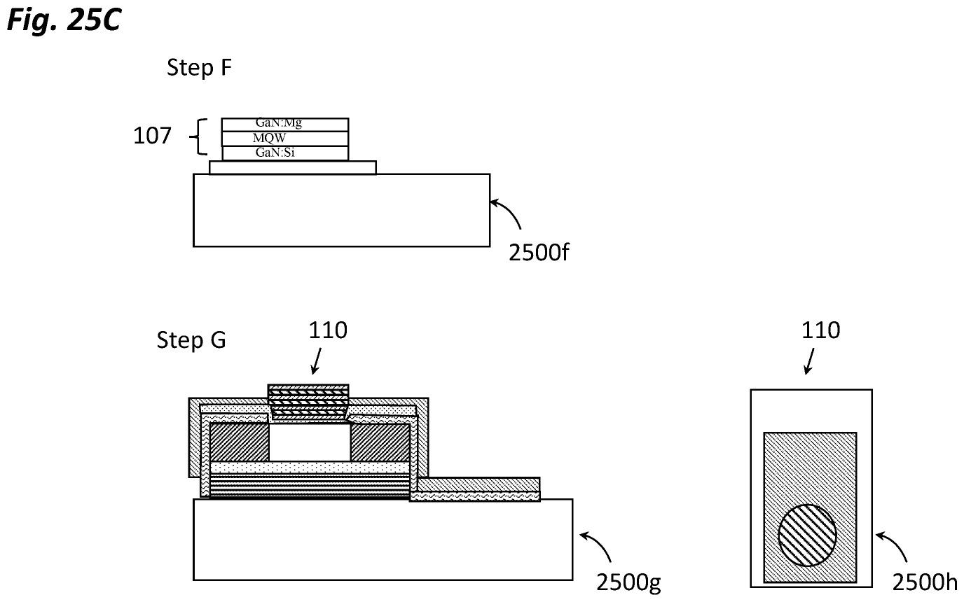

As shown in schematics 2500a, 2500b, 2500c, 2500d, 2500e, 2500f, 2500g, 2500h in FIGS. 25A, 25B and 25C, the sixteenth embodiment describes a method for realizing VCSEL devices 110. After growing the III-nitride device layers 107 in schematic 2500a of Step A and isolating devices 110 in schematic 2500b of Step B, where the devices 110 remain on the growth restrict mask 102, with or without a supportive hook, as described in schematic 2500c of Step C, the devices 110 were dispersed from the substrate 101 onto a larger pre-processed carrier substrate using a pick-and-place or vacuum method, etc., so that the interface 111 faces down on the pre-patterned patch of epitaxial DBR. This dispersion of the devices 110 from the growth substrate 101 may be performed several times to fully populate the larger carrier substrate as described in schematic 2500d of Step D. After populating the carrier substrate, surface activation bonding is performed between the dispersed devices 110 and the epitaxial DBR layers of the carrier as described in schematic 2500e of Step E. Surface activation bonding can be performed at more accelerated conditions as no material damage occurs from the processing mostly done with epitaxial semiconductor layers 105, 107.

Front-end processes such as defining a current aperture, p-contact layer deposition, dielectric DBR placement, etc., were performed on the large carrier substrate as described in schematic 2500f of Step F, which improves yield and reduces manufacturing cost. The carrier containing the epitaxial DBR can be used as one of the electrical contacts. A second electrical contact may be disposed on the top surface of the devices 110; however, if devices 110 are smaller or some technical complexity is involved, an isolation layer may be deposited on the carrier wafer to separate two electrical contacts as described in schematics 2500g and 2500h of Step G.

Process Flowchart

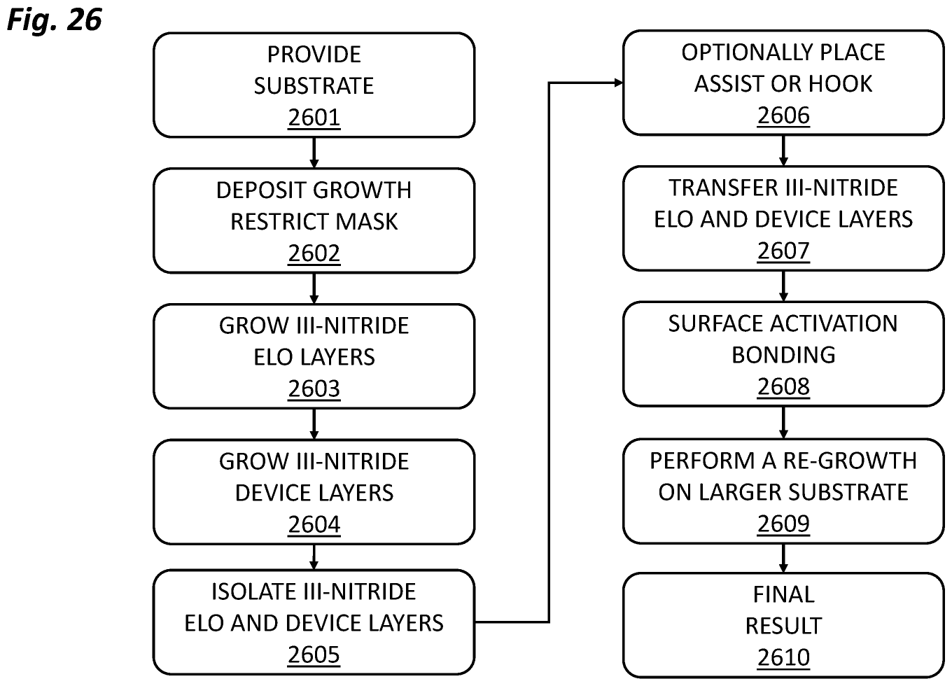

FIG. 26 is a flowchart illustrating how to fabricate semiconducting devices according to this invention.

Block 2601 represents the step of providing a host substrate 101. In one embodiment, the substrate 101 is a semiconducting substrate, independent of crystal orientations, such as III-nitride based substrate 101, for example, a GaN-based substrate, or a hetero-substrate 101, such as a sapphire substrate. This step may also include an optional step of depositing a template layer on or above the substrate 101, wherein the template layer may comprise a buffer layer and/or one or more intermediate layers, such as a GaN underlayer.

Block 2602 represents the step of depositing a growth restrict mask 102 on or above the substrate 101, i.e., on the substrate 101 itself or on the template layer. The growth restrict mask 102 is patterned to include a plurality of striped opening areas 103. The growth restrict mask 102 may comprises a multi-layer structure.

Block 2603 represents the step of forming one or more III-nitride layers 105 on or above the growth restrict mask 102 using epitaxial lateral overgrowth (ELO). This step may or may not include stopping the growth of the III-nitride ELO layers 105 before adjacent ones of the III-nitride ELO layers 105 coalesce to each other.

Block 2604 represents the step of growing one or more III-nitride device layers 107 on or above the III-nitride ELO layers 105, thereby fabricating a bar of one or more devices 110 on the substrate 101. Additional device 110 fabrication may take place before and/or after the device 110 is removed from the substrate 101.

With regard to μLED devices 110, this step may include defining a p-pad and n-pad, and metalizing both pads, wherein p-pad metallization comprises a vertical pad configuration.

With regard to Fabry-Perot or dual-clad laser devices 110, this step may include defining a ridge structure on a wing of the III-nitride ELO layers 105, defining a p-pad and n-pad, and metalizing both pads, wherein p-pad metallization comprises a vertical pad configuration.

With regard to VCSEL devices 110, this step may include defining a current confining aperture, defining a p-pad and n-pad, and metalizing both pads, wherein p-pad metallization comprises a vertical pad configuration.

Block 2605 represents the step of isolating the III-nitride ELO layers 105 and the III-nitride device layers 107 into separate devices 110. This step may comprise a separating process that divides the ELO layers 105 and device layers 107 into the devices 110. This step may also include etching to isolate the III-nitride ELO layers 105 and the III-nitride device layers 107 into separate devices 110, and the etching may include placing an isolation mask on the III-nitride ELO layers 105 to define the etching.

Block 2606 represents the optional step of placing an assist layer 301 or hook layer 302 to secure the III-nitride ELO layers 105 and the III-nitride device layers 107 onto the substrate 101; optionally, there may be no assist layer 301 or hook layer 302.

With regard to Fabry-Perot or dual-clad laser devices 110, this step may include accessing the pads on the isolation mask, selectively bonding devices 110 to a carrier for facet formation and coating, device 110 singulation, and attachment to a heatsink of the carrier on which at least one of the pads is formed.

With regard to VCSEL devices 110, this step may include surface activation bonding to a carrier substrate containing an epitaxial DBR (taking the advantage of surface smoothness at the interface 111 between the III-nitride ELO layers 105 and the growth restrict mask 102), accessing the pads on the isolation mask, device 110 singulation and attachment to a heatsink or a carrier on which at least one of the electrical pads formed.

Block 2607 represents the step of transferring the III-nitride ELO layers 105 and III-nitride device layers 107, using pick-and-place or a vacuum chuck.

With regard to μLED devices 110, this step may include placing devices 110 on an intermediate substrate, local repair on a display panel, and/or dispersing devices 110 onto a display panel, followed by defining electrical paths.

Block 2608 represents the step of surface activation bonding onto a larger substrate.

Block 2609 represents the step of performing a regrowth of the III-nitride device layers 107 on a larger III-nitride ELO layer 105.

Block 2610 represents the resulting product of the method, namely, one or more III-nitride based semiconductor devices 110, such as μLEDs, Fabry-Perot or dual-clad lasers, or VCSELs, fabricated according to this method, as well as a substrate 101 that has been removed from the devices 110 and is available for recycling and reuse.

Advantages and Benefits

This invention is especially useful when bonding the ELO layer or the devices without using solder to another carrier or a substrate.

Generally, the surface activated bonding method needs a flatness and a smoothness with a wide area when bonding wafers. When bonding each wafer, a force and a heat is applied to wafers. Applying the force and the heat in a uniform manner is difficult, especially when each wafer is made of different material. Some part of the wafer can bond to each other, but the remainder cannot bond. Thus, the yield is not high. In the present invention, the ELO layers and the devices are of small size, and bonding with small sizes can avoid these issues. It is preferable that the length of ELO layers being transferred is 40 mm or less, and more preferably, 20 mm. It is also preferable that the width of the ELO layers being transferred is 200 μm or less, and more preferably, 100 μm.

The following describes the processes flow to obtain the above advantages.

Case 1:
1. Growing ELO layers on a substrate with a growth restrict mask.
2. Growing device layers on the ELO layers.
3. Fabricating devices on the device layers.
4. Isolating the devices on the growth restrict mask.
5. Transferring the devices to a carrier wafer with or without DBRs or cladding layers and without solder.
6. Dividing the carrier wafer into the chips.

Case 2:
1. Growing ELO layers on a substrate with a growth restrict mask.
2. Growing device layer on the ELO layers.
3. Isolating the ELO layers on the growth restrict mask.
4. Transferring the devices to a carrier wafer with or without DBRs or cladding layers, and without solder.
5. Fabricating devices on the device layers on the carrier wafer.
6. Dividing the carrier wafer into the chips.

Case 2 has an advantage when the bonding, since the ELO layers do not have electrodes or device structures, such as a ridge stripe, etc., a strong force and high temperature process can be applied when bonding. The strong force and high-temperature process can improve the bonding yield.

The present invention provides a number of other advantages and benefits as well:
Expensive III-nitride based substrates 101 can be reused after the substrates 101 are removed from the device 110 layers.
High crystalline quality layers may be obtained using a substrate 101 of the same or similar materials, with a very low defect density.
Using the same or similar materials for both the substrate 101 and the layers 105, 107 can reduce the strain in the layers 105, 107.
Using materials with the same or similar thermal expansion for both the substrate 101 and the layers 105, 107 can reduce bending of the substrate 101 during epitaxial growth.
Layers 105 grown by ELO have a good crystal quality.
When the III-nitride ELO layers 105 do not coalesce with each other, internal strain is released, which helps to avoid any occurrences of cracks. For device layers 107 that are AlGaN layers, this is very useful, especially in the case of high Al content layers.
The resonant cavity of the VCSEL device is fabricated on an ELO wing region.
The ELO wing region is a low defect region area, which improves characteristics of the device.
There is no need for a tedious substrate thinning process to fabricate a second DBR mirror of the cavity. Thinning is needed for conventional fabrication in order to avoid significant absorption of emitted wavelength of the device.
Alternate processes like photo chemical etching processes to remove semiconductor layers are crystal plane dependent and extremely slow. However, the methods described herein have no crystal plane dependency. Any plane of the crystal can obtain a smooth interface at the growth restrict mask by controlling parameters of the growth restrict mask and growth.
On the other hand, the method of removing in this invention is not expensive, is robust, and can be used for mass transfer.
After removing the III-nitride ELO layers 105, they can be simply surface bonded to an external prepared DBR mirror by surface activation or diffusion bonding, because the interface of the removed layers is smooth enough to assist such bonding techniques
Long cavity curved mirror structures can be fabricated without involving complex steps and only using the epitaxially grown layers, which allows for recycling of the substrate.
The island-like III-nitride semiconductor layers are formed in isolation, so that tensile stress or compressive stress are reduced.
Also, the growth restrict mask 102 and the III-nitride ELO layers 105 are not bonded chemically, so the stress in the III-nitride ELO layers 105 and additional device layers 107 can be relaxed by a slide caused at the interface between the growth restrict mask 102 and the III-nitride ELO layers 105.
Layers 105, 107 of high-quality semiconductor crystal can be grown by suppressing the curvature of the substrate 101, and further, even when the layers 105, 107 are very thick, the occurrences of cracks, etc., can be suppressed, and thereby a large-area semiconductor device can be easily realized.
The fabrication method can also be easily adopted to large size wafers (>2 inches).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

1. A method, comprising:
growing one or more epitaxial lateral overgrowth (ELO) layers and device layers on a substrate using a growth restrict mask;
fabricating one or more devices on or above the ELO layers and device layers;
isolating the ELO layers and device layers on the growth restrict mask from the substrate; and
transferring the isolated ELO layers and device layers to a carrier wafer.

2. The method of claim 1, wherein the isolating step includes a separating process that divides the ELO layers and device layers into the devices.

3. The method of claim 1, wherein the transferring step includes a bonding process without a solder.

4. The method of claim 1, wherein the transferring step includes a bonding process with a solder.

5. The method of claim 1, wherein the transferring step integrates the ELO layers and device layers onto the carrier wafer, and the carrier wafer is larger than the substrate.

6. The method of claim 1, wherein the transferred ELO layers and device layers are integrated onto a photonic integration circuit.

7. The method of claim 1, wherein the fabricating step is conducted after the transferring step.

8. The method of claim 1, wherein the isolated ELO layers and device layers remain on the growth restrict mask.

9. The method of claim 8, wherein the isolated ELO layers and device layers remain on the growth restrict mask with assistance from a secured hook layer.

10. The method of claim 1, further comprising removing the ELO layers and device layers from the substrate.

11. The method of claim 10, wherein the removing step is performed using a pick-and-place, a vacuum chuck, surface activation bonding, or bonding through an intermediate layer.

12. The method of claim 10, wherein the removing step is performed selectively.

13. The method of claim 1, wherein the substrate is a semiconducting substrate.

14. The method of claim 13, wherein the semiconducting substrate is independent of crystal orientations.

15. The method of claim 1, wherein the carrier wafer has one or more cladding layers, distributed Bragg reflector (DBR) layers, or heatsinks, for the devices.

16. The method of claim 1, wherein the carrier wafer has one or more epitaxial distributed Bragg reflector (DBR) layers for the devices.

17. The method of claim 1, wherein the growth restrict mask comprises a multi-layer structure.

18. A device fabricated by the method of claim 1.

19. A device, comprising:
one or more epitaxial lateral overgrowth (ELO) layers and device layers grown on a substrate using a growth restrict mask, wherein:
one or more devices are fabricated on or above the ELO layers and device layers;
the ELO layers and device layers are isolated on the growth restrict mask from the substrate; and
the isolated ELO layers and device layers are transferred to a carrier wafer.

20. The device of claim 19, wherein the device comprises a micro-sized light-emitting diode (μLED), edge-emitting laser, or vertical-cavity surface-emitting laser (VCSEL).
